(19) United States
(12) Patent Application Publication
(10) Pub. No.: US 2023/0024598 A1
(43) Pub. Date: Jan. 26, 2023

(54) SEMICONDUCTOR ELEMENT

(71) Applicant: SONY SEMICONDUCTOR SOLUTIONS CORPORATION, KANAGAWA (JP)

(72) Inventors: TOSHIAKI ONO, KANAGAWA (JP); TADAYUKI TAURA, KANAGAWA (JP)

(21) Appl. No.: 17/757,516

(22) PCT Filed: Dec. 14, 2020
(86) PCT No.: PCT/JP2020/046487

§ 371 Date: Jun. 16, 2022

(30) Foreign Application Priority Data
Dec. 24, 2019 (JP) 2019-233586
Jun. 3, 2020 (JP) 2020-096919

(51) Int. Cl. H01L 27/146; H01L 23/00; H04N 17/00

(52) U.S. Cl. CPC H01L 27/14634; H01L 24/08; H01L 27/14636; H04N 17/002; H01L 2224/08145; H04N 5/378

(57) ABSTRACT

Provided is a semiconductor element capable of inspecting a plurality of wires formed in parallel. A semiconductor element according to an embodiment includes: a first circuit (45B) connected to a first position of each of a plurality of wires of a first wire group (31) including the plurality of wires; a second circuit (45A) connected to a second position corresponding to an end of each of the plurality of wires; and a plurality of connection units (43) that connects a third circuit (14) with each of the plurality of wires, the plurality of connection units (43) being provided on a one-to-one basis to the plurality of wires between the first position and the second position of each of the plurality of wires.

### FIELD

The present disclosure relates to a semiconductor element.

### BACKGROUND

There is known a pixel array in which a plurality of pixels each including one or more light receiving elements is disposed in a matrix arrangement on a semiconductor substrate. The pixel array includes wires for each pixel row and each pixel column connected to light receiving elements. Furthermore, there is known a technique of constituting one imaging element by bonding and laminating a first semiconductor substrate and a second semiconductor substrate. The pixel array is formed on the first semiconductor substrate. A circuit that executes signal processing and the like on a pixel signal read out from each pixel included in the pixel array is formed on the second semiconductor substrate.

### CITATION LIST

### Patent Literature

Patent Literature 1: JP H04-180374 A

### SUMMARY

### Technical Problem

In the pixel array as described above, the presence or absence of a defect of a wire in each pixel row and each pixel column has influence on a yield. Therefore, the presence or absence of a defect of a wire included in the pixel array needs to be inspected before the first semiconductor substrate and the second semiconductor substrate are bonded and laminated for constituting an imaging element.

An object of the present disclosure is to provide a semiconductor element capable of inspecting a plurality of wires formed in parallel.

### Solution to Problem

For solving the problem described above, a semiconductor element according to one aspect of the present disclosure has a first circuit connected to a first position of each of a plurality of wires of a first wire group including the plurality of wires; a second circuit connected to a second position corresponding to an end of each of the plurality of wires; and a plurality of connection units that connects a third circuit with each of the plurality of wires, the plurality of connection units being provided on a one-to-one basis to the plurality of wires between the first position and the second position of each of the plurality of wires.

### BRIEF DESCRIPTION OF DRAWINGS

FIG. 1 is a block diagram schematically illustrating a basic configuration of a CMOS image sensor, which is one example of an imaging element applicable to each embodiment.

FIG. 2 is a circuit diagram illustrating one example of the circuit configuration of a pixel applicable to each embodiment.

FIG. 3 is a block diagram illustrating one example of the configuration of a column-parallel AD conversion unit applicable to each embodiment.

FIG. 4 is an exploded perspective view schematically illustrating a laminated chip structure of the imaging element applicable to each embodiment.

FIG. 5 illustrates a specific configuration example of a first semiconductor substrate according to each embodiment.

FIG. 6 illustrates an example of the configuration of the first semiconductor substrate according to the first embodiment.

FIG. 7 illustrates open detection according to the first embodiment.

FIG. 8A is a schematic diagram illustrating an electrode and the vicinity thereof in the first semiconductor substrate.

FIG. 8B is a cross-sectional view illustrating a first structure example in a case where the first semiconductor substrate and the second semiconductor substrate are bonded and laminated.

FIG. 8C is a cross-sectional view illustrating a second structure example in a case where the first semiconductor substrate and the second semiconductor substrate are bonded and laminated.

FIG. 9 illustrates an example of the configuration of a first semiconductor substrate according to a first variation of the first embodiment.

FIG. 10 illustrates erroneous detection that may occur in open inspection according to the configuration of the first embodiment.

FIG. 11 illustrates open inspection according to the configuration of the first variation of the first embodiment.

FIG. 12 illustrates an example of the configuration of a first semiconductor substrate according to a second variation of the first embodiment.

FIG. 13 illustrates an example of the configuration of a first semiconductor substrate according to a third variation of the first embodiment.

FIG. 14 illustrates an example of the configuration of a first semiconductor substrate according to a fourth variation of the first embodiment.

FIG. 15 illustrates an example of the configuration of a first semiconductor substrate according to a second embodiment.

FIG. 16A is a circuit diagram of one example of a switch circuit according to the second embodiment.

FIG. 16B is a circuit diagram of one example of a transfer circuit according to the second embodiment.

FIG. 17 illustrates an example of the configuration of a first semiconductor substrate according to a third embodiment.

FIG. 18 illustrates another example of the configuration of the first semiconductor substrate according to the third embodiment.

FIG. 19A illustrates an example of the configuration of a first semiconductor substrate according to a fourth embodiment.

FIG. 19B is a circuit diagram illustrating the configuration of one example of a switch decoder according to the fourth embodiment.

FIG. 20 is a circuit diagram schematically illustrating the configuration of one example of a bias unit according to the fourth embodiment.

FIG. 21A illustrates an example of the configuration of a first semiconductor substrate according to a fifth embodiment.

FIG. 21B is a circuit diagram illustrating the configuration of one example of a switch decoder according to the fifth embodiment.

FIG. 22 illustrates another example of the configuration of the first semiconductor substrate according to the fifth embodiment.

FIG. 23A illustrates an example of the setting of a switch decoder ADR in a case where open inspection is performed in the configuration according to the fifth embodiment.

FIG. 23B schematically illustrates the states of vertical signal lines at the time of the open inspection.

FIG. 24 illustrates an example of the setting of the switch decoder ADR in a case where short-circuit inspection in a first example is performed in the configuration according to the fifth embodiment.

FIG. 25 illustrates an example of the setting of the switch decoder ADR in a case where short-circuit inspection in a second example is performed in the configuration according to the fifth embodiment.

FIG. 26A is a circuit diagram illustrating an example of an application circuit according to existing technology.

FIG. 26B is a circuit diagram illustrating an example of an application circuit 660 according to the existing technology.

FIG. 27A is a circuit diagram illustrating an example of an application circuit according to a sixth embodiment.

FIG. 27B is a circuit diagram schematically illustrating a circuit formed on a first semiconductor substrate according to the sixth embodiment.

FIG. 27C is a schematic plan view of one example of the first semiconductor substrate according to the sixth embodiment.

FIG. 28A is a circuit diagram illustrating an example of an application circuit according to a first variation of the sixth embodiment.

FIG. 28B is a circuit diagram schematically illustrating a circuit formed on a first semiconductor substrate according to the first variation of the sixth embodiment.

FIG. 28C is a schematic plan view of one example of the first semiconductor substrate according to the first variation of the sixth embodiment.

FIG. 29 is a schematic plan view of one example of a first semiconductor substrate according to a second variation of the sixth embodiment.

FIG. 30 is a schematic plan view of one example of a first semiconductor substrate according to a third variation of the sixth embodiment.

FIG. 31 illustrates an example of a pixel circuit and a detection circuit for describing inspection using existing technology.

FIG. 32A illustrates effects according to the sixth embodiment and the variations thereof.

FIG. 32B illustrates effects according to the sixth embodiment and the variations thereof.

FIG. 33 is a cross-sectional view of a main portion of an imaging element wafer applicable to the present disclosure.

FIG. 34 illustrates usage examples using the embodiments and the variations thereof according to the technology of the present disclosure.

FIG. 35 is a block diagram illustrating the configuration of one example of an imaging device to which the technology of the present disclosure can be applied.

### DESCRIPTION OF EMBODIMENTS

Embodiments of the present disclosure will be described in detail below with reference to the drawings. Note that, in the following embodiments, the same reference signs are attached to the same parts to omit redundant description.

The embodiments of the present disclosure will be described below in the following order.

1. Configuration Applicable to Each Embodiment

1-1. Configuration Example of CMOS Image Sensor

1-2. Example of Circuit Configuration of Pixel

1-3. Configuration Example of Column-Parallel AD Conversion Unit

1-4. Example of Chip Structure

1-5. Outline of Inspection According to Existing Technology

2. Outline of Configuration According to Each Embodiment

3. First Embodiment

3-0-1. Configuration Example of First Semiconductor Substrate According to First Embodiment

3-0-2. Example of Inspection Method According to First Embodiment

3-0-3. Structure Example of Needle Contact Terminal Applicable to Each Embodiment

3-1. First Variation of First Embodiment

3-1-1. Configuration Example of First Semiconductor Substrate According to First Variation of First Embodiment

3-1-2. Example of Inspection Method According to First Variation of First Embodiment

3-2. Second Variation of First Embodiment

3-2-1. Configuration Example of First Semiconductor Substrate According to Second Variation of First Embodiment

3-2-2. Example of Inspection Method According to Second Variation of First Embodiment

3-3. Third Variation of First Embodiment

3-4. Fourth Variation of First Embodiment

4. Second Embodiment

4-0-1. Configuration Example of First Semiconductor Substrate According to Second Embodiment

4-0-2. Example of Inspection Method According to Second Embodiment

4-0-3. Detailed Description of Bias Circuit According to Second Embodiment

5. Third Embodiment

5-0-1. Configuration Example of First Semiconductor Substrate According to Third Embodiment

5-0-2. Example of Inspection Method According to Third Embodiment

5-1. Another Example of Third Embodiment

6. Fourth Embodiment

6-0-1. Configuration Example of First Semiconductor Substrate According to Fourth Embodiment

6-0-2. Configuration Example of Switch Decoder According to Fourth Embodiment

6-0-3. Example of Inspection Method According to Fourth Embodiment

7. Fifth Embodiment

7-0-1. Configuration Example of First Semiconductor Substrate According to Fifth Embodiment

7-0-2. Example of Inspection Method According to Fifth Embodiment

7-0-2-1. Example of Open Inspection According to Fifth Embodiment

7-0-2-2. Example of Short-Circuit Inspection According to Fifth Embodiment

8. Sixth Embodiment

8-1. Existing Technology

8-2. Configuration According to Sixth Embodiment

8-3. First Variation of Sixth Embodiment

8-4. Second Variation of Sixth Embodiment

8-5. Third Variation of Sixth Embodiment

8-6. Effects According to Sixth Embodiment and Variations Thereof

9. Other Embodiments

10. Structure Applicable to Each Embodiment

11. Example of Application of Technology of Present Disclosure

### 1. Configuration Applicable to Each Embodiment

First, a basic configuration of an imaging element to which the technology of the present disclosure can be applied will be described. Here, the imaging element will be described by taking a complementary metal oxide semiconductor (CMOS) image sensor, which is one type of X-Y address imaging element, as an example. The CMOS image sensor is manufactured by applying or partially using a CMOS process.

(1-1. Configuration Example of CMOS Image Sensor)

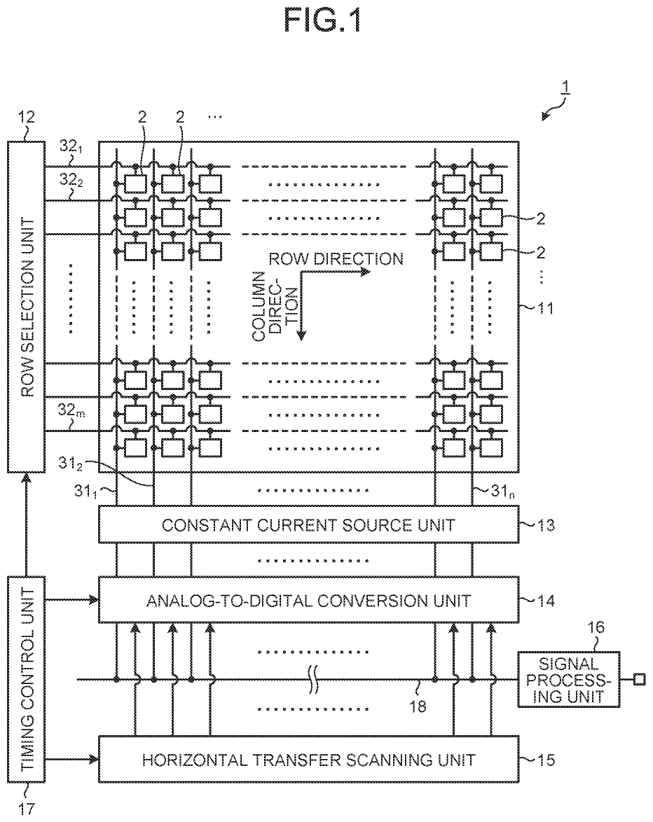

FIG. 1 is a block diagram schematically illustrating a basic configuration of a CMOS image sensor, which is one example of an imaging element applicable to each embodiment.

An imaging element 1 in FIG. 1 includes a pixel array unit (cell array) 11 and a peripheral circuit unit of the pixel array unit 11. In the pixel array unit 11, pixels (cells) 2 including a photoelectric conversion unit are two-dimensionally disposed in a row direction and a column direction, that is, in a matrix arrangement. Here, the row direction refers to an arrangement direction of the pixels 2 in a pixel row (horizontal direction), and the column direction refers to an arrangement direction of the pixels 2 in a pixel column (vertical direction). The pixels 2 perform photoelectric conversion to generate and accumulate a charge in accordance with an amount of received light.

In the example of FIG. 1, the peripheral circuit unit of the pixel array unit 11 includes, for example, a row selection unit 12, a constant current source unit 13, an analog-to-digital conversion unit 14, a horizontal transfer scanning unit 15, a signal processing unit 16, and a timing control unit 17.

In the pixel array unit 11, control lines 32₁ to 32ₙ are wired along the row direction for each pixel row in a matrix pixel arrangement. Furthermore, vertical signal lines 31₁ to 31ₘ are wired along the column direction for each pixel column. Note that, when it is unnecessary to particularly distinguish the vertical signal lines 31₁ to 31ₘ, the vertical signal lines 31₁ to 31ₘ will be appropriately described as a vertical signal line 31. Similarly, when it is unnecessary to particularly distinguish the control lines 32₁ to 32ₙ, the control lines 32₁ to 32ₙ will be appropriately described as a control line 32.

The control line 32 transmits a drive signal for performing driving at the time when a signal is read out from the pixel 2. Although, in FIG. 1, the control line 32 is illustrated as one wire, the control line 32 is not limited to one wire, and may include a plurality of wires. One end of the control line 32 is connected to an output end, corresponding to each row, of the row selection unit 12.

Next, each circuit part of the peripheral circuit unit of the pixel array unit 11, that is, the row selection unit 12, the constant current source unit 13, the analog-to-digital conversion unit 14, the horizontal transfer scanning unit 15, the signal processing unit 16, and the timing control unit 17 will be described.

The row selection unit 12 includes a shift register, an address decoder, and the like, and controls scanning of a pixel row and an address of the pixel row when selecting each pixel 2 included in the pixel array unit 11. Although a specific configuration of the row selection unit 12 is not illustrated, the row selection unit 12 generally includes two scanning systems of a readout scanning system and a sweep-out scanning system.

The readout scanning system sequentially selects and scans the pixels 2 of the pixel array unit 11 in units of rows in order to read out pixel signals from the pixels 2. The pixel signals read out from the pixels 2 are analog signals. The sweep-out scanning system performs sweep-out scanning on a readout row on which readout scanning is to be performed by the readout scanning system prior to the readout scanning by a time corresponding to a shutter speed.

Unnecessary charges are swept out from the photoelectric conversion unit of the pixel 2 in the readout row by sweep-out scanning of the sweep-out scanning system, which resets the photoelectric conversion unit. Then, so-called electronic shutter operation is performed by sweeping out (resetting) unnecessary charges with the sweep-out scanning system. Here, the electronic shutter operation refers to an operation of discarding a charge of the photoelectric conversion unit and newly starting exposure (starting accumulation of charge).

The constant current source unit 13 includes a plurality of current sources I, which include, for example, a metal oxide semiconductor (MOS) transistor, connected to each of the vertical signal lines 31₁ to 31ₘ for each pixel column. The constant current source unit 13 supplies a bias current to each pixel 2 of the pixel row selected and scanned by the row selection unit 12 through each of the vertical signal lines 31₁ to 31ₘ.

The analog-to-digital conversion unit 14 includes, for example, a plurality of analog-to-digital converters provided for each pixel column. The plurality of analog-to-digital converters is provided in accordance with the pixel columns of the pixel array unit 11. The analog-to-digital conversion unit 14 is a column-parallel type analog-to-digital conversion unit that converts a pixel signal, which is an analog signal output through each of the vertical signal lines 31₁ to 31ₘ for each pixel column, into an N-bit digital signal. Hereinafter, the analog-to-digital conversion unit 14 is referred to as a column-parallel analog-to-digital conversion unit 14.

For example, an analog-to-digital converter of the column-parallel analog-to-digital conversion unit 14 can include, for example, a single-slope type analog-to-digital converter, which is one example of a reference signal comparison type of analog-to-digital converter. This example is not a limitation, and the analog-to-digital converter of the column-parallel analog-to-digital conversion unit 14 can include a successive comparison type analog-to-digital converter, a delta-to-sigma modulation type (ΔΣ modulation type) analog-to-digital converter, and the like.

The horizontal transfer scanning unit 15 includes a shift register, an address decoder, and the like, and controls scanning of a pixel column and an address of the pixel column when reading out a signal of each pixel 2 of the pixel array unit 11. Under the control of the horizontal transfer scanning unit 15, a horizontal transfer line 18 having a 2N-bit width reads out the pixel signal, which has been converted into a digital signal by the column-parallel analog-to-digital conversion unit 14, in units of pixel columns.

The signal processing unit 16 performs predetermined signal processing on the digital pixel signal supplied through the horizontal transfer line 18 to generate two-dimensional image data. For example, the signal processing unit 16 can perform each piece of signal processing, such as correction of a vertical line defect and a point defect and signal clamping, on the supplied pixel signal. Furthermore, the signal processing unit 16 can perform signal processing, such as parallel-to-serial conversion, compression, encoding, adding, averaging, and intermittent operation, on the supplied pixel signal. The signal processing unit 16 outputs the generated image data to a subsequent device as an output signal of the imaging element 1.

The timing control unit 17 generates various timing signals, clock signals, control signals, and the like, and performs drive control on the row selection unit 12, the constant current source unit 13, the column-parallel analog-to-digital conversion unit 14, the horizontal transfer scanning unit 15, the signal processing unit 16, and the like based on the generated signals.

(1-2. Example of Circuit Configuration of Pixel)

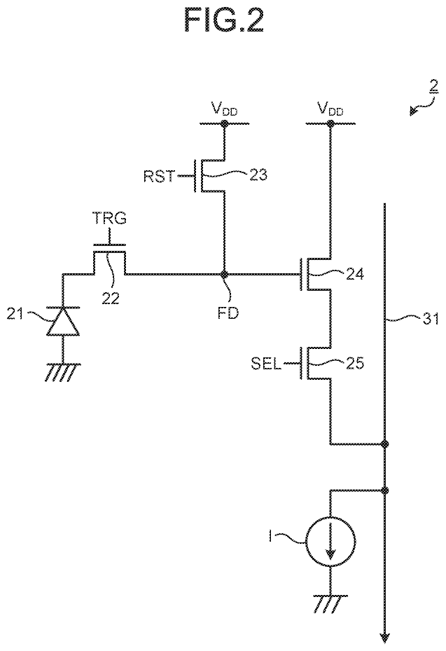

FIG. 2 is a circuit diagram illustrating one example of the circuit configuration of the pixel 2 applicable to each embodiment. The pixel 2 includes, for example, a photodiode 21 as a photoelectric conversion unit. The pixel 2 has a pixel configuration including a transfer transistor 22, a reset transistor 23, an amplification transistor 24, and a selection transistor 25 in addition to the photodiode 21.

In the example of FIG. 2, for example, N-channel MOS field effect transistors (FETs) are used as the four transistors of the transfer transistor 22, the reset transistor 23, the amplification transistor 24, and the selection transistor 25. Hereinafter, the N-channel MOS field effect transistors are referred to as NMOS transistors. The pixel 2 including only the NMOS transistors can promote optimization of area efficiency and a process reduction viewpoint. Note that the combination of the conductivity type of the transfer transistor 22, the reset transistor 23, the amplification transistor 24, and the selection transistor 25 in FIG. 2 is merely one example, and the combination thereof is not a limitation.

For the pixel 2, a plurality of control lines is wired in common for each pixel 2 of the same pixel row as the above-described control line 32. The plurality of control lines is connected to an output end corresponding to each pixel row of the row selection unit 12 in units of pixel rows. The row selection unit 12 appropriately outputs a transfer signal TRG, a reset signal RST, and a selection signal SEL to the plurality of control lines.

The photodiode 21 has an anode electrode connected to a low-potential-side power supply (e.g., ground potential), photoelectrically converts received light into a charge (here, photoelectron) of a charge amount in accordance with an amount of the received light, and accumulates the charge. A cathode electrode of the photodiode 21 is electrically connected to a gate electrode of the amplification transistor 24 via the transfer transistor 22. Here, a region to which the gate electrode of the amplification transistor 24 is electrically connected is a floating diffusion region FD. The floating diffusion region FD is a charge voltage conversion unit that converts a charge into a voltage.

The transfer signal TRG that activates a high level (e.g., V_{DD} level) is supplied from the row selection unit 12 to the gate electrode of the transfer transistor 22. The transfer transistor 22 becomes conductive in response to the transfer signal TRG, thereby transferring the charge photoelectrically converted by the photodiode 21 and accumulated in the photodiode 21 to the floating diffusion region FD.

The reset transistor 23 is connected between a node of a power supply V_{DD} that supplies a high-potential-side power supply voltage and the floating diffusion region FD. The reset signal RST that activates a high level is supplied from the row selection unit 12 to the gate electrode of the reset transistor 23. The reset transistor 23 becomes conductive in response to the reset signal RST, and resets the floating diffusion region FD by discarding the charge of the floating diffusion region FD to the node of the power supply V_{DD}.

The amplification transistor 24 has a gate electrode connected to the floating diffusion region FD and a drain electrode connected to the node of the power supply V_{DD}. The amplification transistor 24 serves as an input unit of a source follower that reads out a signal obtained by photoelectric conversion in the photodiode 21. That is, the amplification transistor 24 has a source electrode connected to the vertical signal line 31 via the selection transistor 25. Then, the amplification transistor 24 and the current source I connected to one end of the vertical signal line 31 constitute a source follower that converts a voltage of the floating diffusion region FD into a voltage of the vertical signal line 31.

The selection transistor 25 has a drain electrode connected to the source electrode of the amplification transistor 24 and a source electrode connected to the vertical signal line 31. The selection signal SEL that activates a high level is supplied from the row selection unit 12 to the gate electrode of the selection transistor 25. The selection transistor 25 becomes conductive in response to the selection signal SEL, thereby transmitting a signal output from the amplification transistor 24 to the vertical signal line 31 with the pixel 2 in a selected state.

Readout processing in the pixel 2 in FIG. 2 will be schematically described. In an initial state, each of the selection signal SEL, the reset signal RST, and the transfer signal TRG is in a low state. Furthermore, since the photodiode 21 is exposed and the transfer transistor 22 is turned off by the transfer signal TRG in the low state, a charge generated by the exposure is accumulated in the photodiode 21.

The selection signal SEL is set to a high state at predetermined timing, and the selection transistor 25 is turned on. Next, the reset signal RST is set to a high state, and a charge of the FD is discharged to a power supply line of a voltage V_{DD}, so that the potential of the FD is reset to a predetermined potential. After a predetermined time has elapsed since the reset signal RST was returned to the low state, the transfer signal TRG is set to the high state, and the charge accumulated in the photodiode 21 by exposure is supplied to the FD and accumulated. A voltage corresponding to the charges accumulated in the FD is generated. The voltage is amplified by the amplification transistor 24, and transmitted to the vertical signal line 31 as a pixel signal via the selection transistor 25.

Here, at the timing when the state of the FD is stabilized after a predetermined time has elapsed since the reset signal RST was set to a high state, a signal A at a reset level (black level) output to the vertical signal line 31 is converted into a digital value by a corresponding analog-to-digital converter of the analog-to-digital conversion unit 14, and temporarily stored in, for example, a register of the analog-to-digital converter. The signal A is offset noise. The readout of the signal A is referred to as P-phase (pre-charge) readout, and a period in which the P-phase readout is performed is referred to as a P-phase period.

Moreover, for example, for example, at the timing when the state of the FD is stabilized after a treatment time has elapsed since the timing when the transfer signal TRG was set to the high state, a signal B at a signal level output to the vertical signal line 31 is converted into a digital value by the analog-to-digital converter, and temporarily stored in, for example, a register of the analog-to-digital converter. The signal B includes the offset noise and a pixel signal. The readout of the signal B is referred to as data phase (D-phase) readout, and a period in which the D-phase readout is performed is referred to as a D-phase period.

The analog-to-digital converter determines a difference between the stored signal A and signal B. A pixel signal from which the offset noise is removed can thereby be obtained.

Next, sweep-out scanning performed by the sweep-out scanning system in a pixel of FIG. 2 will be schematically described. In the sweep-out scanning, the transfer signal TRG and the reset signal RST are set to a high level, and the selection signal SEL is set to a low level. The cathode electrode of the photodiode 21 is connected to the power supply V_{DD}. A charge of the cathode electrode of the photodiode 21 is thereby discarded to the node of the power supply V_{DD}. After the sweep-out scanning, the transfer signal TRG is set to the low level, and the photodiode 21 is disconnected from the power supply V_{DD}. The electronic shutter operation is thereby executed, and charge accumulation can be started by photoelectric conversion to the photodiode 21.

Note that a circuit configuration in which connection is performed between the node of the power supply V_{DD} and the drain electrode of the amplification transistor 24 can be applied to the selection transistor 25. Furthermore, although FIG. 2 illustrates an example in which a pixel circuit of the pixel 2 has a 4Tr configuration including the transfer transistor 22, the reset transistor 23, the amplification transistor 24, and the selection transistor 25, that is, four transistors (Trs), this is not a limitation. For example, a 3Tr configuration in which the selection transistor 25 is omitted and the amplification transistor 24 has a function of the selection transistor 25 may be adopted. A 5Tr or more configuration with the increased number of transistors may be adopted as necessary.

(1-3. Configuration Example of Column-Parallel Analog-to-Digital Conversion Unit)

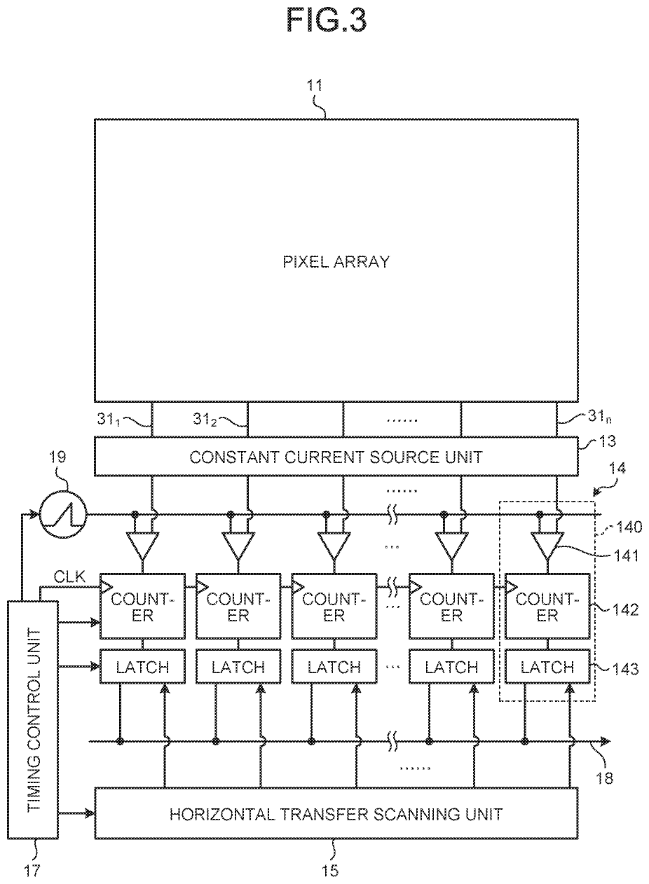

Next, a configuration example of the column-parallel analog-to-digital conversion unit 14 will be described. FIG. 3 is a block diagram illustrating one example of the configuration of the column-parallel analog-to-digital conversion unit 14 applicable to each embodiment. The analog-to-digital conversion unit 14 in the imaging element 1 of the present disclosure includes a set of a plurality of single-slope analog-to-digital converters provided corresponding to each of the vertical signal lines 31₁ to 31ₘ. Here, a single-slope analog-to-digital converter 140 of the nth column will be described in an example.

The single-slope analog-to-digital converter 140 has a circuit configuration including a comparator 141, a counter circuit 142, and a latch circuit 143. The single-slope analog-to-digital converter 140 uses a reference signal of a so-called RAMP waveform (slope waveform) in which a voltage value linearly changes over time. A reference signal generation unit 19 generates a reference signal of a ramp waveform. The reference signal generation unit 19 can include, for example, a digital-to-analog conversion circuit.

The comparator 141 uses an analog pixel signal read out from the pixel 2 as comparison input, and uses a reference signal of a ramp waveform generated by the reference signal generation unit 19 as reference input to compare both signals. Then, for example, when the reference signal is larger than the pixel signal, the output of the comparator 141 is in a first state (e.g., high level). When the reference signal is equal to or smaller than the pixel signal, the output of the comparator 141 is in a second state (e.g., low level). This causes the comparator 141 to output a pulse signal having a pulse width corresponding to the signal level of the pixel signal, specifically, the magnitude of the signal level.

A clock signal CLK is given from the timing control unit 17 to the counter circuit 142 at the same timing as the timing when supply of reference signals to the comparator 141 is started. Then, the counter circuit 142 performs count operation in synchronization with the clock signal CLK to measure the period of the pulse width of an output pulse of the comparator 141, that is, the period from the start of the comparison operation to the end of the comparison operation. The count result (count value) of the counter circuit 142 is a digital value obtained by digitizing the analog pixel signal.

The latch circuit 143 holds (latches) a digital value, which is a count result of the counter circuit 142. Furthermore, the latch circuit 143 takes a difference between a D-phase count value corresponding to a pixel signal at the signal level and a P-phase count value corresponding to a pixel signal at the reset level to perform correlated double sampling (CDS), which is one example of noise removal processing. Then, the latch circuit 143 outputs the latched digital value to the horizontal transfer line 18 under the drive of the horizontal transfer scanning unit 15.

As described above, the column-parallel analog-to-digital conversion unit 14 including a set of the single-slope analog-to-digital converters 140 acquires a digital value from information on time up to when the magnitude relation between a reference signal of a linearly changing analog value generated by the reference signal generation unit 19 and an analog pixel signal output from the pixel 2 is changed. Note that, although the single-slope analog-to-digital conversion unit 14 in which the analog-to-digital converter 140 is arranged in a one-to-one relation for a pixel column has been described in the above-described example, the analog-to-digital conversion unit 14 in which the single-slope analog-to-digital converter 140 is arranged in units of a plurality of pixel columns can also be adopted.

(1-4. Example of Chip Structure)

Next, an example of a chip structure of a CMOS image sensor serving as the imaging element 1 having the above-described configuration will be described. The imaging element 1 having the above-described configuration has a laminated chip (semiconductor integrated circuit) structure (laminated chip). Furthermore, the pixel 2 can have a back surface irradiation pixel structure. In the back surface irradiation pixel structure, a substrate surface on which a wire layer is formed is defined as a front surface, and light is applied from the back surface side opposite to the front surface. The pixel 2 can have a front surface irradiation pixel structure in which light is applied from the front surface side.

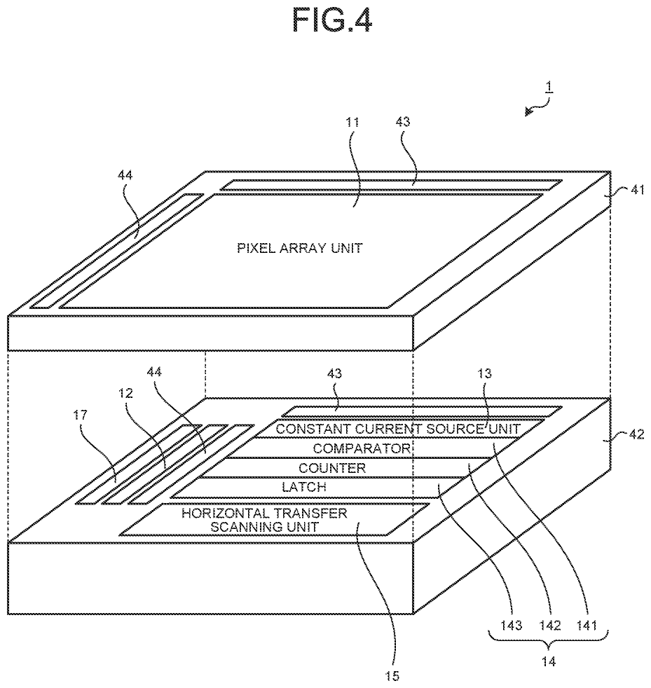

FIG. 4 is an exploded perspective view schematically illustrating a laminated chip structure of the imaging element 1 applicable to each embodiment. As illustrated in FIG. 4, the imaging element 1 has a laminated chip structure in which at least two semiconductor substrates of a first semiconductor substrate 41 and a second semiconductor substrate 42 are laminated and bonded. In the laminated structure, each pixel 2 of the pixel array unit 11, the control lines 32₁ to 32ₙ, and the vertical signal lines 31₁ to 31ₘ are formed in the first layer of the first semiconductor substrate 41. Furthermore, a pixel control unit is formed in the second layer of the second semiconductor substrate 42. The pixel control unit includes the row selection unit 12, the constant current source unit 13, the analog-to-digital conversion unit 14, the horizontal transfer scanning unit 15, the signal processing unit 16, the timing control unit 17, the reference signal generation unit 19, and the like. Note that, in FIG. 4, the signal processing unit 16 and the reference signal generation unit 19 are omitted to avoid complexity. The pixel control unit is a peripheral circuit unit of the pixel array unit 11. Then, the first layer of the first semiconductor substrate 41 and the second layer of the second semiconductor substrate 42 are electrically connected by connection units 43 and 44 such as a through chip via (TCV) and Cu—Cu hybrid bonding.

The imaging element 1 having the laminated structure needs a size (area) only large enough to form the pixel array unit 11 as the first layer of the first semiconductor substrate 41, so that the size (area) of the first semiconductor substrate 41 and thus the size of the entire chip can be reduced. Moreover, a process suitable for manufacturing the pixel 2 can be applied to the first layer of the first semiconductor substrate 41, and a process suitable for manufacturing the pixel control unit can be applied to the second layer of the second semiconductor substrate 42, so that the processes can be optimized when the imaging element 1 is manufactured. In particular, a cutting-edge process can be applied when the pixel control unit is manufactured.

Note that, although a two-layer laminated structure obtained by laminating the first semiconductor substrate 41 and the second semiconductor substrate 42 has been exemplified here, the laminated structure is not limited to the two-layer structure. A structure of three or more layers can be adopted. Then, in a case of a laminated structure of three or more layers, a pixel control unit, which includes the row selection unit 12, the constant current source unit 13, the analog-to-digital conversion unit 14, the horizontal transfer scanning unit 15, the signal processing unit 16, the timing control unit 17, the reference signal generation unit 19, and the like, can be distributed and formed in semiconductor substrates of the second and subsequent layers.

(1-5. Outline of Inspection According to Existing Technology)

By the way, in selecting a non-defective imaging element 1 and a defective imaging element 1, the presence or absence of an open (disconnection) of wires such as the control lines 32₁ to 32ₙ and the vertical signal lines 31₁ to 31ₘ and the presence or absence of a short circuit between adjacent wires are inspected. In the case of a three-dimensional laminated chip structure obtained by bonding the first semiconductor substrate 41 with the pixel array unit 11 and the second semiconductor substrate 42 with the pixel control unit illustrated with reference to FIG. 4, a non-defective product and a defective product are generally selected in inspection of the state of a wafer, which is a final shape after the first semiconductor substrate 41 and the second semiconductor substrate 42 are bonded.

A method of forming a laminated chip includes a method of bonding a wafer on a wafer (wafer on wafer (WOW)), a method of bonding a non-defective chip on a wafer (chip on wafer (COW)), and the like. Unlike the case of a WOW type laminated chip, a yield can be increased by selectively combining a non-defective product and a non-defective product in the case of a COW type laminated chip. Furthermore, also in the WOW method, wafers can be bonded at a position of a non-defective chip in an optimum combination.

In the case of the laminated chip structure in FIG. 4, only the NMOS transistor constitutes a pixel circuit as illustrated in FIG. 2 on the side of the first semiconductor substrate 41 by optimization of area efficiency and a process reduction viewpoint. Then, the pixel control unit, which is a peripheral circuit of the pixel array unit 11, is formed on the side of the second semiconductor substrate 42. That is, the pixel control unit is not mounted on the side of the first semiconductor substrate 41. Therefore, in the case of the COW type laminated chip, selecting a non-defective product and a defective product on the side of the first semiconductor substrate 41, which is a sensor substrate (pixel chip), before bonding is difficult, and a yield improvement effect is inhibited.

As described above, the first semiconductor substrate 41 and the second semiconductor substrate 42 are electrically connected by the connection units 43 and 44 such as a TCV and Cu—Cu hybrid bonding. The connection units 43 and 44 include a connection node to which the control lines 32₁ to 32ₙ and the vertical signal lines 31₁ to 31ₘ are connected. Then, the number of connection nodes of the connection units 43 and 44 is proportional to the number of pixels of the pixel array unit 11, and is several tens of thousands. Open/short circuit of wires of the control lines 32₁ to 32ₙ and the vertical signal lines 31₁ to 31ₘ can be inspected by mounting needle contact terminals on all the connection nodes. In contrast, the needle contact terminals have a size several tens of times larger than a terminal pitch and the number of terminals. Mounting the needle contact terminals on all the connection nodes are impractical in terms of area. Furthermore, mounting a large number of large-sized needle contact terminals leads to addition of an unnecessary parasitic capacitance, which may deteriorate performance.

### 2. Outline of Configuration According to Each Embodiment

Next, an outline of a configuration according to each embodiment will be described. An imaging element of a recent laminated structure tends to have higher defective rates of wires of the control lines 32₁ to 32ₙ and the vertical signal lines 31₁ to 31ₘ and the connection nodes of the connection units 43 and 44 than that of a pixel alone due to speeding up of multiple pixels. Therefore, in each embodiment of the present disclosure, the presence or absence of open/short circuit of a wire can be inspected by a small number of needle contact terminals by mainly checking only a wire layer and adding a minimum number of circuits in the first semiconductor substrate 41, which is a sensor substrate with the pixel array unit 11.

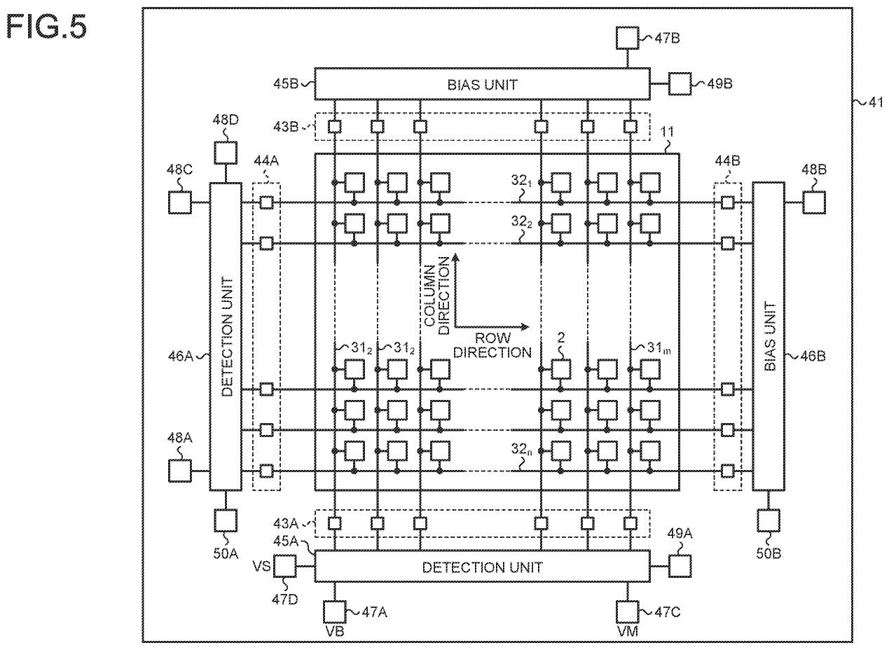

FIG. 5 illustrates a specific configuration example of the first semiconductor substrate 41 according to each embodiment. In the first semiconductor substrate 41, a first wire is formed in accordance with a first pixel row, and a second wire is formed in accordance with a second pixel row. Hereinafter, a wire formed in accordance with a pixel row is appropriately referred to as a row wire. Here, a first row wire formed in accordance with a pixel row refers to the control line 32₁ formed in accordance with the first pixel row. A second row wire formed in accordance with a pixel row refers to the control line 32ₙ formed in accordance with the nth pixel row. A plurality of row wires indicated as control lines 32₂ to 32ₙ₋₁ is provided between the first row wire and the second row wire.

Furthermore, in the first semiconductor substrate 41, a first column wire is formed in accordance with a first pixel column, and a second column wire is formed in accordance with a second pixel column. Hereinafter, a wire formed in accordance with a pixel column is appropriately referred to as a column wire. The first column wire formed in accordance with a pixel column refers to a vertical signal line 31₁ formed in accordance with the first pixel column. The second column wire formed in accordance with a pixel column refers to a vertical signal line 31ₘ formed in accordance with the mth pixel column. Then, a plurality of column wires indicated as vertical signal line 31₂ to 31ₘ₋₁ is provided between the first column wire and the second column wire.

As illustrated also in FIG. 4, the first semiconductor substrate 41 is provided with connection units 43A and 43B and connection units 44A and 44B, which connect the wires (control lines 32₁ to 32ₙ and vertical signal lines 31₁ to 31ₘ) on the first semiconductor substrate 41 and the pixel control unit on the second semiconductor substrate 42, which is a second substrate. Here, when a circuit of the pixel control unit to be connected is provided only on one side in the vertical direction, only one of the connection units 43A and 43B is required to be provided. For example, the vertical signal lines 31₁ to 31ₘ and the analog-to-digital conversion unit 14 are connected via the connection unit 43A. Similarly, when a circuit of the pixel control unit to be connected is provided only on one side in the horizontal direction, only one of the connection units 44A and 44B is required to be provided. For example, the control lines 32₁ to 32ₙ and the row selection unit 12 are connected via the connection unit 44A. Note that, when it is unnecessary to distinguish the connection units 43A and 43B, the connection units 43A and 43B are hereinafter collectively referred to as a connection unit 43.

The first semiconductor substrate 41 is further provided with a detection unit 45A, a bias unit 45B, a detection unit 46A, and a bias unit 46B. The bias unit 45B corresponds to the detection unit 45A. The bias unit 46B corresponds to the detection unit 46A.

The first semiconductor substrate 41 is further provided with the following terminals and electrodes in association with the detection unit 45A, the bias unit 45B, the detection unit 46A, and the bias unit 46B. That is, the first semiconductor substrate 41 is provided with terminals 47A and 47C, an electrode 47D, and a control terminal 49A, each of which is connected to the detection unit 45A. Furthermore, the first semiconductor substrate 41 is provided with terminals 48A and 48C, an electrode 48D, and a control terminal 50A, each of which is connected to the detection unit 46A. Furthermore, the first semiconductor substrate 41 is provided with a control terminal 49B and an electrode 47B, each of which is connected to the bias unit 45B. Moreover, the first semiconductor substrate 41 is provided with a control terminal 50B and an electrode 48B, each of which is connected to the bias unit 46B.

Each terminal, each electrode, and each control terminal provided on the first semiconductor substrate 41 serve as needle contact terminals used for inspection in a wafer state.

The bias unit 45B (first circuit) includes a bias circuit for applying a voltage to each of the vertical signal lines 31₁ to 31ₘ. The bias unit 45B connects the control terminal 49B with a part or all of the vertical signal lines 31₁ to 31ₘ by applying a predetermined voltage to the control terminal 49B. The detection unit 45A for detecting application of a voltage to the vertical signal lines 31₁ to 31ₘ is connected to a far end of the bias unit 45B of the vertical signal lines 31₁ to 31ₘ. The detection unit 45A (second circuit) can monitor, for example, the voltage of the terminal 47A from the terminal 47C. Furthermore, the detection unit 45A connects the electrode 49D with a part or all of the vertical signal lines 31₁ to 31ₘ by applying a predetermined voltage to the control terminal 49A.

Similarly, the bias unit 46B and the detection unit 46A are connected to the control lines 32₁ to 32ₙ. The bias unit 46B applies a voltage to each of the control lines 32₁ to 32ₙ. The detection unit 46A detects application of a voltage to each of the control lines 32₁ to 32ₙ.

Note that the detection units 45A and 46A and the bias units 45B and 46B arranged on the first semiconductor substrate 41 are not generally used after the first semiconductor substrate 41 and the second semiconductor substrate 42 are bonded and laminated.

According to each embodiment of the present disclosure, in the imaging element 1 having a three-dimensional laminated structure, the presence or absence of open/short circuit of a wire can be inspected by adding a small-scale circuit including the detection units 45A and 46A, the bias units 45B and 46B, the terminals 47A, 47C, 48A, and 48C, the electrodes 47B, 47D, 48B, and 48D, and the control terminals 49A, 49B, 50A, and 50B. This allows a good balance between inhibition of an increase in a chip area and improvement of a yield.

### 3. First Embodiment

Next, a first embodiment of the present disclosure will be described. The first embodiment is an example of the imaging element 1 for easily inspecting the presence or absence of an open (disconnection) of the vertical signal lines 31₁ to 31ₘ.

(3-0-1. Configuration Example of First Semiconductor Substrate According to First Embodiment)

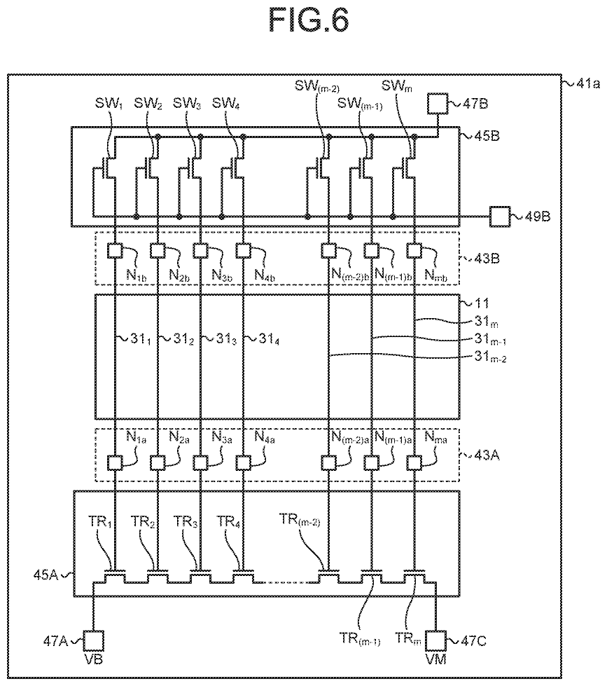

FIG. 6 illustrates an example of the configuration of a first semiconductor substrate 41a according to the first embodiment. Note that, in FIG. 6, the first semiconductor substrate 41a corresponds to the first semiconductor substrate 41 in FIG. 5, and is laminated on the second semiconductor substrate 42 to constitute the imaging element 1. Furthermore, in FIG. 6, each of the pixels 2 of the pixel array unit 11 and each of the control lines 32₁ to 32ₙ in FIG. 5 are omitted. Similarly, in FIG. 6, configurations in association with a pixel row (configurations in association with each of control lines 32₁ to 32ₙ) among the configurations in FIG. 5 are appropriately omitted.

In FIG. 6, the connection unit 43A includes connection nodes N₁ₐ, N₂ₐ, N₃ₐ, N₄ₐ, . . . , N₍ₘ₋₂₎ₐ, N₍ₘ₋₁₎ₐ, and Nₘₐ in the number corresponding to the number of columns (m) of the pixel array unit 11. Similarly, the connection unit 43B includes connection nodes N_{1b}, N_{2b}, N_{3b}, N_{4b}, . . . , N_{(m-2)b}, N_{(m-1)b}, and N_{mb} in the number corresponding to the number of columns (m) of the pixel array unit 11.

Ends of the vertical signal lines 31₁ to 31ₘ are respectively connected to the connection nodes N_{1b} to N_{mb} on a one-to-one basis. Similarly, the other ends of the vertical signal lines 31₁ to 31ₘ are respectively connected to the connection nodes N₁ₐ to Nₘₐ on a one-to-one basis.

The first semiconductor substrate 41 and the second semiconductor substrate 42 are electrically connected by each of the connection nodes N₁ₐ to Nₘₐ or each of the connection nodes N_{1b} to N_{mb}.

A bias unit 45Ba includes, as bias circuits, switch elements SW₁, SW₂, SW₃, SW₄, . . . , SW₍ₘ₋₂₎, SW₍ₘ₋₁₎, and SWₘ in the number corresponding to the number of columns (m) of the pixel array unit 11. Each of the switch elements SW₁ to SWₘ includes an NMOS transistor similarly to the pixel 2. The switch elements SW₁ to SWₘ include ends (drains) connected in common to the electrode 47B and the other ends (sources) respectively connected to ends of the vertical signal lines 31₁ to 31ₘ via the connection nodes N_{1b} to N_{mb} on a one-to-one basis.

A control terminal 49B is connected in common to control ends (gates) of the switch elements SW₁ to SWₘ. A high level voltage (e.g., 3 [V]) is applied to the control terminal 49B. Each of switch elements SW_{1b} to SW_{mb} thereby becomes on (conductive). The electrode 47B and each of the vertical signal lines 31₁ to 31ₘ are connected. The voltage applied to the electrode 47B is applied to each of the vertical signal lines 31₁ to 31ₘ. That is, each of the switch elements SW₁ to SWₘ can be considered as an output circuit that outputs a voltage to each of the vertical signal lines 31₁ to 31ₘ. Here, although voltage drop occurs at a threshold of each of the switch elements SW_{1b} to SW_{mb}, the influence of the voltage drop can be inhibited by increasing a voltage to be applied to the control terminal 49B to the extent allowed in terms of withstand voltage.

A detection unit 45Aa includes transfer elements TR₁, TR₁, TR₁, TR₁, . . . , TR₍ₘ₋₂₎, TR₍ₘ₋₁₎, and TRₘ in the number corresponding to the number of columns (m) of the pixel array unit 11. Each of the transfer elements TR₁ to TRₘ includes an NMOS transistor similarly to the pixel 2. The vertical signal lines 31₁ to 31ₘ are respectively connected to gates of the transfer elements TR₁ to TRₘ via the connection nodes N₁ₐ to Nₘₐ on a one-to-one basis.

That is, each of the transfer elements TR₁ to TRₘ can be considered as an input circuit to which a voltage to be applied to each of the vertical signal lines 31₁ to 31ₘ is input. Furthermore, each of the transfer elements TR₁ to TRₘ has a function as a switch whose states of conduction and non-conduction are controlled in accordance with the voltage input (applied) to the gate.

Furthermore, the transfer elements TR₁ to TRₘ are connected in series. The terminal 47A is connected to one end of the series connection. The terminal 47C is connected to the other end thereof.

More specifically, among the transfer elements TR₁ to TRₘ, the terminal 47A is connected to, for example, the drain of the transfer element TR₁ arranged at a left end in FIG. 6, and a source is connected to the drain of the transfer element TR₂ adjacent to the transfer element TR₁. The source of the transfer element TR₂ is connected to the drain of the transfer element TR₃ adjacent to the transfer element TR₂, and the source of the transfer element TR₃ is connected to the drain of the transfer element TR₄ adjacent to the transfer element TR₃. In this way, the sources of the transfer elements TR₁ to TR₍ₘ₋₁₎ are sequentially connected to the drains of the adjacent transfer elements. The source of the transfer element TR₍ₘ₋₁₎ is connected to the drain of the transfer element TRₘ- arranged at a right end in FIG. 6, and the source of the transfer element TRₘ is connected to the terminal 47C.

This configuration causes the electrode 47B to be connected to the gate of each of the transfer elements TR₁ to TRₘ.

Note that, in the following description, when it is unnecessary to distinguish the switch elements SW₁ to SWₘ, the switch elements SW₁ to SWₘ will be appropriately represented by a switch element SW. Similarly, when it is unnecessary to distinguish the transfer elements TR₁ to TRₘ, the description will be given by appropriately causing a transfer element TR to represent the transfer elements TR₁ to TRₘ.

Hereinafter, a mode in which the transistors (transfer elements TR₁ to TRₘ) are sequentially connected by the drain and source connection with an adjacent transistor as illustrated in FIG. 6 will be referred to as series connection. In the series connection, output is determined by a logical product of the states of gates in response to application of a voltage to the gates of the transistors. That is, when at least one of the transistors connected in series is off (non-conductive), both ends of the series connection are non-conductive.

Furthermore, although a specific example will be described later, a mode in which a plurality of transistors are provided with a drain and a source of each transistor being connected in common and with a gate of each transistor being independently connected is referred to as parallel connection. In the parallel connection, output is determined by a logical sum of the states of gates in response to application of a voltage to the gates of the transistors. That is, when at least one of the transistors connected in parallel is on (conductive), both ends of the parallel connection (place between source and drain connected in common) are conductive.

(3-0-2. Example of Inspection Method According to First Embodiment)

A method of inspecting the presence or absence of an open of the vertical signal lines 31₁ to 31ₘ (hereinafter, appropriately referred to as open inspection) in the configuration according to the first embodiment will be described more specifically. In the case of an example of the first embodiment, at the time of inspection, a probe (inspection needle) connected to a predetermined inspection device is brought into contact with the terminals 47A and 47C, the electrode 47B, and the control terminal 49A. The inspection device sets the electrode 47B to a predetermined high-level voltage (3 [V]), and also sets the control terminal 49B to a predetermined high-level voltage (3 [V]). In this case, if each of the vertical signal lines 31₁ to 31ₘ has no open portion, a voltage attenuated by a threshold value in each of the switch elements SW₁ to SWₘ (e.g., 2 [V]) is applied to each of the transfer elements TR₁ to TRₘ.

Note that the voltage attenuated by a threshold value, for example, 2 [V] is defined as a high-level voltage, and the high-level voltage is applied to a gate, so that each of the transfer elements TR₁ to TRₘ becomes on (conductive) Furthermore, a voltage lower than a predetermined voltage less than the high-level voltage is defined as a low-level voltage, and each of the transfer elements TR₁ to TRₘ becomes off (non-conductive).

In this state, the inspection device monitors (measures) a voltage VM of the terminal 47C by applying a voltage VB of, for example, 1 [V] to the terminal 47A as a voltage for inspection. If each of the vertical signal lines 31₁ to 31ₘ has no open (disconnection), a voltage VM of 1 [V] is detected at the terminal 47C.

In contrast, if each of the vertical signal lines 31₁ to 31ₘ has even one open (disconnection) portion, the voltage VB applied to the terminal 47A is not conducted from the terminal 47A to the terminal 47C, and the terminal 47C has an inconstant voltage VM.

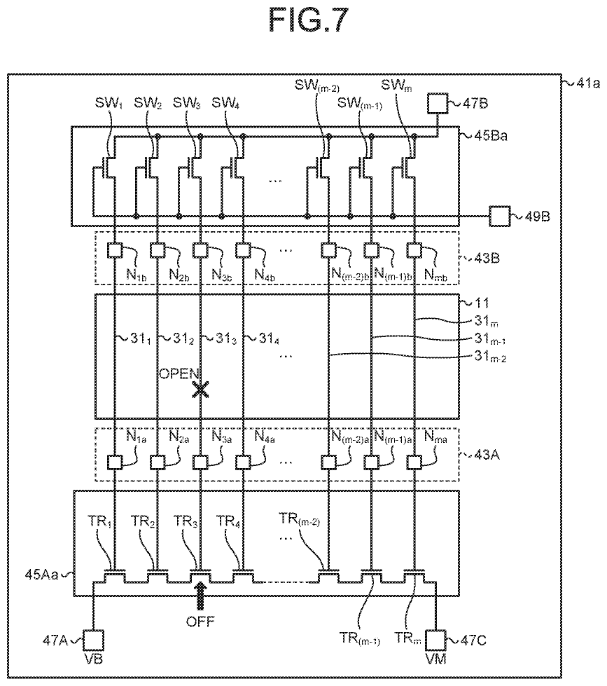

FIG. 7 illustrates open inspection according to the first embodiment. In the example of FIG. 7, in the first semiconductor substrate 41a, one vertical signal line 31₃ among the vertical signal lines 31₁ to 31ₘ has an open portion. In this case, the open (disconnection) of the vertical signal line 31₃ prevents a predetermined voltage from being applied to the gate of the transfer element TR₃, whose gate is connected to the vertical signal line 31₃, and the transfer element TR₃ becomes off (conductive). This blocks a path obtained by series connection of the transfer elements TR₁ to TRₘ, and causes the terminal 47C to have an inconstant voltage VM.

Therefore, according to the configuration of the first embodiment, whether or not one of the vertical signal lines 31₁ to 31ₘ has an open portion can be determined by monitoring the voltage VM of the terminal 47C. This allows determination of whether the first semiconductor substrate 41a is non-defective or defective.

(3-0-3. Structure Example of Needle Contact Terminal Applicable to Each Embodiment)

Next, a structure example of a needle contact terminal according to each embodiment will be described. Hereinafter, the description will be given by taking the first semiconductor substrate 41 as an example unless otherwise specified. All of the terminals 47A, 47C, 48A, and 48C, the electrodes 47D, 47B, 48B, and 48D, and the control terminals 49A, 49B, 50A, and 50B in the first semiconductor substrate 41 in FIG. 5 serve as needle contact terminals for a probe to be brought into contact with. In the example of FIG. 6, the terminals 47A and 47C, the electrode 47B, and the control terminal 49B serve as needle contact terminals.

The needle contact terminals need to have a fixed voltage when inspection ends and lamination on the second semiconductor substrate 42 is performed. One method of fixing a voltage of a needle contact terminal includes a method of wire-bonding a needle contact terminal as an external pad. In this method, an increase in a chip area, an increase in bonding process time, a yield loss in bonding, and the like may occur.

In each embodiment of the present disclosure, the first semiconductor substrate 41 provided with a needle contact terminal and the second semiconductor substrate 42 are laminated, so that the needle contact terminal is connected to a predetermined voltage, and the voltage of the needle contact terminal can be fixed.

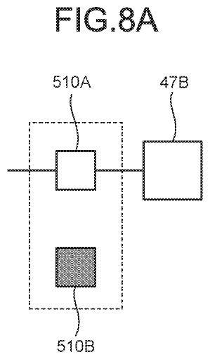

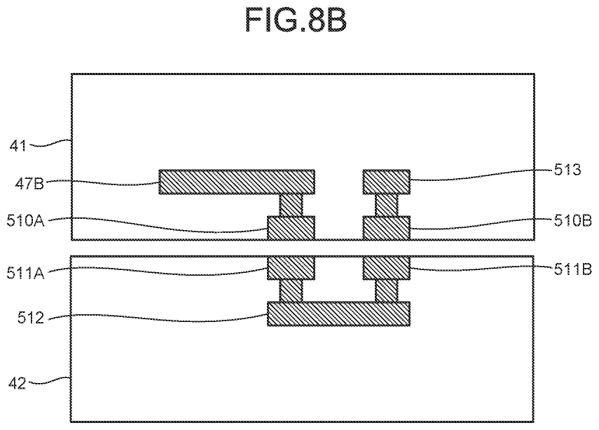

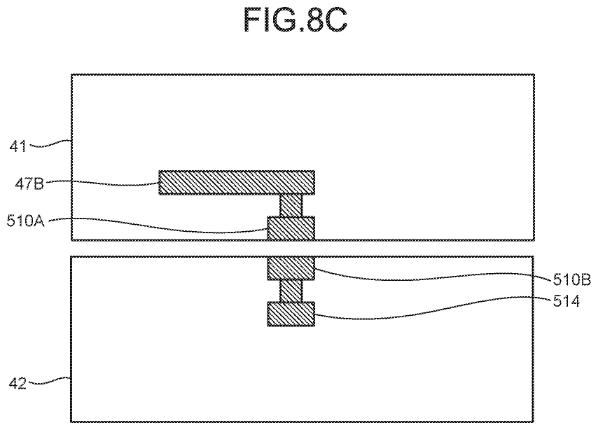

FIGS. 8A to 8C illustrate the structure example of a needle contact terminal according to each embodiment. FIG. 8A is a schematic diagram illustrating, for example, the electrode 47B and the vicinity thereof in the first semiconductor substrate 41. In FIG. 8A, in the first semiconductor substrate 41, a connection terminal 510A is arranged, and a connection terminal 510B is provided in the vicinity of the connection terminal 510A. The connection terminal 510A is connected to the electrode 47B. The connection terminal 510B is not connected to the electrode 47B and the connection terminal 510A in the first semiconductor substrate 41. Here, each of the connection terminals 510A and 510B is to be connected to a connection terminal (to be described later) provided on the second semiconductor substrate 42 by Cu—Cu hybrid bonding.

The first semiconductor substrate 41 and the second semiconductor substrate 42 are inspected alone without being laminated. Therefore, the connection terminal 510A and the connection terminal 510B serve as different nodes.

Here, the second semiconductor substrate 42 is configured such that the connection terminal 510A and the connection terminal 510B are electrically connected by bonding and laminating the first semiconductor substrate 41 and the second semiconductor substrate 42.

FIG. 8B is a cross-sectional view illustrating a first structure example in which the connection terminal 510A and the connection terminal 510B are electrically connected in a case where the first semiconductor substrate 41 and the second semiconductor substrate 42 are bonded and laminated. In FIG. 8B, connection terminals 511A and 511B are provided on the second semiconductor substrate 42 at positions respectively corresponding to the connection terminals 510A and 510B. These connection terminals 511A and 511B are connected by a wire 512 on the second semiconductor substrate 42. Furthermore, a terminal 513 to be connected to the connection terminal 510B is provided on the first semiconductor substrate 41.

In such configuration, the connection terminal 510A and the connection terminal 511A and the connection terminal 510B and the connection terminal 511B are connected by bonding the first semiconductor substrate 41 and the second semiconductor substrate 42. As a result, the connection terminal 510A, that is, the electrode 47B, and a terminal 513 are connected via the connection terminals 510A and 511A, the wire 512, and the connection terminals 510B and 511B. The voltage of the electrode 47B can be fixed by applying a predetermined voltage to the terminal 513.

FIG. 8C is a cross-sectional view illustrating a second structure example in which the connection terminal 510A and the connection terminal 510B are electrically connected in a case where the first semiconductor substrate 41 and the second semiconductor substrate 42 are bonded and laminated. In the second structure example, the connection terminal 510B is provided on the second semiconductor substrate 42 at a position corresponding to the connection terminal 510A. Furthermore, a terminal 514 to be connected to the connection terminal 510B is provided on the second semiconductor substrate 42.

In such configuration, the connection terminal 510A and the connection terminal 510B are connected by bonding the first semiconductor substrate 41 and the second semiconductor substrate 42. As a result, the connection terminal 510A, that is, the electrode 47B, and the terminal 514 are connected via the connection terminals 510B and 511B. The voltage of the electrode 47B can be fixed by applying a predetermined voltage to the terminal 514. The second structure is effective, for example, when an intermediate voltage (specific example thereof will be described later) is supplied from a power supply line arranged on the second semiconductor substrate 42.

(3-1. First Variation of First Embodiment)

Next, a first variation of the first embodiment will be described. The first variation of the first embodiment is an example of the imaging element 1. In the imaging element 1, each of the detection unit 45A and the bias unit 45B includes two systems of circuits. The imaging element 1 easily inspects the presence or absence of an open (disconnection) and the presence or absence of a short circuit between adjacent wires for the vertical signal lines 31₁ to 31ₘ.

(3-1-1. Configuration Example of First Semiconductor Substrate According to First Variation of First Embodiment)

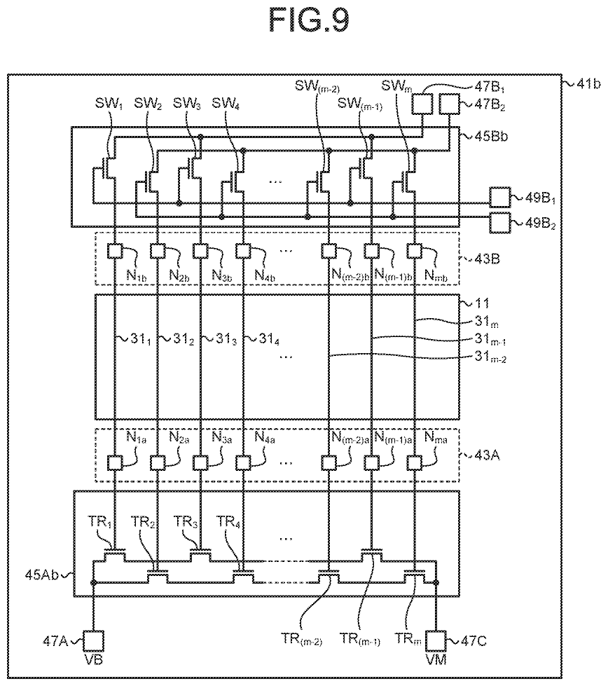

FIG. 9 illustrates an example of the configuration of a first semiconductor substrate 41b according to the first variation of the first embodiment. Note that FIG. 9 corresponds to FIG. 6 above, and the first semiconductor substrate 41b is laminated on the second semiconductor substrate 42 to constitute the imaging element 1.

In FIG. 9, a bias unit 45Bb includes, as bias circuits, switch elements SW₁, SW₂, SW₃, SW₄, . . . , SW_{(m-2)b}, SW₍ₘ₋₁₎, and SWₘ, each of which includes, for example, an NMOS transistor, in the number corresponding to the number of columns (m) of the pixel array unit 11.

In the first variation of the first embodiment, two electrodes 47B₁ and 47B₂ and two control terminals 49B₁ and 49B₂ are connected to the bias unit 45Bb. The bias circuit of the bias unit 45Bb includes two systems of circuits of a first system and a second system. The first system includes an electrode 47B₁ and a control terminal 49B₁. The second system includes an electrode 47B₂ and a control terminal 49B₂.

In the first system, ends (drains) of a plurality of (m/2 when m is even) switch elements selected every other switch element from the switch elements SW₁ to SWₘ are connected in common to the electrode 47B₁. Furthermore, control ends (gates) of a plurality of (m/2 when m is even) switch elements selected every other switch element from the switch elements SW₁ to SWₘ are connected in common to the control terminal 49B₁.

In the second system, ends (drains) of a plurality of switch elements selected from the switch elements SW₁ to SWₘ so as not to overlap the switch elements connected in common to the electrode 47B₁ are connected in common to the electrode 47B₂. Furthermore, the control terminal 49B₂ is connected in common to control ends (gates) of a plurality of switch elements selected from the switch elements SW₁ to SWₘ so as not to overlap the switch elements controlled in common by a voltage applied to the control terminal 49B₁.

For example, in FIG. 9, for each of the switch elements SW₁ to SWₘ, the switch element SW₁ at a left end is defined as the first switch element SW₁, and a number that increases toward a right end by one is attached to each of the switch elements SW₁ to SWₘ. In this case, in the first system, the electrode 47B₁ is connected in common to ends of the odd-numbered switch elements SW₁, SW₃, . . . , and SW₍ₘ₋₁₎. The control terminal 49B₁ is connected in common to control ends of the odd-numbered switch elements SW₁, SW₃, . . . , and SW₍ₘ₋₁₎.

Furthermore, in the second system, the electrode 47B₂ is connected in common to ends of the even-numbered switch elements SW₂, SW₄, . . . , and SWₘ. The control terminal 49B₂ is connected in common to control ends of the even-numbered switch elements SW₂, SW₄, . . . , and SWₘ.

The other ends of the switch elements SW₁ to SWₘ are respectively connected to the vertical signal lines 31₁ to 31ₘ via the connection nodes N_{1b} to N_{mb} on a one-to-one basis.

In FIG. 9, a detection unit 45Ab a detection unit 45Ab includes transfer elements TR₁, TR₁, TR₁, TR₁, . . . , TR₍ₘ₋₂₎, TR₍ₘ₋₁₎, and TRₘ, each of which includes, for example, an NMOS transistor, in the number corresponding to the number of columns (m) of the pixel array unit 11. The connection nodes N₁ₐ to Nₘₐ are respectively connected to the gates of the transfer elements TR₁ to TRₘ on a one-to-one basis.

Here, in the transfer elements TR₁ to TRₘ, a first group and a second group are connected with one end of a series connection and the other end of another series connection being in common. In the first group, a plurality of (m/2 when m is even) transfer elements selected every other transfer element from the transfer elements TR₁ to TRₘ is connected in series. In the second group, transfer elements, which are not included in the first group, from the transfer elements TR₁ to TRₘ are connected in series. One end common to the first group and the second group is connected to the terminal 47A, and the other end common thereto is connected to the terminal 47C. The first group corresponds to the above-described first system. The second group corresponds to the above-described second system.

In the example of FIG. 9, when, for the transfer elements TR₁ to TRₘ respectively connected to the connection nodes N₁ₐ to Nₘₐ on a one-to-one basis, the transfer element TR₁ connected to a connection node N₁ₐ at a left end is defined as the first transfer element TR₁, and a number that increases toward a right end by one is attached to each of the transfer elements TR₁ to TRₘ, the odd-numbered transfer elements TR₁, TR₃, . . . , and TR₍ₘ₋₁₎ are connected in series as the first group. Furthermore, the even-numbered transfer elements TR₂, TR₄, . . . , and TRₘ are connected in series as the second group.

For each of the first group and the second group, each drain of the transfer element with the smallest number is connected in common to the terminal 47A, and each source of the transfer element with the largest number is connected to the terminal 47C. In the example of FIG. 9, the drains of the transfer elements TR₁ and TR₂ are connected in common to the terminal 47A, and the sources of the transfer elements TR₍ₘ₋₁₎ and TRₘ are connected in common to the terminal 47A.

(3-1-2. Example of Inspection Method According to First Variation of First Embodiment)

A method of inspecting the presence or absence of an open between adjacent wires of the vertical signal lines 31₁ to 31ₘ (hereinafter, referred to as open inspection) in the configuration according to the first variation of the first embodiment will be described more specifically.

Prior to the description of the open inspection in the configuration according to the first variation of the first embodiment, in order to facilitate understanding, a case where erroneous detection occurs in the open inspection according to the configuration of the first embodiment described with reference to FIG. 6 will be described.

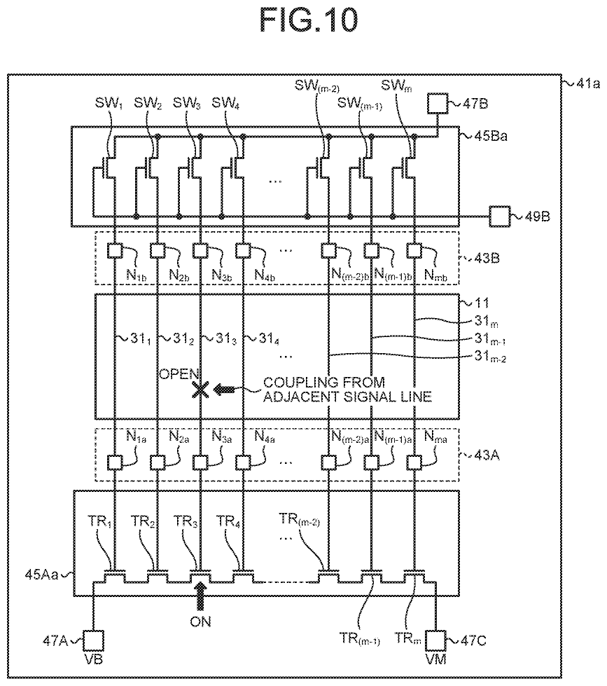

FIG. 10 illustrates erroneous detection that may occur in open inspection according to the configuration of the first embodiment (first semiconductor substrate 41a). In FIG. 10, the vertical signal line 31₃ has an open portion. In the configuration in FIG. 10, at the time of inspection, a high-level voltage is applied to the control terminal 49B to turn on each of the switch elements SW₁ to SWₘ, and a predetermined voltage is applied to each of the vertical signal lines 31₁ to 31ₘ. The vertical signal line 31₃ is in a floating state between the open portion and the gate of the transfer element TR₃.

Here, when each of the vertical signal lines 31₁ to 31ₘ has a distance narrower than a certain degree, coupling may occur between the vertical signal line 31₃ and an adjacent wire, for example, a vertical signal line 31₄. When the coupling occurs, the voltage of the vertical signal line 31₃ increases due to the influence of the voltage of the vertical signal line 31₄ in a place in the floating state between the open portion of the vertical signal line 31₃ and the transfer element TR₃. This may cause the transfer element TR₃ to become on, so that a place between the terminal 47A and the terminal 47C may become conductive. In this case, the open of the vertical signal line 31₃ is not correctly detected.

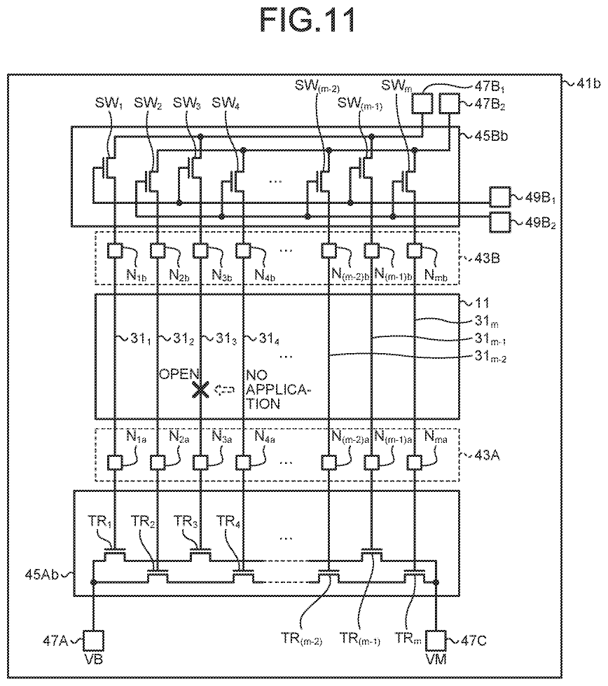

A method of performing open inspection for the vertical signal lines 31₁ to 31ₘ in the configuration according to the first variation of the first embodiment will be described more specifically. FIG. 11 illustrates open inspection according to the configuration of the first variation of the first embodiment (first semiconductor substrate 41b).

In the case of the first variation of the first embodiment, for the vertical signal lines 31₁ to 31ₘ, open inspection for the odd-numbered vertical signal lines 31₁, 31₃, . . . , and 31ₘ₋₁ and open inspection for the even-numbered vertical signal lines 31₂, 31₄, . . . , 31ₘ₋₂, and 31ₘ are individually performed.

For example, when the open inspection for the odd-numbered vertical signal lines 31₁, 31₃, . . . , and 31ₘ₋₁ is performed, for example, a probe connected to a predetermined inspection device is brought into contact with the terminals 47A and 47C, the electrodes 47B₁ and 47B₂, and control terminals 49A₁ and 49A₂. The inspection device sets the electrode 47B₁ to a predetermined voltage (3 [V]), and sets the electrode 47B₂ to 0 [V]. Each of the control terminals 49B₁ and 49B₂ is set to a predetermined voltage (3 [V]).

In this case, when each of the odd-numbered vertical signal lines 31₁, 31₃, . . . , and 31ₘ₋₁ has no open portion, a voltage attenuated by a threshold value in each of the odd-numbered switch elements SW₁, SW₃, . . . , and SW₍ₘ₋₁₎ (e.g., 2 [V]) is applied to a corresponding gate of each of the transfer elements TR₁, TR₃, . . . , and TR₍ₘ₋₁₎ included in the first group.

In contrast, a voltage of 0 [V] is applied to a gate of each of the even-numbered transfer elements TR₂, TR₄, . . . , TR_{(m-2)b}, and TRₘ included in the second group in accordance with the setting of the electrode 47B₂. Therefore, all the even-numbered transfer elements TR₂, TR₄, . . . , TR_{(m-2)b}, and TRₘ included in the second group become off.

In this state, the inspection device monitors (measures) the voltage VM of the terminal 47C by applying the voltage VB of, for example, 1 [V] to the terminal 47A. If all the odd-numbered vertical signal lines 31₁, 31₃, . . . , and 31₍ₘ₋₁₎ have no open, the voltage VM of 1 [V] is detected at the terminal 47C.

In contrast, if at least one of the odd-numbered vertical signal lines 31₁, 31₃, . . . , and 31₍ₘ₋₁₎ (vertical signal line 31₃) has an open, the voltage VB applied to the terminal 47A is not conducted from the terminal 47A to the terminal 47C, and the terminal 47C has an inconstant voltage VM.

In this case, as illustrated in FIG. 11, a voltage of 0 [V] is applied to the vertical signal lines 31₂ and 31₄ adjacent to both sides of the vertical signal line 31₃ having an open portion. Therefore, for example, erroneous detection due to coupling of the vertical signal line 31₄ to the vertical signal line 31₃ can be prevented.

Open inspection for the even-numbered vertical signal lines 31₂, 31₄, . . . , 31₍ₘ₋₂₎, and 31ₘ is similarly executed. In this case, the electrode 47B₁ is set to 0 [V], and the electrode 47B₂ is set to a predetermined voltage (e.g., 3 [V]). Note that each of the control terminals 49B₁ and 49B₂ is set to a predetermined voltage (3 [V]) similarly to the open inspection for odd-numbered vertical signal lines.

Note that, in the configuration of FIG. 11, open inspection similar to the above can be executed by making the control terminals 49B₁ and 49B₂ common with each other. Furthermore, open inspection similar to the above can be executed by allotting the terminal 47A and the terminal 47C for the odd-numbered vertical signal lines 31₁, 31₃, . . . , and 31₍ₘ₋₁₎ and the even-numbered vertical signal lines 31₂, 31₄, . . . , 31₍ₘ₋₂₎, and 31ₘ.

Note that, according to the first variation of the first embodiment, the presence or absence of a short circuit with an adjacent wire in the vertical signal lines 31₁ to 31ₘ can be inspected (referred to as short-circuit inspection). In the above-described open inspection, a voltage of 2 [V] or 0 [V] is applied every other vertical signal line to the vertical signal lines 31₁ to 31ₘ. Therefore, the presence or absence of a short circuit between adjacent wires can be detected by measuring the current of the electrodes 47B₁ and 47B₂.

In the first variation of the first embodiment, the voltage of a vertical signal line adjacent to a vertical signal line to be subject to open inspection can be set to 0 [V]. Therefore, even if there is a vertical signal line that is brought into a floating state by an open, erroneous detection accompanying an increase in voltage due to coupling with a vertical signal line adjacent to the vertical signal line can be inhibited.

(3-2. Second Variation of First Embodiment)

Next, a second variation of the first embodiment will be described. The second variation of the first embodiment is an example of the imaging element 1. Similarly to the above, the imaging element 1 easily inspects the presence or absence of an open (disconnection) and the presence or absence of a short circuit between adjacent wires for the vertical signal lines 31₁ to 31ₘ. Here, in the second variation of the first embodiment, each of a detection unit 45Ac and the bias unit 45B includes two systems of circuits. An electrode common to the two systems of circuits is connected to the bias unit 45B. Furthermore, the detection unit 45Ac is provided with a reset element RS that resets the floating state of each of the vertical signal lines 31₁ to 31ₘ.

(3-2-1. Configuration Example of First Semiconductor Substrate According to Second Variation of First Embodiment)

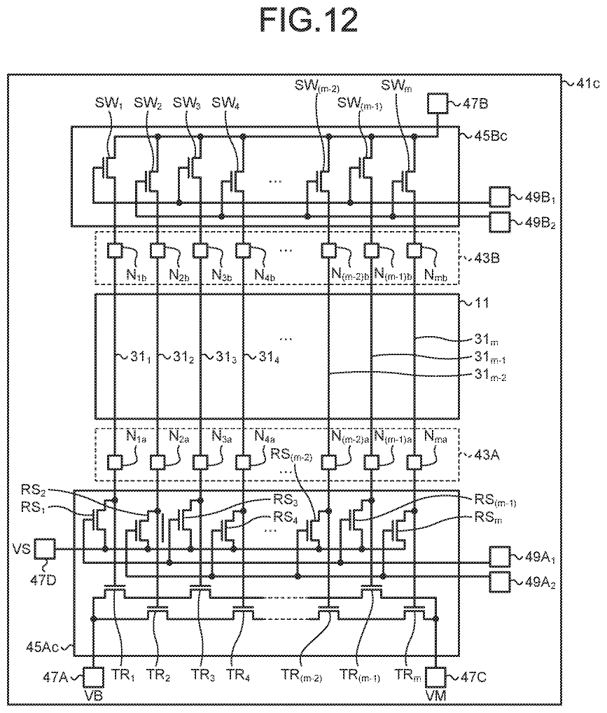

FIG. 12 illustrates an example of the configuration of a first semiconductor substrate 41c according to the second variation of the first embodiment. Note that FIG. 12 corresponds to FIG. 6 above, and the first semiconductor substrate 41c is laminated on the second semiconductor substrate 42 to constitute the imaging element 1.

In FIG. 12, a bias unit 45Bc includes, as bias circuits, switch elements SW₁, SW₂, SW₃, SW₄, . . . , SW₍ₘ₋₂₎, SW₍ₘ₋₁₎, and SWₘ, each of which includes, for example, an NMOS transistor, in the number corresponding to the number of columns (m) of the pixel array unit 11.

In the second variation of the first embodiment, the electrode 47B and the two control terminals 49B₁ and 49B₂ are connected to the bias unit 45Bc.

The bias circuit of the bias unit 45Bc includes two systems of circuits of a first system and a second system. The first system includes the control terminal 49B₁. The second system includes the control terminal 49B₂. Ends (drains) of the switch elements SW₁, SW₂, SW₃, SW₄, . . . , SW_{(m-2)b}, SW₍ₘ₋₁₎, and SWₘ included in the first system and the second system are connected in common to the electrode 47B. Furthermore, the other ends (sources) of the switch elements SW₁ to SWₘ are respectively connected to ends of the vertical signal lines 31₁ to 31ₘ via the connection nodes N_{1b} to N_{mb}.

In the bias unit 45Bc, the control ends (gates) of a plurality of (m/2 when m is even) switch elements selected every other switch element from the switch elements SW₁ to SWₘ are connected in common to the control terminal 49B₁. Furthermore, the control ends of a plurality of switch elements, which is selected from the switch elements SW₁ to SWₘ so as not to overlap the switch elements connected in common to the control terminal 49B₁, are connected in common to the control terminal 49B₂.

In the example of FIG. 12, the control ends of the odd-numbered switch elements SW₁, SW₃, . . . , and SW₍ₘ₋₁₎ are connected in common to the control terminal 49B₁. Furthermore, the control ends of the even-numbered switch elements SW_{2b}, SW₄, . . . , SW₍ₘ₋₂₎, and SWₘ are connected in common to the control terminal 49B₂.

The detection unit 45Ac according to the second variation of the first embodiment is obtained by adding reset elements RS₁, RS₂, RS₃, RS₄, . . . , RS₍ₘ₋₂₎, RS₍ₘ₋₁₎, and RSₘ, each of which is, for example, an NMOS transistor, in the number corresponding to the number of columns (m) of the pixel array unit 11, to the detection unit 45Ab in FIG. 9 in the connection unit 43B. Furthermore, the terminals 47A and 47C, the electrode 47D, and the control terminals 49A₁ and 49A₂ are connected to the detection unit 45Ac.

A drain of each of the reset elements RS₁ to RSₘ is connected to each of connection lines on a one-to-one basis. Each of the connection lines connects each of the connection nodes N₁ₐ to Nₘₐ with a gate of each of the transfer elements TR₁ to TRₘ. Sources of the reset elements RS₁ to RSₘ are connected in common to the electrode 47D.

Gates of a plurality of (m/2 when m is even) reset elements RS selected every other reset element from the reset elements RS₁ to RSₘ are connected in common to the control terminal 49A₁. Furthermore, the gates of a plurality of reset elements RS, which is selected from the reset elements RS₁ to RSₘ so as not to overlap the reset element RS to which the control terminal 49A₁ is connected, are connected in common to the control terminal 49A₂.

In the example of FIG. 12, gates of the odd-numbered reset elements RS₁, RS₃, . . . , and RS₍ₘ₋₁₎ are connected in common to the control terminal 49A₁. Furthermore, gates of the even-numbered reset elements RS₂, RS₄, . . . , RS₍ₘ₋₂₎, and RSₘ are connected in common to the control terminal 49A₂.

(3-2-2. Example of Inspection Method According to Second Variation of First Embodiment)

A method of inspecting the presence or absence of an open between adjacent wires of the vertical signal lines 31₁ to 31ₘ (hereinafter, referred to as open inspection) in the configuration according to the first variation of the first embodiment will be described more specifically.

Also in the second variation of the first embodiment, similarly to the above-described first variation of the first embodiment, for the vertical signal lines 31₁ to 31ₘ, open inspection for the odd-numbered vertical signal lines 31₁, 31₃, . . . , and 31ₘ₋₁ and open inspection for the even-numbered vertical signal lines 31₂, 31₄, . . . , 31ₘ₋₂, and 31ₘ are individually performed.

In one example, when the open inspection for the odd-numbered vertical signal lines 31₁, 31₃, . . . , and 31ₘ₋₁ is performed, for example, a probe connected to a predetermined inspection device is brought into contact with the terminals 47A and 47C, the electrodes 47B and 47D, and the control terminals 49A₁ and 49A₂. The inspection device sets the electrode 47B to a predetermined voltage (3 [V]), sets the control terminal 49B₁ to 3 [V], and sets the control terminal 49B₂ to a predetermined voltage (0 [V]).

A voltage VS of the electrode 47D connected to the detection unit 45Ac is set to a ground voltage, for example, 0 [V]. Furthermore, the control terminal 49A₁ is set to a predetermined voltage (0 [V]), and the control terminal 49A₂ is set to 3 [V].

In this case, similarly to the above-described first variation of the first embodiment, when each of the odd-numbered vertical signal lines 31₁, 31₃, . . . , and 31ₘ₋₁ has no open portion, a voltage attenuated by a threshold value in each of the odd-numbered switch elements SW₁, SW₃, . . . , and SW₍ₘ₋₁₎ (e.g., 2 [V]) is applied to a corresponding gate of each of the transfer elements TR₁, TR₃, . . . , and TR₍ₘ₋₁₎ included in the first group.

In contrast, a voltage of 0 [V] is applied to a gate of each of the even-numbered transfer elements TR₂, TR₄, . . . , TR₍ₘ₋₂₎, and TRₘ included in the second group in accordance with the setting of the control terminal 49A₂. Therefore, all the even-numbered transfer elements TR₂, TR₄, . . . , TR₍ₘ₋₂₎b, and TRₘ included in the second group become off.

In this state, the inspection device monitors (measures) the voltage VM of the terminal 47C by applying the voltage VB of, for example, 1 [V] to the terminal 47A. If all the odd-numbered vertical signal lines 31₁, 31₃, . . . , and 31₍ₘ₋₁₎ have no open, the voltage VM of 1 [V] is detected at the terminal 47C.

In contrast, if at least one of the odd-numbered vertical signal lines 31₁, 31₃, . . . , and 31₍ₘ₋₁₎ (vertical signal line 31₃) has an open, the voltage VB applied to the terminal 47A is not conducted from the terminal 47A to the terminal 47C, and the terminal 47C has an inconstant voltage VM.

Open inspection for the even-numbered vertical signal lines 31₂, 31₄, . . . , 31₍ₘ₋₂₎, and 31ₘ is similarly executed. In this case, the electrode 47B is set to a predetermined voltage (e.g., 3 [V]). The control terminals 49B₁ and 49B₂ are set by interchanging voltages in inspection for odd-numbered vertical signal lines. Specifically, the voltage of the control terminal 49A₁ is set to 0 [V], and the voltage of the control terminal 49A₂ is set to 3 [V]. Accordingly, the voltage of the control terminal 49B₂ connected to the detection unit 45Ac is set to 3 [V], and the voltage of the control terminal 49B₂ is set to 0 [V].

Here, in the second variation of the first embodiment, the voltages set for the control terminals 49A₁ and 49A₂ and the control terminals 49B₁ and 49B₂ are complementary at the gates of the switch element SW and the reset element RS connected to the same vertical signal line 31.

Specifically, in an example of the vertical signal line 31₂, the switch element SW₂ and the reset element RS₂ are connected to the vertical signal line 31₂. A voltage of, for example, 0 [V] is set to the control terminal 49B₁ connected to the gate of the switch element SW₂. A voltage of, for example, 3 [V] is set to the control terminal 49A₁ connected to the gate of the reset element RS₂. In contrast, when a voltage of, for example, 3 [V] is set to the control terminal 49B₁ connected to the gate of the switch element SW₂, a voltage of, for example, 0 [V] is set to the control terminal 49A₁ connected to the gate of the reset element RS₂.

Here, the description will be given by taking a case where a voltage of 0 [V] is set to the control terminal 49B₁ and a voltage of 3 [V] is set to the control terminal 49A₁ as an example. When the reset element RS₃ is not provided, 0 [V] is applied to the gate of the switch element SW₂, and thus the vertical signal line 31₂ connected to the source is brought into a floating state, and the voltage becomes inconstant.

In contrast, in the second variation of the first embodiment, the drain of the reset element RS₂ is connected to the vertical signal line 31₂. In the case, a source of the reset element RS₂ has the voltage VS of 0 [V] (or ground potential). A gate thereof has a voltage of 3 [V]. The reset element RS₂ is turned on. This causes the voltage of the vertical signal line 31₂ to be fixed to 0 [V], and avoids the vertical signal line 31₂ not to be inspected from being in the floating state.

Note that, according to the second variation of the first embodiment, similarly to the above-described first variation of the first embodiment, a short circuit with an adjacent wire in the vertical signal lines 31₁ to 31ₘ can be inspected. In the above-described open inspection, a voltage of 2 [V] or 0 [V] is applied every other vertical signal line to the vertical signal lines 31₁ to 31ₘ. Therefore, the presence or absence of a short circuit between adjacent wires can be detected by measuring the current of the electrodes 47B and 47D.

In the second variation of the first embodiment, the voltage of a vertical signal line adjacent to a vertical signal line to be subject to open inspection can be set to 0 [V]. Therefore, even if there is a vertical signal line that is brought into a floating state by an open, erroneous detection accompanying an increase in voltage due to coupling with a vertical signal line adjacent to the vertical signal line can be inhibited.

Furthermore, in the second variation of the first embodiment, a floating state of the vertical signal line 31 can be avoided by applying complementary voltages to the gates of the switch element SW and the reset element RS connected to the same vertical signal line 31, and more stable inspection can be performed.

Note that, although, in the description of the example of FIG. 12, an inspection device controls the settings of the complementary voltages to the control terminals 49A₁ and 49B₁ and the control terminals 49A₂ and 49B₂, this example is not a limitation. That is, for example, for input of one voltage, a circuit that generates the voltage and a voltage complementary to the voltage may be formed on the first semiconductor substrate 41c.

(3-3. Third Variation of First Embodiment)

Next, a third variation of the first embodiment will be described. The third variation of the first embodiment is an example obtained by adding a terminal for inputting the voltage VB for inspection or for extracting the monitoring voltage VM to, for example, the configuration according to the above-described second variation of the first embodiment.

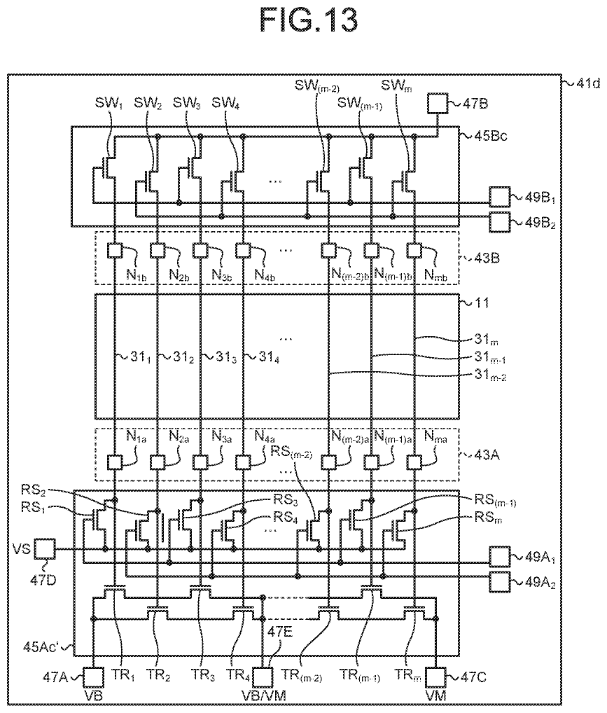

FIG. 13 illustrates an example of the configuration of a first semiconductor substrate according to the third variation of the first embodiment. A first semiconductor substrate 41d according to the third variation of the first embodiment is an example obtained by adding terminals at intermediate portions of the first group and the second group of the series connections of the detection unit 45Ac according to the above-described second variation of the first embodiment.

More specifically, as illustrated in FIG. 13, in the first semiconductor substrate 41d according to the third variation of the first embodiment, a terminal 47E is connected in common to an intermediate point of the series connection of the first group including the odd-numbered transfer elements TR₁, TR₃, . . . , and TR₍ₘ₋₁₎ and an intermediate point of the series connection of the second group including the even-numbered transfer elements TR₂, TR₄, . . . , TR₍ₘ₋₂₎, and TRₘ in a detection unit 45Ac′.

Note that, in the example of FIG. 13, for the sake of description, the terminal 47E is illustrated as being connected in common to a place between the transfer element TR₃ and the next transfer element in the first group and a place between the transfer element TR₄ and the next transfer element in the second group. Furthermore, vertical signal lines adjacent to the right and left of the intermediate point are defined as vertical signal lines 31ₖ₋₁ and 31ₖ (not illustrated) with 1<k<m.

The terminal 47E can be used as a terminal for applying the voltage VB for inspection. This is not a limitation, and the terminal 47E can also be used as a terminal for extracting the monitoring voltage VM. When the terminal 47E is used as a terminal for applying the voltage VB for inspection, the terminal 47A and the terminal 47C can be used as terminals for extracting the monitoring voltage VM. Furthermore, when the terminal 47E is used as a terminal for extracting the monitoring voltage VM, the terminal 47A and the terminal 47C can be used as terminals for inputting the voltage VB for inspection.

In any case, open inspection for the vertical signal line 31₁ at a left end to the vertical signal line 31ₖ₋₁ among the vertical signal lines 31₁ to 31ₘ and open inspection for the vertical signal lines 31ₖ to 31ₘ thereamong can be independently performed. This facilitates identification of an open position, and can reduce a burden of analysis.

Note that, although one terminal 47E is added between the terminals 47A and 47C in the example of FIG. 13, this example is not a limitation. Two or more terminals may be added. This allows the open position to be identified in more detail. Furthermore, the terminal 47E may be arranged not at central portions of the series connections of the first group and the second group but at a position close to either the right or the left. Moreover, when numerous transfer elements TR connected in series are provided, monitoring time can be shortened by providing one or more terminals 47E and dividing the function of the detection unit 45Ac′.

(3-4. Fourth Variation of First Embodiment)

Next, a fourth variation of the first embodiment will be described. The fourth variation of the first embodiment is an example obtained by allowing one or more specific transfer elements among the transfer elements TR₁ to TRₘ to be short-circuited in the configuration, in which the transfer elements TR₁ to TRₘ are connected in series, of the detection unit 45Aa described with reference to FIG. 6.

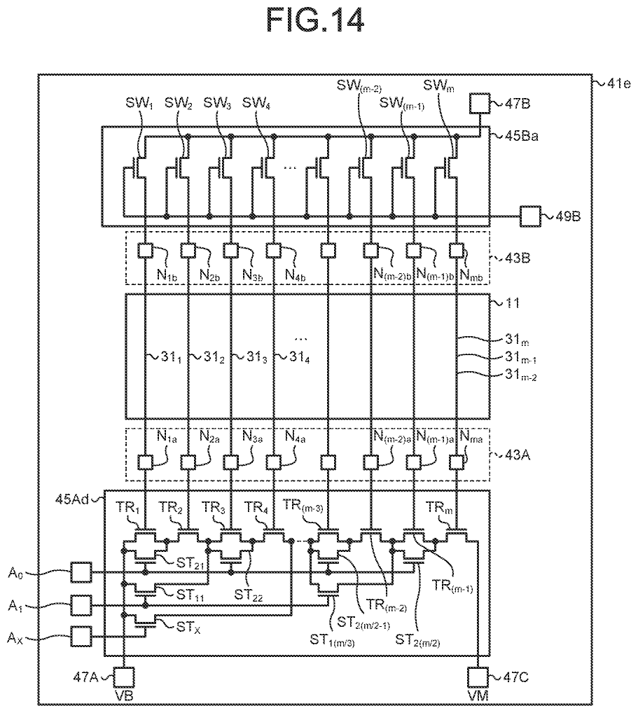

FIG. 14 illustrates an example of the configuration of a first semiconductor substrate according to the fourth variation of the first embodiment. In a first semiconductor substrate 41e in FIG. 14, a detection unit 45Ad is obtained by adding short-circuit elements ST₁₁, ST₁₂, . . . , ST_{1(m/2-1)}, and ST_{1(m/2)}, each of which includes an NMOS transistor, short-circuit elements ST₂₁, . . . , and ST_{2(m/3)}, and a short-circuit element ST_{X} to the detection unit 45Aa in FIG. 6. Furthermore, the detection unit 45d is obtained by adding terminals A₀, A₁, and A₂ for designating an address to the detection unit 45Aa in FIG. 6.

In these components, a source and a drain of each of the short-circuit elements ST₂₁, ST₂₂, . . . , ST_{2(m/2-1)}, and ST_{2(m/2)} are connected to a source and a drain of each of transfer elements TR selected every other transfer element from the transfer elements TR₁ to TRₘ, for example, each of the transfer elements TR₁, TR₃, . . . , TR₂₍ₘ₋₃₎, and TR₂₍ₘ₋₁₎. Furthermore, gates of the short-circuit elements ST₂₁, ST₂₂, . . . , ST_{2(m/2-1)}, and ST_{2(m/2)} are connected in common to the terminal A₀.

That is, a place between a source and a drain of each of the short-circuit elements ST₂₁, ST₂₂, . . . , ST_{2(m/2-1)}, and ST_{2(m/2)} becomes on (conductive) by setting the terminal A₀ to a high state. This causes each of the corresponding transfer elements TR₁, TR₃, . . . , TR₂₍ₘ₋₃₎, and TR₂₍ₘ₋₁₎ to be addressed, and a source and a drain of each of the transfer elements TR₁, TR₃, . . . , TR₂₍ₘ₋₃₎, and TR₂₍ₘ₋₁₎ are short-circuited. Therefore, open inspection can be selectively executed for the vertical signal lines 31₁, 31₃, . . . , 31₍ₘ₋₂₎, and 31ₘ among the vertical signal lines 31₁ to 31ₘ. The vertical signal lines 31₁, 31₃, . . . , 31₍ₘ₋₂₎, and 31ₘ are connected to transfer elements TR₂, TR₄, . . . , and TRₘ, whose source and drain are not short-circuited, among the transfer elements TR₁ to TRₘ.

In contrast, a source and a drain of each of the short-circuit elements ST₁₁, . . . , and ST_{1(m/3)} are connected to both ends of the series connection of sets of transfer elements obtained by selecting, every other set, sets of adjacent two transfer elements TR connected in series from the transfer elements TR₁ to TRₘ. In the example of FIG. 14, connection is performed to a source and a drain of each of a set of TR₁ and TR₂, . . . , and a set of TR₂₍ₘ₋₃₎ and TR₂₍ₘ₋₂₎ among the transfer elements TR₁ to TRₘ. Furthermore, gates of the short-circuit elements ST₁₁, . . . , and ST_{1(m/3)} are connected in common to the terminal A₁.

That is, a place between a source and a drain of each of the short-circuit elements ST₁₁, . . . , and ST_{1(m/3)} becomes on (conductive) by setting the terminal A₁ to a high state. This causes each of the corresponding set of the transfer elements TR₁ and TR₂, . . . , and a set of TR₂₍ₘ₋₃₎ and TR₂₍ₘ₋₂₎ to be addressed, and each of the set of the transfer elements TR₁ and TR₂, . . . , and the set of TR₂₍ₘ₋₃₎ and TR₂₍ₘ₋₂₎ is short-circuited. Therefore, open inspection can be selectively executed for the vertical signal lines 31₃, 31₄, . . . , 31₍ₘ₋₁₎, and 31ₘ among the vertical signal lines 31₁ to 31ₘ. The vertical signal lines 31₃, 31₄, . . . , 31₍ₘ₋₁₎, and 31ₘ are connected to a set of transfer elements TR₃ and TR₄, . . . , and a set of transfer elements TR₍ₘ₋₁₎ and TRₘ, whose source and drain are not short-circuited, among the transfer elements TR₁ to TRₘ.

The same applies to the short-circuit elements ST_{X} . . . . That is, a source and a drain of each of the short-circuit elements ST_{X}, . . . are connected to both ends of the series connection of sets of transfer elements obtained by selecting, every four sets, sets of adjacent two transfer elements TR connected in series from the transfer elements TR₁ to TRₘ. In the example of FIG. 14, connection is performed to a source and a drain of each of a set of TR₁ to TR₄, . . . among the transfer elements TR₁ to TRₘ. Furthermore, gates of the short-circuit elements ST_{X}, . . . are connected in common to the terminal A₂.

That is, a place between a source and a drain of each of the short-circuit element ST_{X}, . . . becomes on (conductive) by setting the terminal A₂ to a high state. Each of a corresponding set of transfer elements TR₁ to TR₄, . . . is addressed. Each of the set of the transfer elements TR₁ to TR₄, . . . is short-circuited. Therefore, open inspection can be selectively executed for the vertical signal line 31 among the vertical signal lines 31₁ to 31ₘ. The vertical signal line 31 is connected to each of sets of four transfer elements TR, whose source and drain are not short-circuited, among the transfer elements TR₁ to TRₘ.

In this way, in the fourth variation of the first embodiment, one or more specific transfer elements TR among the transfer elements TR₁ to TRₘ connected in series are addressed, and can be short-circuited. Therefore, open inspection for the vertical signal line 31 connected to the specific transfer element TR among the vertical signal lines 31₁ to 31ₘ can be invalidated, and the open portion can be easily identified. In the above-described example, open inspection for the odd-numbered vertical signal lines 31₁, 31₃, . . . among the vertical signal lines 31₁ to 31ₘ can be invalidated by setting the terminal A₀ to a high state. Open inspection for the even-numbered vertical signal lines 31₂, 31₄, . . . can be selectively executed.

Note that, although validity/invalidity of the open inspection for the vertical signal line 31 connected to a transfer element TR is set by short-circuiting the transfer element TR with a short-circuit element ST in the above description, this example is not a limitation. For example, the validity/invalidity of the open inspection for the vertical signal line 31 can be set by using another method, such as forcibly setting the gate of the transfer element TR to, for example, 3 [V].

### 4. Second Embodiment

Next, a second embodiment of the present disclosure will be described. In the above-described first embodiment, the configuration for executing open inspection and short-circuit inspection for the vertical signal lines 31₁ to 31ₘ has been described. In contrast, in the second embodiment, open inspection and short-circuit inspection for the control lines 32₁ to 32ₙ for each pixel row are executed.

(4-0-1. Configuration Example of First Semiconductor Substrate According to Second Embodiment)

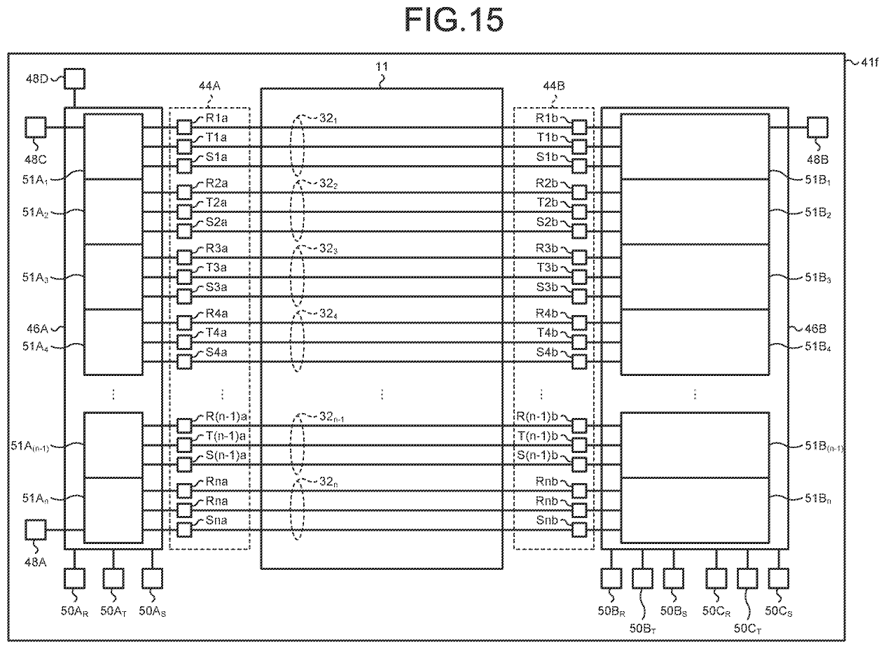

FIG. 15 illustrates an example of the configuration of a first semiconductor substrate according to the second embodiment. The configuration of a first semiconductor substrate 45f in FIG. 15 can be applied in combination with the configuration of each of the first semiconductor substrates described in the above-described first embodiment and the variations thereof.

Note that, in FIG. 15, each of the pixels 2 of the pixel array unit 11 and each of the vertical signal lines 31₁ to 31ₘ in FIG. 5 are omitted. Similarly, in FIG. 15, configurations in association with a pixel column (configurations in association with each of vertical signal lines 31₁ to 31ₘ) among the configurations in FIG. 5 are appropriately omitted.

In the example of FIG. 15, in the first semiconductor substrate 41f, each of the control lines 32₁ to 32ₙ for each pixel row includes three control lines. More specifically, each of the control lines 32₁ to 32ₙ includes a first control line, a second control line, and a third control line. The first control line transfers the reset signal RST. The second control line transfers the transfer signal TRG. The third control line transfers the selection signal SEL. Note that this example is not a limitation, and each of the control lines 32₁ to 32ₙ may include four or more control lines.

In the first semiconductor substrate 41f, the bias unit 46B includes n switch circuits 51B₁, 51B₂, . . . , and 51Bₙ provided to the control lines 32₁ to 32ₙ on a one-to-one basis. The control lines 32₁ to 32ₙ including three control lines are respectively connected to the switch circuits 51B₁ to 51Bₙ on a one-to-one basis. Furthermore, the electrode 48B, control terminals 50B_{R}, 50B_{T}, and 50B_{S}, and control terminals 50C_{R}, 50C_{T}, and 50C_{S} are connected to the bias unit 46B.

The electrode 48B, the control terminals 50B_{R}, 50B_{T}, and 50B_{S}, and the control terminals 50C_{R}, 50C_{T}, and 50C_{S} are connected in common to each of the switch circuits 51B₁ to 51Bₙ. The switch circuits 51B₁ to 51Bₙ and the control lines 32₁ to 32ₙ are connected by applying a predetermined voltage (e.g., 3 [V] to the electrode 48B. Note that the electrode 48B may be independently provided for each of the control terminals 50B_{R}, 50B_{T}, and 50B_{S} and the control terminals 50C_{R}, 50C_{T}, and 50C_{S}.

Three control lines included in each of the control lines 32₁ to 32ₙ are connected to the pixel array unit 11 and then the connection unit 44A via connection nodes R_{1b}, T_{1b}, and S_{1b}, R_{2b}, T_{2b}, and S_{3b}, R_{3b}, T_{3b}, and S_{3b}, R_{4b}, T_{4b}, and S_{4b}, . . . , R_{(n-1)b}, T_{(n-1)b}, and S_{(n-1)b}, and R_{nb}, T_{nb}, and S_{nb} included in the connection unit 44B.

In the connection unit 44A, three control lines included in each of the control lines 32₁ to 32ₙ are connected to the detection unit 46A via connection nodes R₁ₐ, T₁ₐ, and S₁ₐ, R₂ₐ, T₂ₐ, and S₃ₐ, R₃ₐ, T₃ₐ, and S₃ₐ, R₄ₐ, T₄ₐ, and S₄ₐ, . . . , R₍ₙ₋₁₎ₐ, T₍ₙ₋₁₎ₐ, and S₍ₙ₋₁₎ₐ, and Rₙₐ, Tₙₐ, and Sₙₐ included in the connection unit 44A.

The detection unit 46A includes n transfer circuits 51A₁, 51A₂, . . . , and 51Aₙ provided to the control lines 32₁ to 32ₙ on a one-to-one basis. The control lines 32₁ to 32ₙ including three control lines are respectively connected to the transfer circuits 51A₁ to 51Aₙ on a one-to-one basis. Furthermore, the electrode 48D, the terminals 48A and 48C, and the control terminals 50A_{R}, 50A_{T}, and 50A_{S} are connected to the detection unit 46A.

Note that, in the following description, when it is unnecessary to distinguish the switch circuits 51B₁ to 51Bₙ, the switch circuits 51B₁ to 51Bₙ will be appropriately represented by a switch circuit 51B. Similarly, when it is unnecessary to distinguish the transfer circuits 51A₁ to 51Aₙ, the description will be given by appropriately causing a transfer circuit 51A to represent the transfer circuits 51A₁ to 51Aₙ.

The electrode 48D and the control terminals 50A_{R}, 50A_{T}, and 50A_{S} are connected in common to each of the transfer circuits 51A₁ to 51Aₙ. Furthermore, the terminals 48A and 48C are respectively connected to the transfer circuits 51A₁ and 51Aₙ at both ends of the transfer circuits 51A₁ to 51Aₙ. Such configuration causes the terminals 48A and 48C to be connected to a transfer circuit group including the transfer circuits 51A₁ to 51Aₙ.

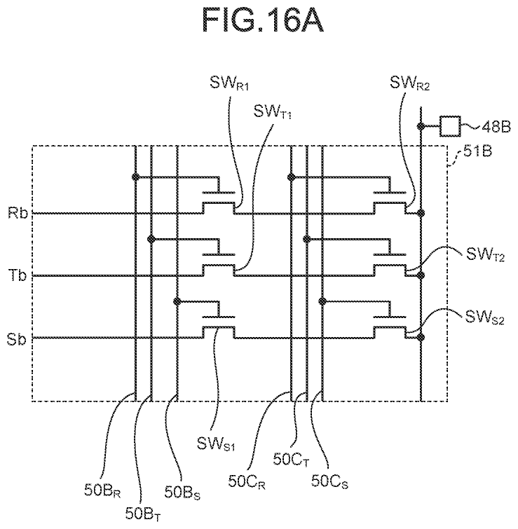

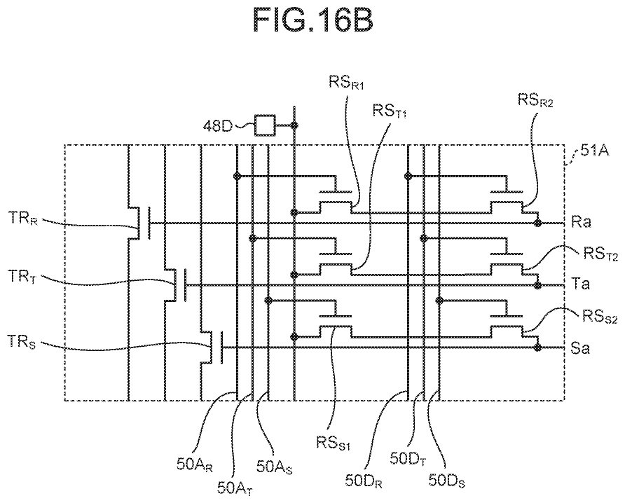

FIG. 16A is a circuit diagram of one example of the switch circuit 51B₁ according to the second embodiment. Note that the switch circuits 51B₂ to 51ₙ have the same configuration as the switch circuit 51B₁, and thus the switch circuits 51B₂ to 51ₙ will be represented by the switch circuit 51B₁ in the following description.

The switch circuit 51B₁ includes a set of switch elements SW_{R1}, SW_{T1}, and SW_{S1} and a set of switch elements SW_{R2}, SW_{T2}, and SW_{S2}. Each of the switch elements is, for example, an NMOS transistor. A drain of each of the switch elements SW_{R2}, SW_{T2}, and SW_{S2} is connected to the electrode 48B. A source of each of the switch elements SW_{R2}, SW_{T2}, and SW_{S2} is connected to a drain of each of the switch elements SW_{R1}, SW_{T1}, and SW_{S1}. Sources of the switch elements SW_{R1}, SW_{T1}, and SW_{S1} are respectively connected to a first control line, a second control line, and a third control line via terminals Rb, Tb, and Sb.

The control terminals 50B_{R}, 50B_{T}, and 50B_{S} are respectively connected to gates of the switch elements SW_{R1}, SW_{T1}, and SW_{S1}. Similarly, the control terminals 50C_{R}, 50C_{T}, and 50C_{S} are respectively connected to gates of the switch elements SW_{R2}, SW_{T2}, and SW_{S2}.

That is, when the control terminals 50B_{R} and 50C_{R} have a high-level voltage (e.g., 3 [V]), the voltage set to the electrode 48B is applied to the first control line that transfers the reset signal RST via the switch elements SW_{R2} and SW_{R1}. Furthermore, when the control terminals 50B_{T} and 50C_{T} have a high-level voltage (e.g., 3 [V]), the voltage set to the electrode 48B is applied to the second control line that transfers the transfer signal TRG via the switch elements SW_{T2} and SW_{T1}. Furthermore, when the control terminals 50B_{S} and 50C_{S} have a high-level voltage (e.g., 3 [V]), the voltage set to the electrode 48B is applied to the third control line that transfers the selection signal SEL via the switch elements SW_{S2} and SW_{S1}. That is, the switch elements SW_{S2} and SW_{S1} function as output units that output a voltage to the third control line.

In this way, the switch circuit 51B₁ can select which of the first control line, the second control line, and the third control line the voltage applied to the electrode 48D is applied to by setting a predetermined voltage to each of a set of the control terminals 50B_{R} and 50C_{R}, a set of the control terminals 50B_{T} and 50C_{T}, and a set of the control terminals 50B_{S} and 50C_{S}.

FIG. 16B is a circuit diagram of one example of the transfer circuit 51A₁ according to the second embodiment. Note that the transfer circuits 51A₂ to 51Aₙ have the same configuration as the transfer circuit 51A₁, and thus the transfer circuits 51A₂ to 51Aₙ will be represented by the transfer circuit 51A₁ in the following description. Furthermore, in the following, for the sake of description, the detection unit 46A has a function corresponding to the detection unit 45Aa, in which the transfer elements TR₁ to TRₘ are connected in series, illustrated in FIG. 6. That is, the detection unit 46A performs open inspection for each of the control lines 32₁ to 32ₙ by applying a predetermined voltage VB (e.g., 1 [V]) to the terminal 48A and monitoring the voltage VM at the terminal 48C.

In the transfer circuit A₁, the first control line, the second control line, and the third control line are respectively connected to the gates of the transfer elements TR_{R}, TR_{T}, and TR_{S}, each of which is an NMOS transistor. Furthermore, in the transfer circuits 51A₁, 51A₂, . . . , and 51Aₙ of the detection unit 46A, for example, the transfer elements TR_{R} are connected in series through the transfer circuits 51A₁, 51A₂, . . . , and 51Aₙ. Similarly, other transfer elements TR_{T} and TR_{S} are connected in series through the transfer circuits 51A₁, 51A₂, . . . , and 51Aₙ.

Ends on a drain side of the series connection of the transfer elements TR_{R}, TR_{T}, and TR_{S} connected in series through the transfer circuits 51A₁, 51A₂, . . . , and 51Aₙ are connected in common to the terminal 47C, and ends on a source side are connected in common to the terminal 47A.

The transfer circuit 51A₁ includes a set of reset elements RS_{R1}, RS_{T1}, and RS_{S1}, each of which is an NMOS transistor, and a set of reset elements RS_{R2}, RS_{T2}, and RS_{S2}. For example, a source of the reset element RS_{R2} is connected to the first control line via a terminal Ra, and a drain thereof is connected to the source of the reset element RS_{R1}. The drain of the reset element RS_{R1} is connected to the electrode 48D in common with the drains of the other reset elements RS_{T1} and RS_{S1}.

Furthermore, the gate of the reset element RS_{R1} is connected to the control terminal 50A_{R}, and the gate of the reset element RS_{R2} is connected to a control terminal 50D_{R}. Similarly, gates of the reset elements RS_{T1} and RS_{T2} and the reset elements RS_{S1} and RS_{S2} are connected to the control terminals A_{T} and A_{S}.

For example, the reset elements RS_{R1} and RS_{R2} are turned on by setting a high-level voltage (e.g., 3 [V]) to both the control terminals 50A_{R} and 50D_{R}. The voltage set to the electrode 48D is applied from the terminal Ra to the first control line.

In one example, when the control terminals 50B_{R} and 50C_{R} have a voltage of 0 [V] in the above-described switch circuit 51B₁, the first control line, which transfers the reset signal RST, of the control line 32₁ connected to the switch circuit 51B₁ is in a floating state. In this state, 0 [V] is applied to the electrode 48D, and a voltage of, for example, 3 [V] is set to the control terminals 50A_{R} and 50D_{R}. The voltage of the electrode 48D is thereby applied to the first control line. The voltage of the first control line can be fixed to 0 [V].

(4-0-2. Example of Inspection Method According to Second Embodiment)

Next, an example of an inspection method according to the second embodiment will be described. Here, open inspection for the first control line that transfers the reset signal RST among the three control lines included in the control line 32₁ will be described.

In the switch circuit 51B₁, a predetermined voltage (e.g., 3 [V]) is applied to the electrode 48B while a high-level voltage (e.g., 3 [V]) is set to the control terminals 50B_{R} and 50C_{R} and a low-level voltage (e.g., 0 [V]) is set to the control terminals 50B_{T} and C_{T} and control terminals B_{S} and C_{S}. In contrast, in the transfer circuit 51A₁, a predetermined voltage (e.g., 0 [V]) is applied to the electrode 48D while a low-level voltage (e.g., 0 [V]) is set to each of the control terminals 50A_{R} and 50D_{R}. Furthermore, a high-level voltage (e.g., 3 [V]) is set to each of the control terminals 50A_{T} and 50D_{T} and the control terminals 50A_{S} and 50D_{S}.

In this state, for example, 1 [V] is set to the terminal 48A as the voltage VB for inspection, and the voltage VM of the terminal 48C is monitored.

Here, in each of the switch circuits 51B₁ to 51Bₙ, each of the switch elements T₁ and S₁ and the switch elements T₂ and S₂ is turned off. Furthermore, in each of the transfer circuits 51A₁ to 51Aₙ, each of the reset elements RS_{T1} and RS_{S1} and the reset elements RS_{T2} and RS_{S2} is turned on, and a voltage of 0 [V] is applied to the electrode 48D. Therefore, in each of the switch circuits 51B₁ to 51Bₙ, all the transfer elements TR_{T} and TR_{S} are turned off while all the transfer elements TR_{R} are turned on (when there is no open).

Therefore, whether or not the first control line that transfers the reset signal RST has an open in at least one control line of the control lines 32₁ to 32ₙ can be inspected by monitoring the voltage VM of the terminal 48C.

(4-0-3. Detailed Description of Bias Circuit According to Second Embodiment)

In the switch circuit 51B₁ in FIG. 16A, two switch elements SW_{R1} and SW_{R2} are connected in series in, for example, a path for applying a voltage to the first control line. The reason will be described below.

In controlling the transfer transistor 22, the reset transistor 23, and the selection transistor 25 of the pixel 2, a voltage equal to or higher than the withstand voltages of the transistors may be applied. For example, a voltage of −1 [V] may be applied at the time of a low voltage in contrast to a voltage of 3 [V] applied at the time of a high voltage. Although there is no problem at the time of inspection, a problem occurs at the time of actual circuit operation in a case where the first semiconductor substrate 41 (first semiconductor substrate 41e) and the second semiconductor substrate 42 are bonded and laminated.

The description will be given by taking the reset transistor 23 as an example. For example, a voltage of −1 [V] is applied to the terminals Ra and Rb for applying the reset signal RST to the reset transistor 23. At this time, the electrode 48D and the electrode 48B have a voltage desirably fixed to −1 [V]. Furthermore, at least one of the control terminal 50B_{R} and the control terminal 50C_{R} needs to have a voltage fixed to −1 [V]. Similarly, at least one of the control terminal 50A_{R} and the control terminal 50D_{R} needs to have a voltage fixed to −1 [V]. This can prevent leakage to the electrode 48B and the electrode 48D.

Furthermore, a case where 3 [V] is applied at the time of a high voltage will be considered. Here, for example, the reset transistor 23 is assumed to have a gate withstand voltage of approximately 3 [V]. As described above, a voltage of −1 [V] is applied to the terminals Ra and Rb for applying the reset signal RST to the reset transistor 23. At this time, for example, the voltages of the control terminal 50B_{R} and the control terminal 50D_{R} are fixed to −1 [V]. In this case, the potential difference applied to the gate of the reset transistor 23 is 4 [V], which causes concern in terms of reliability.

In order to address the concern, the voltages of the control terminal 50B_{R} and the control terminal 50D_{R} are fixed to a voltage higher than −1 [V]. The voltage may be 0 [V], or may be a low voltage used in a circuit, for example, 1 [V]. In this case, from the viewpoint of leakage, the control terminal 50C_{R} and the control terminal 50A_{R} need to have a voltage fixed to −1 [V]. The voltage has been dropped by the control terminal 50B_{R} and the control terminal 50D_{R}. A potential difference equal to or larger than the withstand voltage can be prevented from being applied.

Note that, when a transistor has a sufficient withstand voltage, the two switch elements SW_{R1} and SW_{R2} are not necessarily required to be connected in series. One switch element SW may be applied to one control line. Furthermore, the configuration of the series connection of the two switch elements SW_{R1} and SW_{R2} can be applied to the bias unit 45B that applies a voltage to the vertical signal lines 31₁ to 31ₘ. The bias unit 45B has been described in the first embodiment and the variations thereof.

### 5. Third Embodiment

(5-0-1. Configuration Example of First Semiconductor Substrate According to Third Embodiment)

Next, a third embodiment of the present disclosure will be described. In the third embodiment, a plurality of pixels 2 included in one pixel row is used as a bias circuit that applies a voltage to the vertical signal lines 31₁ to 31ₘ.

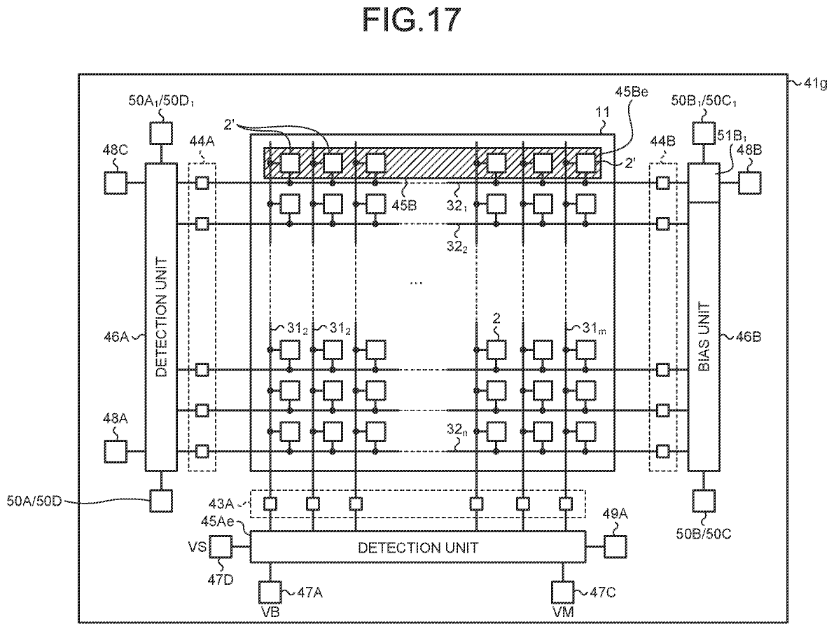

FIG. 17 illustrates an example of the configuration of a first semiconductor substrate according to the second embodiment. In a first semiconductor substrate 41g in FIG. 17, a bias unit 45Be includes m pixels 2′ connected to the first row of the pixel array unit 11 (row at upper end of pixel array unit 11). Note that the same configuration as that described with reference to FIG. 2 can be applied to the configuration of the pixel 2′, and thus the description thereof will be omitted here. For example, a row included in a region called an optical black region of an outer peripheral portion in a pixel region in which the pixel 2 of the pixel array unit 11 is arranged can be used as the bias unit 45Be.

In the configuration of FIG. 17, each of the pixels 2′ included in the bias unit 45Be is controlled by the switch circuit 51B₁ corresponding to the first row among the switch circuits 51B₁ to 51Bₙ included in the bias unit 46B for biasing each row described with reference to FIGS. 15, 16A, and 16B.

Control terminals 50B₁ and 50C₁ are connected to a bias unit 46C. Each of the pixels 2′ included in the bias unit 45Be is controlled by voltages applied to these control terminals 50B₁ and 50C₁. Here, in FIG. 17, the control terminal 50B₁ includes the control terminals 50B_{R}, 50B_{T}, and 50B_{S} described with reference to FIG. 16B. Similarly, the control terminal 50C₁ includes the control terminals 50C_{R}, 50C_{T}, and 50C_{S} described with reference to FIG. 16B.

Note that a detection unit 45Ae can be applied to any of the configurations of the detection units 45Aa to 45Ad described in the first embodiment and the variations thereof.

(5-0-2. Example of Inspection Method According to Third Embodiment)

The control terminals 50B₁ and 50C₁ are set as follows, for example, when open inspection is performed for the vertical signal lines 31₁ to 31ₘ. Referring to FIGS. 2 and 16B, the voltage of the power supply V_{DD} supplied to the pixel 2 is set to 3 [V]. The voltages of the control terminals 50B_{R} and 50C_{R} and the control terminals 50B_{S} and 50C_{S} are set to 3 [V]. The control terminals 50B_{R} and 50C_{R} and the control terminals 50B_{S} and 50C_{S} are connected to gates of the switch elements SW_{R1} and SW_{R2} and the switch elements SW_{S1} and SW_{S2}. The switch elements SW_{R1} and SW_{R2} are connected to the gate of the reset transistor 23. The switch elements SW_{S1} and SW_{S2} are connected to the gate of the selection transistor 25. Furthermore, the voltages of the control terminals 50B_{T} and 50C_{T} connected to the gates of the switch elements SW_{T1} and SW_{T2} connected to the transfer transistor 22 are fixed to 0 [V].

The voltages of the control terminals 50B_{R}, 50B_{T}, and 50B_{S} and the control terminals 50C_{R}, 50C_{T}, and 50C_{S} are set in this way, so that the power supply V_{DD} and the vertical signal line 31 are connected, and a potential of the vertical signal line 31 can be set to a high level through the pixel 2′.

Furthermore, when the voltages to be applied to the gates of the selection transistors 25 of the pixels 2′ can be individually set for, for example, the odd-numbered vertical signal lines 31₁, 31₃, . . . and the even-numbered vertical signal lines 31₂, 31₄, . . . , adjacent two vertical signal lines 31 of the vertical signal lines 31₁ to 31ₘ can be set to each of a high level and a low level. This allows short-circuit inspection.

Furthermore, according to the configuration of the third embodiment, the bias unit 45B is not required to be arranged outside the pixel array unit 11 to the first semiconductor substrate 41, which allows effective use of the substrate area.

(5-1. Another Example of Third Embodiment)

Although, in the example of FIG. 17, the bias unit 45Be is described as including m pixels 2′ connected to the first row of the pixel array unit 11, this example is not a limitation. The bias unit 45Be can be configured in any row among rows included in the pixel array unit 11.

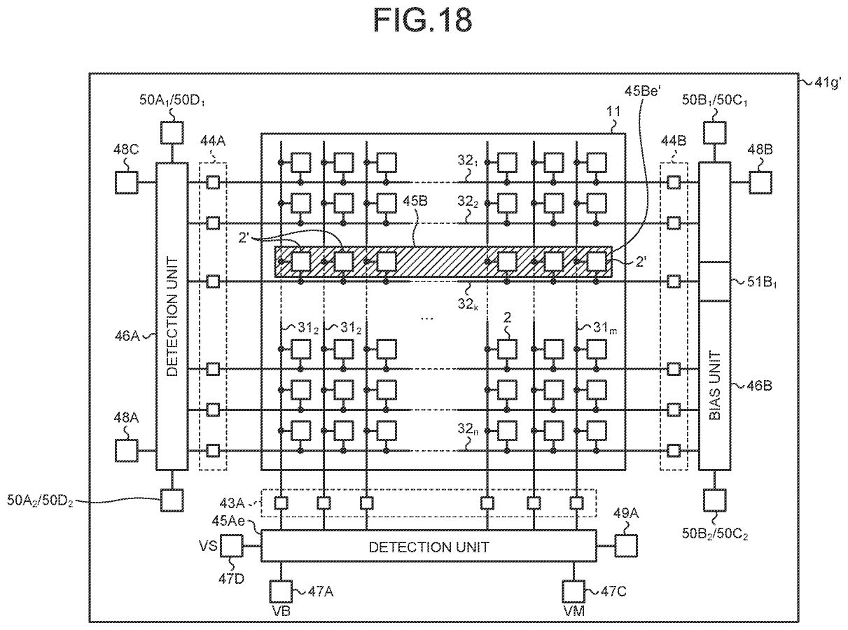

FIG. 18 illustrates another example of the configuration of a first semiconductor substrate according to the third embodiment. In a first semiconductor substrate 41g′ in FIG. 18, a bias unit 45Be′ includes a plurality of pixels 2′ included in the kth (1<k<n) pixel row among the first to nth pixel rows included in the pixel array unit 11. Furthermore, each of the pixels 2′ included in the bias unit 45Be is controlled by a switch circuit 51Bₖ corresponding to the kth row among the switch circuits 51B included in the bias unit 46B.

In one example, the bias unit 45Be′ can be set at, for example, a central portion of the pixel array unit 11, and the detection units 45A can be arranged above and below the pixel array unit 11. For example, for the purpose of speeding up of readout from the pixel 2, the vertical signal lines 31₁ to 31ₘ may be separated at a center in the vertical direction of the pixel array unit 11. In such a case, it is difficult to arrange the dedicated bias unit 45Ba outside the pixel array unit 11, for example, as described in the first embodiment, and the other example of the third embodiment is effective.

Furthermore, a plurality of bias units 45Be′ can be provided. An open position can be identified by providing a plurality of bias units 45Be′.

### 6. Fourth Embodiment

Next, a fourth embodiment of the present disclosure will be described. The fourth embodiment is an example in which the transfer elements TR₁ to TRₘ are connected in parallel in the first semiconductor substrate. The transfer elements TR₁ to TRₘ are provided for each of the vertical signal lines 31₁ to 31ₘ in the detection unit 45A. Furthermore, in the fourth embodiment, the bias unit 45B is provided with an addressing unit for selecting a specific vertical signal line 31 from the vertical signal lines 31₁ to 31ₘ.

(6-0-1. Configuration Example of First Semiconductor Substrate According to Fourth Embodiment)

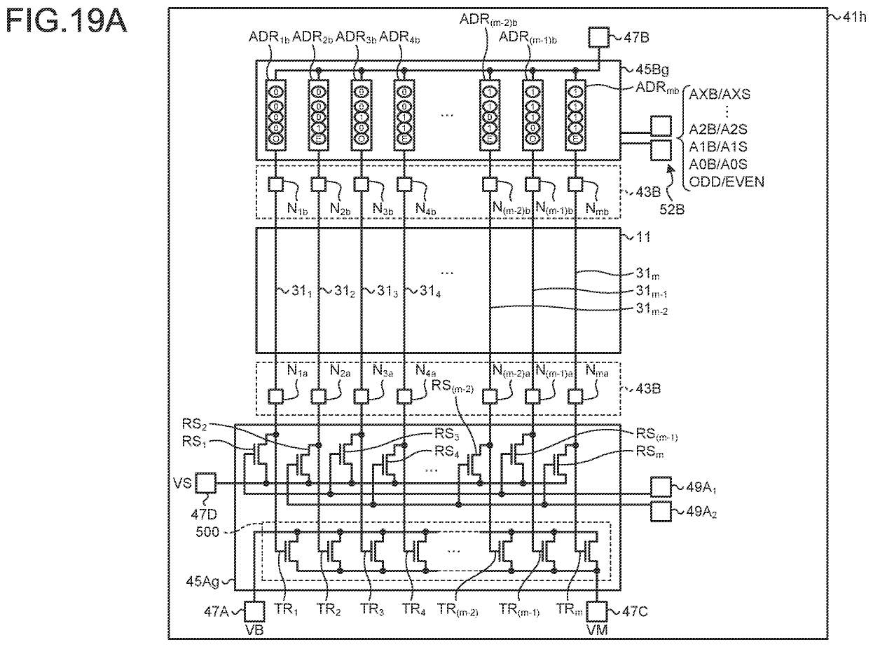

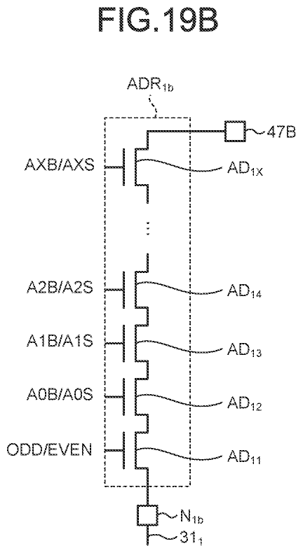

FIG. 19A illustrates an example of the configuration of a first semiconductor substrate according to the fourth embodiment. In a first semiconductor substrate 41h in FIG. 19A, in a bias unit 45Bg, switch decoders ADR_{1b}, ADR_{2b}, ADR_{3b}, ADR_{4b}, . . . , ADR_{(m-2)b}, ADR_{(m-1)b}, and ADR_{mb} are respectively provided to the vertical signal lines 31₁ to 31ₘ on a one-to-one basis.

One or a plurality of switch decoders is selected from the switch decoders ADR_{1b} to ADR_{mb} in accordance with a voltage applied to a control terminal 52B. For example, the control terminal 52B includes terminals in the number in which bit strings corresponding to the number of the vertical signal lines 31₁ to 31ₘ can be set. A control line is connected to each of the terminals. In one example, when the number of the vertical signal lines 31₁ to 31ₘ can be expressed by 10 bits with m=1024, 20 control lines are connected to the control terminal 52B to designate each of a bit value “1” and a bit value “0”. In practice, one bit for collectively designating the vertical signal lines 31₁ to 31ₘ by odd numbers and even numbers may be further used. In the above-described example of m=1024, 22 control lines including two control lines for designating one bit are connected to the control terminal 52B.

More specifically, a set of voltages A0B/A0S, A1B/A1S, A2B/A2S, . . . , and AXB/AXS for individually designating the vertical signal lines 31₁ to 31ₘ and a set of voltages ODD/EVEN for collectively designating the vertical signal lines 31₁ to 31ₘ by odd numbers and even numbers are applied to the control terminal 52.

The electrode 47B is connected in common to voltage input ends of the switch decoders ADR_{1b} to ADR₁ₘ. The voltage output ends of the switch decoders ADR_{1b} to ADR₁ₘ are respectively connected to the vertical signal lines 31₁ to 31ₘ via the connection nodes N_{1b} to N_{mb} on a one-to-one basis.

The vertical signal lines 31₁ to 31ₘ are connected to a detection unit 45Ag via the connection nodes N₁ₐ to Nₘₐ. The detection unit 45Ag includes the reset elements RS₁ to RSₘ, each of which is an NMOS transistor, and the transfer elements TR₁ to TRₘ, each of which is similarly an NMOS transistor. Here, the reset elements RS₁ to RSₘ have a configuration similar to that described with reference to FIG. 12, and thus the description thereof will be omitted here.

In the detection unit 45A, the transfer elements TR₁ to TRₘ are connected in parallel such that drains and sources are connected in common. The gates of the transfer elements TR₁ to TRₘ are respectively connected to the vertical signal lines 31₁ to 31ₘ on a one-to-one basis. Therefore, each of the transfer elements TR₁ to TRₘ can be considered as an input circuit to which a voltage to be applied to each of the vertical signal lines 31₁ to 31ₘ is input. The terminal 47A for applying the voltage VB for inspection is connected in common to the drains of the transfer elements TR₁ to TRₘ. The terminal 47C for extracting the monitoring voltage VM is connected in common to the sources of the transfer elements TR₁ to TRₘ.

(6-0-2. Configuration Example of Switch Decoder According to Fourth Embodiment)

Here, a configuration example of each of the switch decoders ADR_{1b} to ADR_{mb} will be described. Note that the switch decoders ADR_{1b} to ADR_{mb} have the same configuration, the description will be given by taking the switch decoder ADR_{1b} as an example. Furthermore, when it is unnecessary to distinguish the switch decoders ADR_{1b} to ADR_{mb}, the description will be given by referring to the switch decoders ADR_{1b} to ADR_{mb} as a switch decoder ADR.

FIG. 19B is a circuit diagram illustrating the configuration of one example of the switch decoder ADR_{1b} according to the fourth embodiment. As illustrated in FIG. 19B, the switch decoder ADR_{1b} is an NMOS transistor, and includes a plurality of switch elements AD₁₁, AD₁₂, AD₁₃, AD₁₄, . . . , and AD_{1X} connected in series.

The switch element AD₁₁ among these switch elements collectively designates the vertical signal lines 31₁ to 31ₘ to odd numbers or even numbers. A voltage ODD/EVEN is applied to the gate of the switch element AD₁₁. Note that the switch element AD₁₁ is not an essential configuration. For example, the switch element AD₁₂ can be substituted for the function of the switch element AD₁₁. The switch elements AD₁₂ to AD_{1X} individually designate the vertical signal lines 31₁ to 31ₘ. Voltages A0B/A0S, A1B/A1S, A2B/A2S, . . . , and AXB/AXS are applied to the switch elements AD₁₂ to AD_{1X}. When all of the switch elements AD₁₁ to AD_{1X} become on (conductive), the voltage of the electrode 47B is applied to the vertical signal line 31₁.

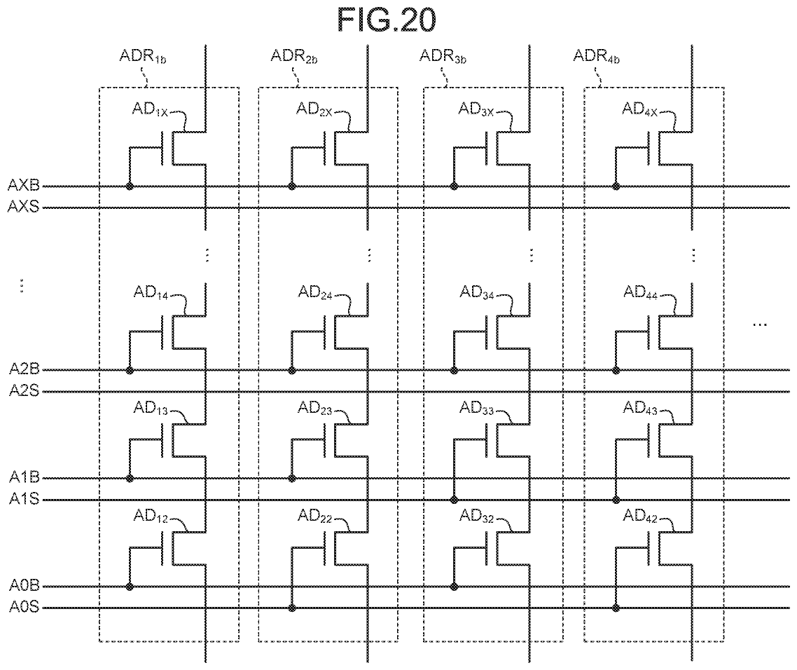

FIG. 20 is a circuit diagram illustrating the configuration of one example of the bias unit 45Bg according to the fourth embodiment. Note that, in FIG. 20, for the sake of description, a switch element (e.g., switch element AD₁₁) for collectively designating the vertical signal lines 31₁ to 31ₘ to odd numbers or even numbers is omitted.

In FIG. 20, as illustrated above, the switch decoder ADR_{1b} includes the switch elements AD₁₂ to _{1X} connected in series. Similarly, the switch decoders ADR_{2b}, ADR_{3b}, and ADR_{4b} respectively include switch elements AD₂₂ to AD_{2X}, switch elements AD₃₂ to AD_{3X}, and switch elements AD₄₂ to AD_{4X}, which are connected in series.

Note that, in the following description, when it is unnecessary to distinguish the switch elements AD₁₂ to _{1X}, the switch elements AD₂₂ to AD_{2X}, the switch elements AD₃₂ to AD_{3X}, and the switch elements AD₄₂ to AD_{4X}, the switch elements AD₁₂ to _{1X}, the switch elements AD₂₂ to AD_{2X}, the switch elements AD₃₂ to AD_{3X}, and the switch elements AD₄₂ to AD_{4X} will be appropriately represented by a switch element AD.

In the switch decoders ADR_{1b}, ADR_{2b}, . . . , two control lines are provided as a pair for switch elements AD whose bit positions correspond to each other. The two control lines include a control line (control line B) for designating a bit value “0” and a control line (control line S) for designating a bit value “1”. The control line B designates the bit value “0” at a high level, for example. Similarly, the control line S designates the bit value “1” at a high level, for example.

In the example of FIG. 20, when attention is paid to, for example, the switch elements AD₁₂, AD₂₂, AD₃₂, AD₄₂, . . . , the control line S and the control line B are provided for the switch elements AD₁₂, AD₂₂, AD₃₂, AD₄₂ . . . . A voltage A0S is applied to the control line S. A voltage A0B is applied to the control line B. Here, the gates of the switch elements AD₁₂ and AD₃₂ are connected to the control line B. The gates of the switch elements AD₂₂ and AD₄₂ are connected to the control line S. Therefore, the switch elements AD₂₂ and AD₄₂ are turned on by setting the control line S to a high level to designate the bit value “1”. Similarly, the switch elements AD₁₂ and AD₃₂ are turned on by setting the control line B to a high level to designate the bit value “0”.

Note that the states of the control line B and the control line S provided as a pair are exclusively controlled. That is, the control line S paired with the control line B set to a high level is set to a low level. Furthermore, the control line B paired with the control line S set to a high level is set to a low level. Note that it is possible to select a plurality of control lines B and S that have been set to a high level.

When seen from a direction of the series connection of switch elements AD, the control lines S are connected to the gates of the switch elements AD₄₂ and AD₄₃ in, for example, the switch decoder ADR_{4b}. Furthermore, the control lines B are connected to the gates of the switch elements AD₄₄ to AD_{4X}.

In this state, each of the control lines S connected to each of the gates of the switch elements AD₄₂ and AD₄₃ is set to a high level (voltages A0S and A1S are set to high level), and each of the control lines B connected to each of the gates of the switch elements AD₄₄ to AD_{4X} is set to a high level (voltages A2B to AXB are set to high level). This causes each of the switch elements AD₄₂ to AD_{4X} to be turned on, and causes both ends of the series connection of the switch elements AD₄₂ to AD_{4X} to be conducted. This is synonymous with giving a bit string “0 . . . 011” to each of the switch elements AD₄₂ to AD_{4X} with the switch element AD_{4X} as a head (least significant bit (LSB)).

In contrast, other switch decoders ADR_{1b}, ADR_{2b}, and ADR_{3b} in the same state as the above-described state (voltages A0S and A1S are set to high level, and voltages A2B to AXB are set to high level) will be considered. In this case, in the switch decoder ADR_{1b}, each of the gates of the switch elements AD₁₂ and AD₁₃ to which the control line B is connected is set to a low level, and these switch elements AD₁₂ and AD₁₃ are turned off. Therefore, both ends of the switch elements AD₁₂ to AD_{1X} are not conducted. Similarly, in the switch decoder ADR_{2b}, the gate of the switch element AD₂₃ to which the control line B is connected is set to a low level, and the switch element AD₂₃ is turned off. Therefore, both ends of the switch elements AD₂₂ to AD_{2X} are not conducted. Furthermore, in the switch decoder ADR_{3b}, the gate of the switch element AD₃₂ to which the control line B is connected is set to a low level, and the switch element AD₃₂ is turned off. Therefore, both ends of the switch elements AD₃₂ to AD_{3X} are not conducted.

In this way, the control line S or the control line B is connected to the gate of each of the switch elements AD included in the switch decoder ADR in accordance with, for example, a bit string corresponding to the address of the vertical signal line 31 connected to the switch decoder ADR. This allows the specific vertical signal line 31 to be designated from the vertical signal lines 31₁ to 31ₘ by the settings of the voltages A0B and A0S, A1B and A1S, A2B and A2S, . . . , and AXB and AXS.

(6-0-3. Example of Inspection Method According to Fourth Embodiment)

A method of performing open inspection and short-circuit inspection for the vertical signal lines 31₁ to 31ₘ in the configuration according to the fourth embodiment will be described more specifically.

A combination of different addresses is designated for the gate of each of the switch elements AD included in the switch decoders ADR_{1b} to ADR_{mb} respectively connected to the vertical signal lines 31₁ to 31ₘ by the control line B and the control line S. Therefore, a voltage can be applied from the electrode 47B to one specific vertical signal line 31 in accordance with the designated combination.

Note that, if the designated vertical signal line 31 is an even-numbered specific vertical signal line 31, the other even-numbered vertical signal lines 31 are in a floating state, and 0 [V] is applied to the odd-numbered vertical signal lines 31. For example, 0 [V] is applied to the electrode 47D as the voltage VS. A voltage of 3 [V] is set to the control terminal 49A₁, and a voltage of 0 [V] is set to the control terminal 49A₂.

In this state, for example, 1 [V] is applied to the terminal 47A as the voltage VB, and the voltage VM of the terminal 47C is monitored.

The transfer elements TR₁ to TRₘ of the detection unit 45Ag are connected in parallel. Therefore, when the vertical signal line 31 designated in the switch decoder ADR does not have an open (disconnection), 1 [V] is detected at the terminal 47C. In contrast, when the vertical signal line 31 has an open (disconnection), the voltage VS of the terminal 47A is not conducted to the terminal 47C, and the terminal 47C is in an inconstant state.

In this case, the vertical signal line 31 (odd-numbered vertical signal line 31) adjacent to the vertical signal line 31 (even-numbered vertical signal line 31) designated in the switch decoder ADR has a voltage set to 0 [V]. Therefore, a short circuit of the vertical signal line 31 designated by the switch decoder ADR can be inspected by monitoring the current of the electrode 47B or the electrode 47D.

In the first embodiment and the third embodiment described above, only the presence or absence of an open or a short circuit can be detected for the vertical signal lines 31₁ to 31ₘ. In contrast, in the fourth embodiment, the vertical signal line 31 having an open or a short circuit can be identified by appropriately scanning addresses and changing the vertical signal lines 31 to be designated. As a result, for example, when the cause of a defect is analyzed later, the defective portion can be easily identified, which can contribute to the efficiency of the analysis.

Note that, each set of the voltages A0B/A0S, A1B/A1S, A2B/A2S, . . . , and AXB/AXS corresponding to the address basically has a complementary relation. When one is 0 [V], the other is set to 3 [V]. For example, in the set of the voltages A0B/A0S, when the voltage A0B is 0 [V], the voltage A0S is set to 3 [V].

This is not a limitation, and the same voltage (e.g., 3 [V]) can be set to two voltages constituting the above-described set. For example, in the set of the voltages A0B/A0S, each of the voltage A0B and the voltage A0S is set to 3 [V]. In this case, for example, if all the addresses (voltages A0B/A0S, A1B/A1S, A2B/A2S, . . . , and AXB/AXS) are set to 3 [V], the voltage can be applied to all the even-numbered vertical signal lines 31₂, 31₄, . . . or all the odd-numbered vertical signal lines 31₁, 31₃, . . . , similarly to the third variation of the first embodiment described with reference to FIG. 13. In this case, however, the detection unit 45Ag preferably has a configuration of not parallel connection but series connection similarly to the third variation of the first embodiment.

Furthermore, for example, a voltage can be applied only to the vertical signal line 31 selected by the voltage A0B or only to the vertical signal line 31 selected by the voltage A0B and the voltage A1S depending on the setting of the application voltage of an address.

### 7. Fifth Embodiment

Next, a fifth embodiment of the present disclosure will be described. The fifth embodiment is an example obtained by combining the example according to the above-described third embodiment with the configuration according to the above-described fourth embodiment. In the configuration according to the above-described fourth embodiment, the specific vertical signal line 31 can be designated by using the switch decoder ADR. In the example according to the above-described third embodiment, a plurality of pixels 2 included in one pixel row is used as a bias circuit for applying a voltage to each of the vertical signal lines 31.

(7-0-1. Configuration Example of First Semiconductor Substrate According to Fifth Embodiment)

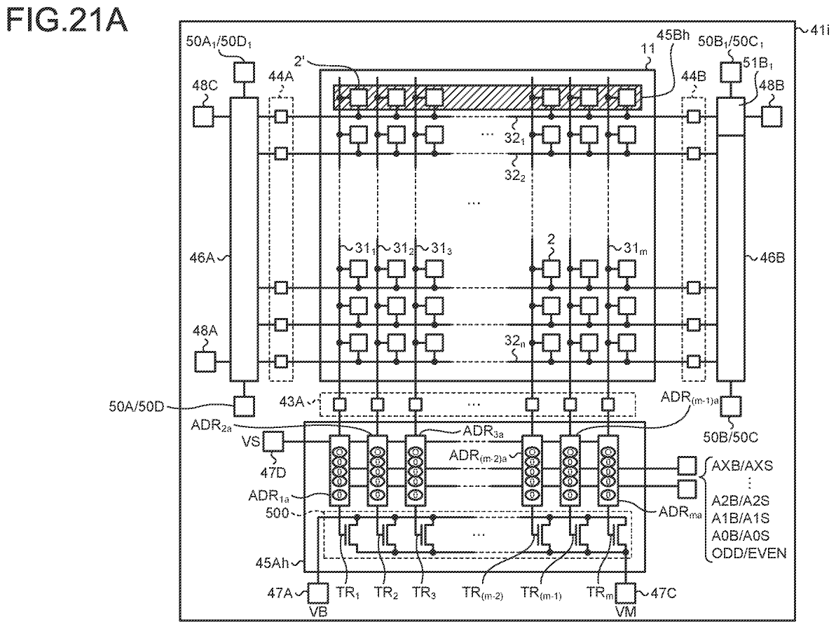

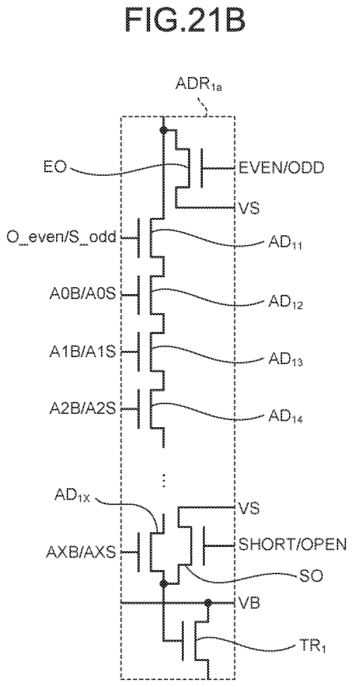

FIG. 21A illustrates an example of the configuration of a first semiconductor substrate according to the fifth embodiment. In a first semiconductor substrate 41i in FIG. 21A, a bias unit 45Bh includes m pixels 2′ connected to the first row of the pixel array unit 11 (row at upper end of pixel array unit 11). Note that the same configuration as that described with reference to FIG. 2 can be applied to the configuration of the pixel 2′, and thus the description thereof will be omitted here.

Furthermore, in FIG. 21A, a detection unit 45Ah includes switch decoders ADR₁ₐ, ADR₂ₐ, ADR₃ₐ, . . . , ADR₍ₘ₋₂₎ₐ, ADR₍ₘ₋₁₎ₐ, and ADRₘₐ respectively provided to the vertical signal lines 31₁ to 31ₘ on a one-to-one basis. The electrode 47D to which the voltage VS is applied is connected in common to the switch decoders ADR₁ₐ to ADRₘₐ. Furthermore, each set of the voltages A0B/A0S, A1B/A1S, A2B/A2S, . . . , AXB/AXS, and ODD/EVEN is input as an address to each of the switch decoders ADR₁ₐ to ADRₘₐ.

Moreover, the detection unit 45Ah includes a detection circuit 500. The detection circuit 500 includes the transfer elements TR₁, TR₂, TR₃, . . . , TR₍ₘ₋₂₎, TR₍ₘ₋₁₎, and TRₘ, which are connected in parallel and respectively provided to the vertical signal lines 31₁ to 31ₘ on a one-to-one basis.

The terminal 47A for setting the voltage VB for inspection is connected in common to the drains of the transfer elements TR₁ to TRₘ. Furthermore, the terminal 47C for extracting the monitoring voltage VM is connected in common to the sources of the transfer elements TR₁ to TRₘ.

FIG. 21B is a circuit diagram illustrating the configuration of one example of the switch decoder ADR₁ₐ according to the fifth embodiment. Note that the switch decoders ADR₁ₐ to ADRₘₐ have the same configuration, and thus the description will be given here by taking the switch decoder ADR₁ₐ as an example.

As illustrated in FIG. 21B, the switch decoder ADR₁ₐ includes a configuration similar to that of the switch decoder ADR_{1b} described with reference to FIG. 19B, is an NMOS transistor, and includes a plurality of switch elements AD₁₁, AD₁₂, AD₁₃, AD₁₄, . . . , and AD_{X1} connected in series. The drain of the switch element AD₁₁ is connected to the vertical signal line 31₁.

The switch element AD₁₁ among these switch elements collectively sets open inspection or short-circuit inspection for the odd numbers of the vertical signal lines 31₁ to 31ₘ or the even numbers of the vertical signal lines 31₁ to 31ₘ. Voltages O_even/S_odd are applied to the gate of the switch element AD₁₁. The switch elements AD₁₂ to AD_{1X} individually designate the vertical signal lines 31₁ to 31ₘ. Voltages A0B/A0S, A1B/A1S, A2B/A2S, . . . , and AXB/AXS are applied to the switch elements AD₁₂ to AD_{1X}. When all of the switch elements AD₁₁ to AD_{1X} become on (conductive), the voltage of the electrode 48B is applied to the vertical signal line 31₁.

The switch decoder ADR₁ₐ further includes a switch element EO and a switch element SO. The switch element EO has a drain connected to the vertical signal line 31₁ and a source connected to the electrode 47D (not illustrated). The voltage VS is applied to the switch element EO. Voltages EVEN/ODD for collective designation to even numbers or odd numbers are applied to the gate of the switch element EO.

Furthermore, in the switch decoder ADR₁ₐ, the source of a short-circuit detection element SO, which is an NMOS transistor, is connected to the source of the switch element AD_{1X}. The electrode 47D is connected to the drain of the short-circuit detection element SO, and the voltage VS is applied to the drain. Voltages SHORT/OPEN for setting either short-circuit inspection or open inspection are applied to the gate of the short-circuit detection element SO.

Note that, in the example of FIG. 21B, the switch decoder ADR₁ₐ is described as including the transfer element TR₁. The gate of the transfer element TR₁ is connected to a connection point where the source of the switch element AD_{1X} and the source of the short-circuit detection element SO are connected. The drain of the transfer element TR₁ is connected to the terminal 47A, and the voltage VB is applied to the drain. Furthermore, although not illustrated, the source of the transfer element TR₁ is connected to the terminal 47C.

Note that, in FIG. 21A, the configuration described according to the above-described second embodiment can be applied as it is to the configurations of the detection unit 46A and the bias unit 46B for inspecting each of the control lines 32₁ to 32ₙ.

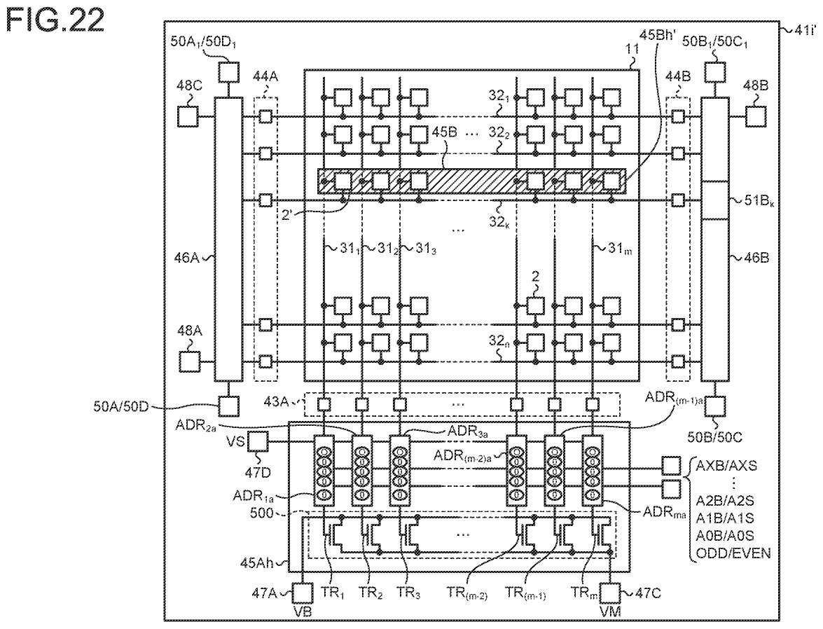

Furthermore, although, in the example of FIG. 21A, the bias unit 45Bh is described as including m pixels 2′ connected to the first row of the pixel array unit 11, this example is not a limitation. Similarly to the other example of the third embodiment described with reference to FIG. 18, the bias unit 45Bh can be configured in any row among rows included in the pixel array unit 11. For example, as illustrated as a first semiconductor substrate 41i′ in FIG. 22, a bias unit 45Bh′ can include a plurality of pixels 2′ included in the kth (1<k<n) pixel row among the first to nth pixel rows included in the pixel array unit 11.

In this way, an open portion can be identified in more detail by changing the position of the bias unit 45Bh′. For example, when the first row of the pixel array unit 11 is defined as the bias unit 45Bh, the bias unit 45Bh′ of the kth row of an intermediate portion performs open inspection again after an open is detected. When an open is not detected by the open inspection of the bias unit 45Bh, it can be determined that there is a defective portion between the kth row and the first row. When an open is detected, it can be determined that there is a defective portion between the kth row and the nth row. The same applies to the configuration according to another example of the third embodiment described with reference to FIG. 18.

(7-0-2. Example of Inspection Method According to Fifth Embodiment)

A method of performing open inspection and short-circuit inspection for the vertical signal lines 31₁ to 31ₘ in the configuration according to the fifth embodiment will be described.

(7-0-2-1. Example of Open Inspection According to Fifth Embodiment)

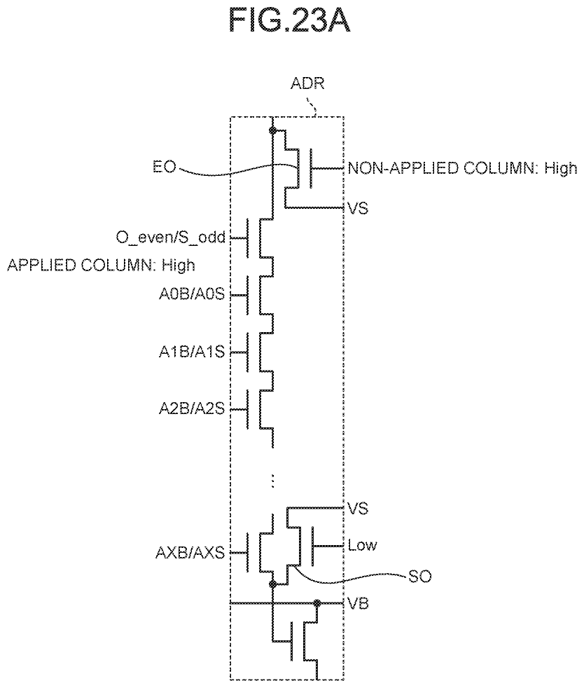

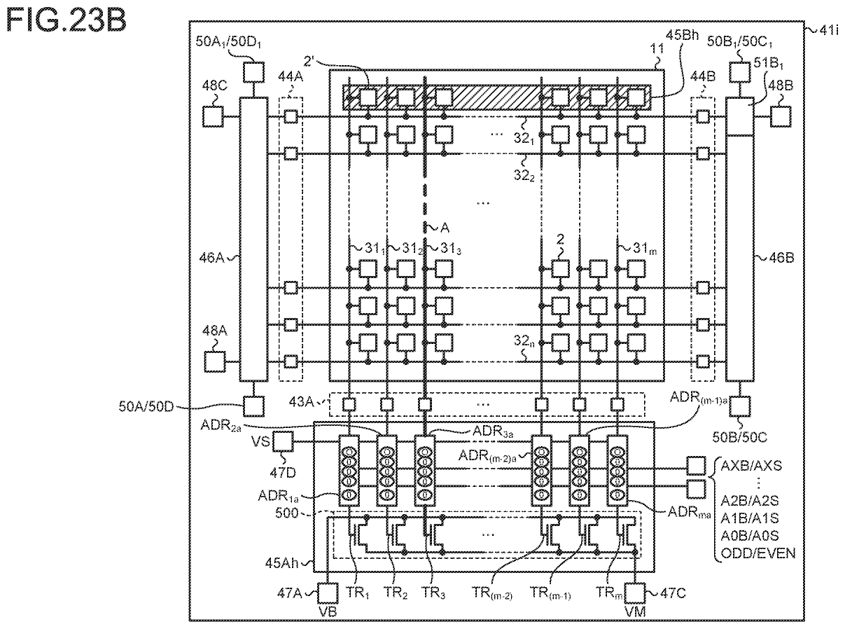

First, an example in which open inspection is performed will be described with reference to FIGS. 23A and 23B. FIG. 23A illustrates an example of the setting of the switch decoder ADR in a case where open inspection is performed in the configuration according to the fifth embodiment. Furthermore, FIG. 23B schematically illustrates the states of vertical signal lines at the time of the open inspection. The vertical signal line 31 to which a high-level voltage is to be applied is selected from the vertical signal lines 31₁ to 31ₘ, and the open inspection is performed.

In one example, when open inspection is performed for the odd-numbered vertical signal lines 31₁, 31₃, . . . , the odd-numbered vertical signal lines 31₁, 31₃, . . . are set to a high level through the pixel 2′ of the bias unit 45Bh.

For example, in the switch decoder ADR of a non-applied column (in this example, even-numbered vertical signal lines 31₂, 31₄, . . . ) to which a high level is not applied, the gate of the switch element EO is set to a high level, the voltage VS of 0 [V] is applied to the non-applied column, and the non-applied column is reset to 0 [V]. Furthermore, the gate of the short-circuit detection element SO is set to a low level, and turned off. This causes a voltage from the vertical signal line 31 whose address is designated by the switch decoder ADR to be applied to the gate of the transfer element TR connected to the switch decoder ADR.

A specific vertical signal line 31 is selectively connected to the transfer element TR in a combination of addresses of the switch decoders ADR₁ₐ to ADRₘₐ. In this case, an address is designated such that any of the odd-numbered vertical signal lines 31₁, 31₃, . . . is designated. Furthermore, in this example in which open inspection is performed, in the switch decoder ADR corresponding to an applied column, the voltages O_even/S_odd are set to a high level. A low level is applied to the gate of each of the transfer elements TR corresponding to an address that is not designated by the switch decoder ADR, and each of the transfer elements TR is turned off.

In this state, for example, 1 [V] is applied to the terminal 47A as the voltage VB, and the voltage VM of the terminal 47C is monitored. In the detection unit 45Ah, the transfer elements TR₁ to TRₘ are connected in parallel, so that, if the selected vertical signal line 31 has no open (disconnection), 1 [V] is detected as the voltage VM of the terminal 47C. If the selected vertical signal line 31 has an open portion, the voltage VB of the terminal 47A is not conducted, and the terminal 47C has the inconstant voltage VM.

In the example of FIG. 23B, in the detection unit Ah, the vertical signal line 31₃ is selected by a switch decoder ADR₃ₐ. When the vertical signal line 31₃ has no open portion, a high-level voltage applied to the vertical signal line 31₃ through the pixel 2′ is applied to the gate of the transfer element TR₃ via the switch decoder ADR₃ₐ as illustrated by a thick line as a path A in the figure. The address of the switch decoder ADR₃ₐ is designated so as to select the vertical signal line 31₃. This causes the transfer element TR₃ to be turned on, and causes 1 [V] applied to the terminal 47A as the voltage VB to appear to the terminal 47C as the voltage VM via the drain and the source of the transfer element TR₃.

(7-0-2-2. Example of Short-Circuit Inspection According to Fifth Embodiment)

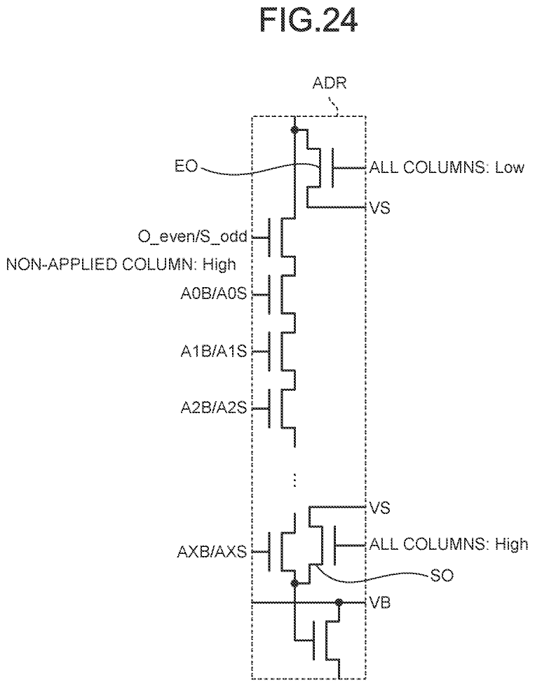

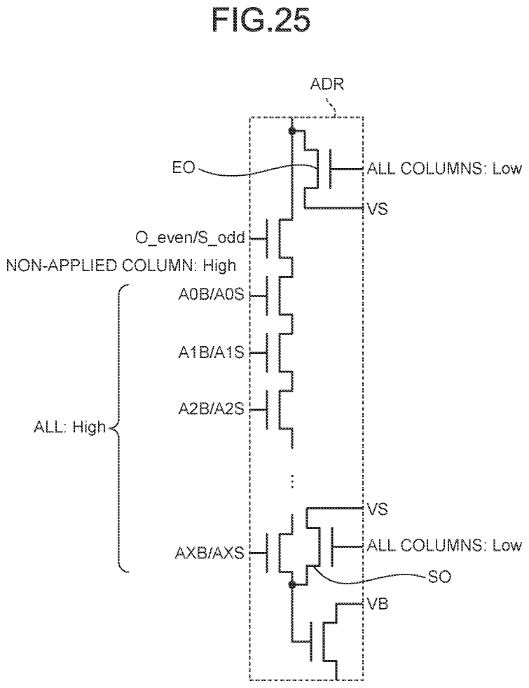

Note that short-circuit inspection can be performed by using the configuration in FIG. 21A. For example, as described in the first variation of the first embodiment, the potential setting between the adjacent vertical signal lines 31 among the vertical signal lines 31₁ to 31ₘ is made different. Then, in the detection unit 45Ah, short-circuit inspection for the vertical signal line 31 whose address is designated by the switch decoder ADR can be performed by monitoring the current of the electrode 47D. FIG. 24 illustrates an example of the setting of the switch decoder ADR in this case. This example is not a limitation, and the short-circuit inspection between adjacent vertical signal lines 31 can be performed by monitoring the voltage VM of the terminal 47C. FIG. 25 illustrates an example of the setting of the switch decoder ADR in this case.

In the configuration according to the fifth embodiment, the vertical signal line 31 having an open or a short circuit can be identified by appropriately scanning addresses and changing the vertical signal lines 31 to be inspected. As a result, for example, when the cause of a defect is analyzed later, the defective portion can be easily identified, which can contribute to the efficiency of the analysis.

### 8. Sixth Embodiment

Next, a sixth embodiment of the present disclosure will be described. The sixth embodiment can be applied to each of the above-described embodiments and the variations thereof, and is an example of a configuration and a structure for maximizing a range of an application voltage in the bias units 45B (bias units 45Ba to 45Bh) and 46B according to each of the embodiments and the variations thereof. Note that, in the following description, the bias units 45B (bias units 45Ba to 45Bh) and 46B will be described as being application circuits in consideration of the fact that these bias units are circuits for applying a voltage to an object to be detected.

(8-1. Existing Technology)

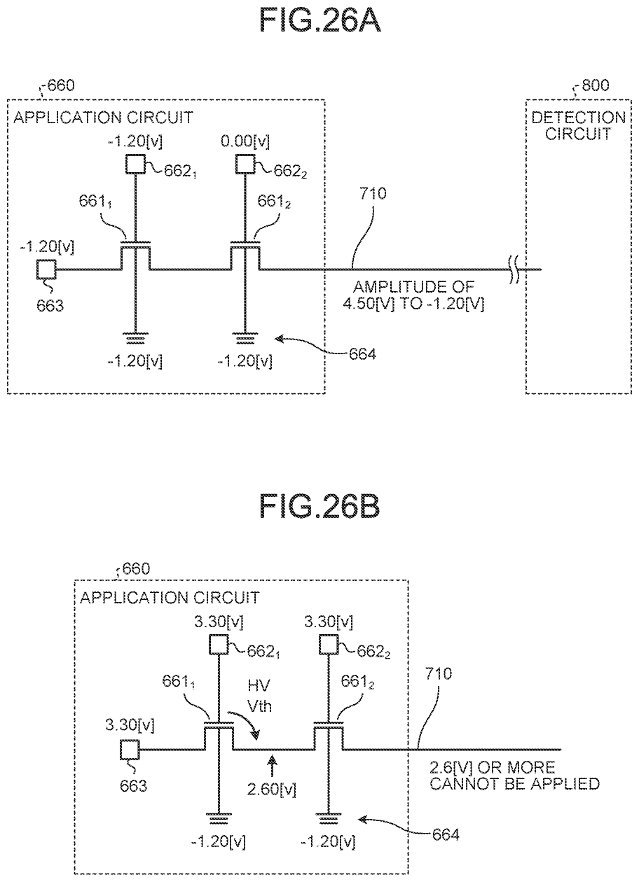

FIGS. 26A and 26B are circuit diagrams illustrating an example of an application circuit 660 according to existing technology. In an example of FIG. 26A, the application circuit 660 includes transistors 661₁ and 661₂, each of which is an NMOS transistor. The transistor 661₁ has a drain connected to an input terminal 663 and a source connected to the drain of the transistor 661₂. The source of the transistor 661₂ is connected to an object to be detected by a pixel wire 710. Control terminals 662₁ and 662₂ are respectively connected to the gates of the transistors 661₁ and 661₂. Each of the transistors 661₁ and 661₂ is turned on by applying a high-level voltage to the gate of each of the control terminals 662₁ and 662₂. A voltage input to the input terminal 663 is applied to the pixel wire 710.

Note that the pixel wire 710 corresponds to, for example, the above-described vertical signal line 31 or the control line 32. Furthermore, in the example of FIG. 26A, the two transistors 661₁ and 661₂ are connected in series in a drain-source direction, which improves the withstand voltage performance of a circuit.

Here, the same potential as the lowest potential used in a circuit is generally set to a well potential 664 applied to the back gates of the transistors 661₁ and 661₂. This is because, without such a setting, a forward current flows between a source and a well or between a drain and a well. For example, in a case of assumption that up to −1.2 [V] is applied to the pixel wire 710, as illustrated in FIG. 26A, the well potential 664 applied to the back gates of the transistors 661₁ and 661₂ is set to −1.2 [V].

From the viewpoint of the withstand voltages of the transistors 661₁ and 661₂, when a voltage applied between a gate and a well and between a gate and a drain is set not to exceed the voltage Vdd (=4.5 V), as illustrated in FIG. 26B, the gate potential (potential applied to control terminals 662₁ and 662₂) of the application circuit 660 is restricted up to 3.3 [V]. If voltage drop (Vth drop) by a threshold voltage Vth between a drain and a source in an NMOS transistor is considered, only a voltage of up to approximately 2.6 [V] can be applied to the pixel wire 710. Therefore, a range of an application voltage that can be applied to the pixel wire 710 is −1.2 [V] to 2.6 [V].

In this way, in the examples of FIGS. 26A and 26B, the voltage Vdd is 4.5 [V], but only up to 2.6 [V] can be applied to the pixel wire 710. When the range of the application voltage to the pixel wire 710 is small, a circuit operation range at the time of inspection is restricted, and sufficient inspection may be impossible.

(8-2. Configuration According to Sixth Embodiment)

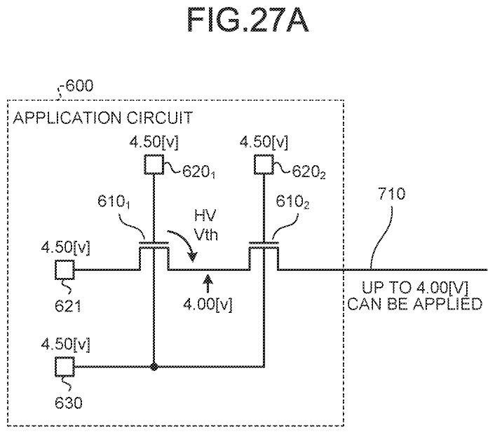

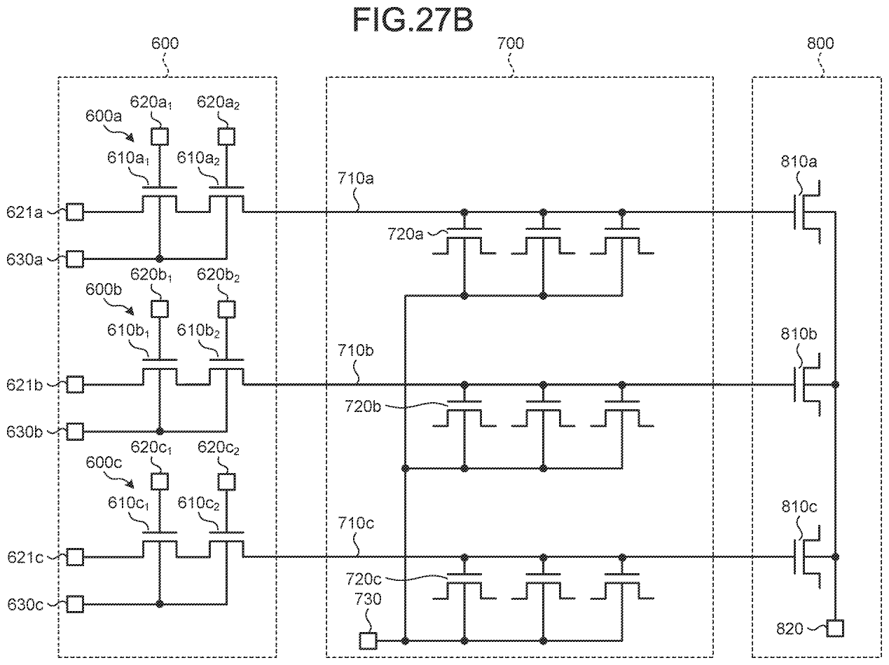

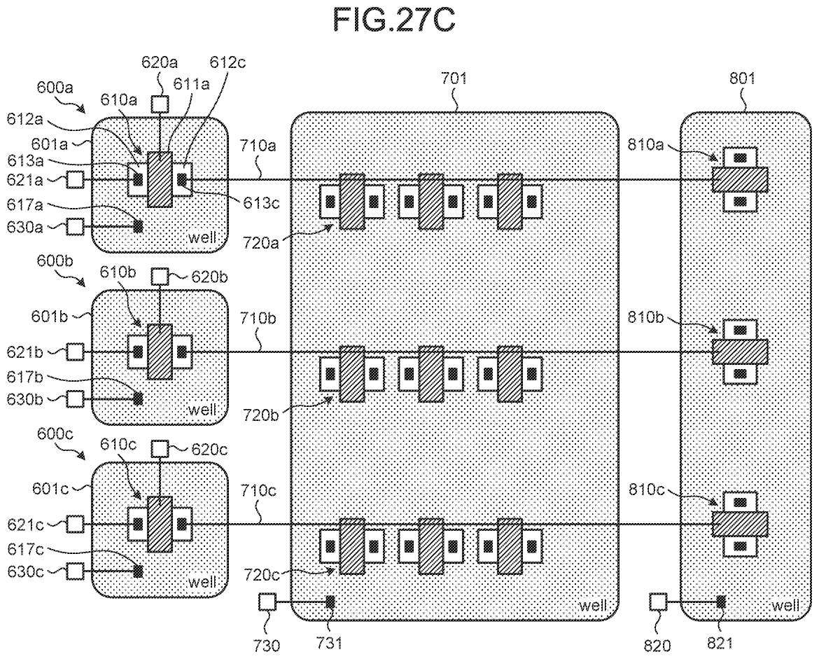

Next, the sixth embodiment will be described with reference to FIGS. 27A, 27B, and 27C. FIG. 27A is a circuit diagram illustrating an example of an application circuit according to the sixth embodiment. An application circuit 600 in FIG. 27A is an NMOS transistor, and includes two transistors 610₁ and 610₂ connected in series in the drain-source direction, similarly to the application circuit 660 described with reference to FIG. 26A.

The transistor 610₁ has a drain connected to an input terminal 621 and a source connected to the drain of the transistor 610₂. The source of the transistor 610₂ is connected to an object to be detected by the wire 710. Control terminals 620₁ and 620₂ are respectively connected to the gates of the transistors 610₁ and 610₂.

Here, in the configuration of FIG. 27A, a well terminal 630 directly connected to the wells of the transistors 610₁ and 610₂ is provided, and a voltage input to the well terminal 630 can be applied to the back gates of the transistors 610₁ and 610₂. This allows a well potential to follow an input voltage input to the input terminal 621, and allows a voltage of up to the voltage Vdd (=4.50 [V]), which is the maximum voltage of the withstand voltages of the transistors 610₁ and 610₂, to be applied to the input terminal 621 and the control terminals 620₁ and 620₂.

In the example of FIG. 27A, a voltage of 4.50 [V], which is the same as the voltage Vdd, is input to each of the input terminal 621, the well terminal 630, and the control terminals 620₁ and 620₂. In this case, a voltage of up to 4.00 [V] can be applied to the pixel wire 710 including the Vth drop.

Moreover, in the sixth embodiment, the pixel wire 710 that applies a voltage makes wells in which a plurality of adjacent application circuits 600 is formed electrically independent from each other. The configuration according to the sixth embodiment will be described with reference to FIGS. 27B and 27C. Note that, in FIGS. 27B and 27C, in the configuration on the first semiconductor substrate 41, only portions deeply related to the sixth embodiment are extracted and schematically illustrated, and the other portions are omitted.

FIG. 27B is a circuit diagram schematically illustrating a circuit formed on the first semiconductor substrate 41 according to the sixth embodiment. In FIG. 27B, an application unit 670a corresponds to, for example, the bias unit 45B or the bias unit 46B described above, and includes a plurality of application circuits 600a, 600b, and 600c.

Each of the application circuits 600a, 600b, and 600c has the same configuration as the application circuit 600 in FIG. 27A. That is, the application circuit 600a includes transistors 610a₁ and 610a₂ connected in series in the source-drain direction. An input terminal 621a is connected to the drain of the transistor 610a₁. Each of control terminals 620a₁ and 620a₂ is connected to each gate. Furthermore, a voltage input to a well terminal 630a can be applied to the back gate of each of the transistors 610a₁ and 610a₂.

Similarly, an application circuit 600b includes transistors 610b₁ and 610b₂ connected in series in the source-drain direction. Control terminals 620b₁ and 620b₂ are respectively connected to the gates of the transistors 610b₁ and 610b₂. An input terminal 621b is connected to the drain of the transistor 610b₁. A pixel wire 710b is connected to the source of the transistor 610b₂. Furthermore, a voltage input to a well terminal 630b can be applied to the back gate of each of the transistors 610b₁ and 610b₂.

Similarly, an application circuit 600c includes transistors 610c₁ and 610c₂. The transistors 610c₁ and 610c₂ are connected in series in the source-drain direction. Control terminals 620c₁ and 620b₂ are respectively connected to the gates of the transistors 610c₁ and 610c₂. An input terminal 621c is connected to the drain of the transistor 610c₁. A pixel wire 710c is connected to the source of the transistor 610c₂. Furthermore, a voltage input to a well terminal 630c can be applied to the back gate of each of the transistors 610c₁ and 610c₂.

The application circuits 600a, 600b, and 600c respectively apply voltages from the sources of the transistors 610a₂, 610b₂, and 610c₂ to the pixel wires 710a, 710b, and 710c.

A pixel circuit unit 700 corresponds to, for example, the above-described pixel array unit 11. The pixel circuit unit 700 includes a plurality of pixel transistors 720a, a plurality of pixel transistors 720b, and a plurality of pixel transistors and 720c. The pixel transistors 720a are connected to the pixel wire 710a. The pixel transistors 720b are connected to the pixel wire 710b. The pixel transistors 720c are connected to the pixel wire 710c. A voltage input to a well terminal 730 can be applied to the back gate of each of the pixel transistors 720a, 720b, and 720c.

Note that each of the pixel transistors 720a, 720b, and 720c may be any of, for example, the transfer transistor 22, the reset transistor 23, the amplification transistor 24, and the selection transistor 25 in FIG. 2, or may be any of the transistors in a case where the pixel 2 has a configuration different from that in FIG. 2. This is not a limitation, and the pixel wires 710a, 710b, and 710c are not required to be connected to the pixel transistors 720a, 720b, and 720c included in the pixel circuit unit 700.

Each of the pixel wires 710a, 710b, and 710c is connected to a detection circuit unit 800 via the pixel circuit unit 700. The detection circuit unit 800 corresponds to, for example, the detection unit 45A or the detection unit 46A described above.

Although, in the example of FIG. 27B, for the sake of description, the detection circuit unit 800 is illustrated as including transistors 810a, 810b, and 810c respectively corresponding to the pixel wires 710a, 710b, and 710c, FIG. 27B is a schematic diagram for description. In practice, the detection circuit unit 800 has a configuration equivalent to each detection circuit described up to the fifth embodiment. A voltage input to a well terminal 720 can be applied to the back gate of each of the transistors 810a, 810b, and 810c of the detection circuit unit 800.

In such a configuration, the transistors 610a₁ and 610a₂ apply a voltage to the pixel wire 710a at the time of inspection. Each of the transistors 610a₁ and 610a₂ is controlled in accordance with the voltages applied to the control terminals 620a₁ and 620a₂, and applies a voltage input to the input terminal 621a to the pixel wire 710a.

The same applies to the transistors 610b₁ and 610b₂ and the transistors 610c₁ and 610c₂ for applying a voltage to each of the pixel wires 710b and 710c at the time of inspection. The transistors 610b₁ and 610b₂ and the transistors 610c₁ and 610c₂ are respectively controlled in accordance with the voltages applied to the control terminals 620b₁ and 620b₂ and the control terminals 620c₁ and 620c₂, and apply voltages input to the input terminals 621b and 621c to the pixel wires 710b and 710c.

The detection circuit unit 800 detects whether or not each of the pixel wires 710a, 710b, and 710c has a defect by using a voltage applied to each of the pixel wires 710a, 710b, and 710c as described above.

FIG. 27C is a schematic plan view of one example of the first semiconductor substrate 41 according to the sixth embodiment. Note that, in FIG. 27C, the two transistors 610a₁ and 610a₂ included in the application circuit 600a in FIG. 27B are collectively illustrated as a transistor 610a. Similarly, in the application circuits 600b and 600c, the transistors 610b₁ and 610b₂ are collectively described as a transistor 610b, and the transistors 610c₁ and 610c₂ are collectively described as a transistor 610c.

In FIG. 27C, the application circuit 600a includes the transistor 610a formed on a well 601a. The transistor 610a has a gate 611a to which a control terminal 620a is connected, a drain 612a to which the input terminal 621a is connected via a connection unit 613a, and a source 612c to which the pixel wire 710a is connected via a connection unit 613c. Furthermore, the well terminal 630a is connected to the well 601a via a connection unit 617a.

Similarly for the application circuits 600b and 600c, the application circuits 600b and 600c respectively include the transistors 610b and 610c formed on wells 601b and 601c. The transistor 610b has a gate to which a control terminal 620b is connected, a drain to which the input terminal 621b is connected, and a source to which the pixel wire 710b is connected. Furthermore, the well terminal 630b is connected to a well 601b via a connection unit 617b. The transistor 610c has a gate to which a control terminal 620c is connected, a drain to which the input terminal 621c is connected, and a source to which the pixel wire 710c is connected. Furthermore, the well terminal 630c is connected to a well 601c via a connection unit 617c.

Here, the well 601a, the well 601b, and the well 601c are electrically separated. The application circuit 600a is formed in the well 601a. The application circuit 600b is formed in the well 601b. The application circuit 600c is formed in the well 601c. That is, a pixel wire that applies a voltage separates wells in which adjacent application circuits are formed.

Moreover, the wells 601a, 601b, and 601c and a well 701 are electrically separated. Voltages are applied to the well 701 via the pixel wires 710a, 710b, and 710c. The pixel transistors 720a, 720b, and 720c in the pixel circuit unit 700 are formed in the well 701. A voltage of a well potential is applied from the well terminal 730 to the well 701 via a connection unit 731.

The well potential of the transistor 610a is biased (applied) from the well terminal 630a of the application circuit 600a. The well potential of the pixel transistor 720a to which a voltage is applied by the application circuit 600a is biased from a well terminal 731 on the well 701 in which the pixel circuit unit 700 is formed. The well potentials can be biased at different potentials. Similarly, the wells 601b and 601c formed in the application circuits 600b and 600c sequentially adjacent to the application circuit 600a are electrically separated, so that well potentials can be biased at different potentials.

As a result, for example, when a high voltage is desired to be applied to the pixel wire 710a, the potentials of the well terminal 630a and the control terminal 620a are increased while the potential of the input terminal 621a is increased. The high voltage thereby can be applied to the pixel wire 710a in a range in consideration of Vth drop from the voltage Vdd while the withstand voltage of the transistor 610a is maintained.

Moreover, when a voltage lower than that of the pixel wire 710a is desired to be applied to the pixel wire 710b adjacent to the pixel wire 710a at the same time when the high voltage is applied to the pixel wire 710a, the potentials of the well terminal 630a and the control terminal 620b are lowered accompanying the reduction in the potential of a voltage input to the input terminal 621b. In this way, control can be performed to prevent a forward current from flowing to the well 601b even when a voltage is applied to the pixel wire 710b to a range of negative voltages.

In the example of FIG. 27C, a well 801 in which the detection circuit unit 800 is formed is further electrically separated from the wells 601a, 601b, and 601c and the well 701. A voltage can be applied from a well terminal 820 to the well 801 via a connection unit 821. That is, the well potentials of the transistors 810a, 810b, and 810c included in the detection circuit unit 800 can also be biased from the well terminal 820 independently of the pixel circuit unit 700 and the application circuits 600a, 600b, and 600c. Therefore, when change in a well potential is preferred for convenience (e.g., viewpoint of withstand voltage and advantage in operation point and operation range) of operation of the detection circuit unit 800, the well potential can be changed independently of the pixel circuit unit 700 and the application circuits 600a, 600b, and 600c to be optimized.

(8-3. First Variation of Sixth Embodiment)

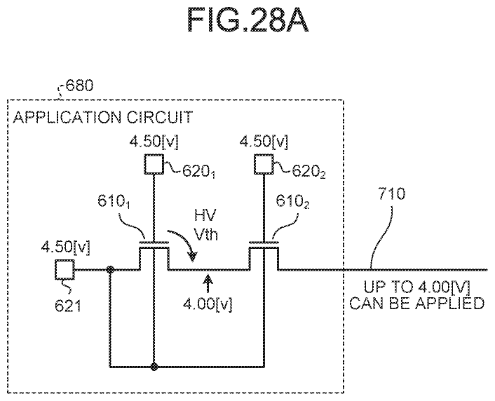

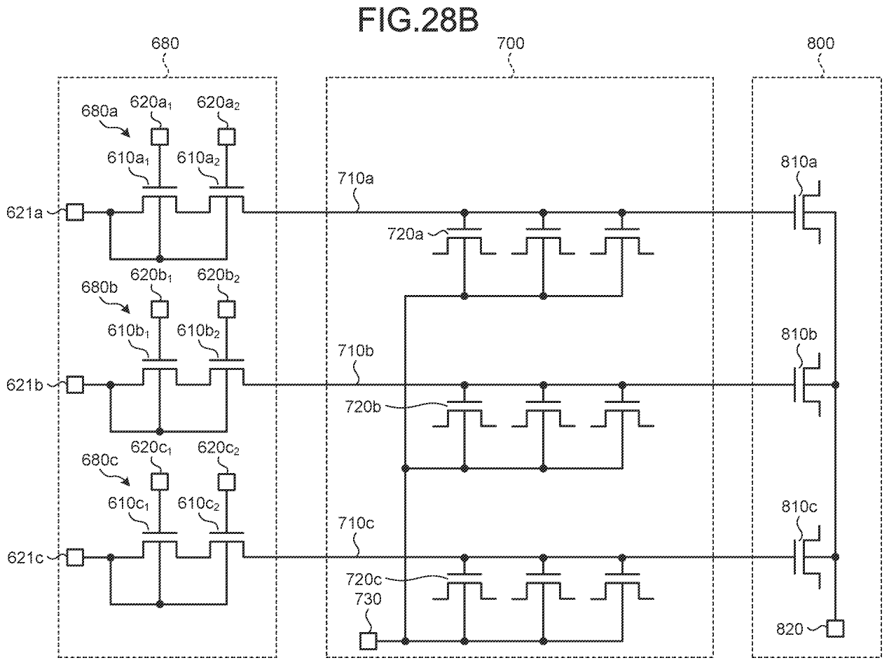

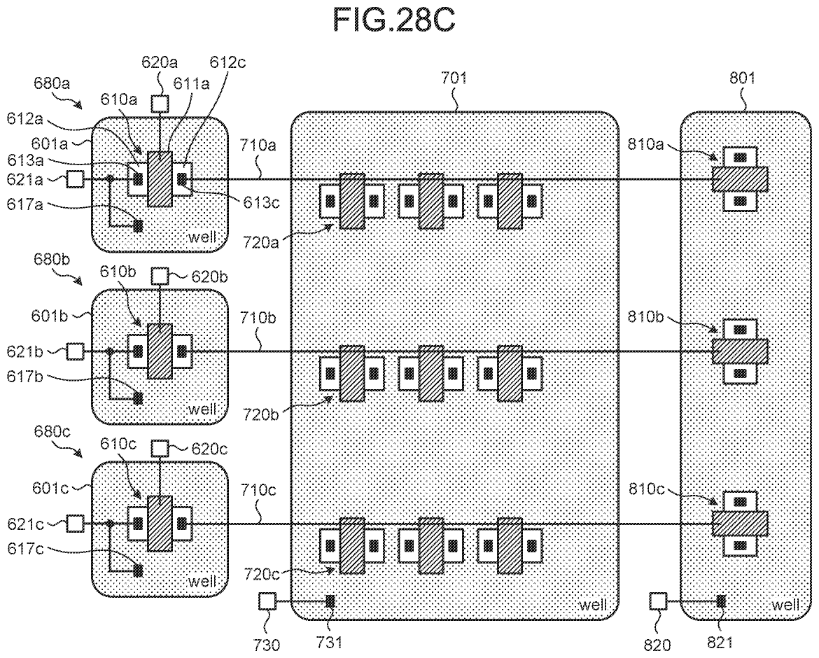

Next, a first variation of the sixth embodiment will be described. FIG. 28A is a circuit diagram illustrating an example of an application circuit according to the first variation of the sixth embodiment.

An application circuit 680 in FIG. 28A is obtained by connecting the input terminal 621 to the drain of the transistor 610₁ and the back gate of each of the transistors 610₁ and 610₂ in the application circuit 600 described with reference to FIG. 27A. More specifically, as described later, the input terminal 621 is directly connected to the well in which each of the transistors 610₁ and 610₂ is formed.

This causes the potential of a voltage applied to the back gate of each of the transistors 610₁ and 610₂ to be the same as the potential of a voltage input to the input terminal 621. This allows a well potential to follow an input voltage input to the input terminal 621, and allows a voltage of up to the voltage Vdd (=4.50 [V]), which is the maximum voltage of the withstand voltages of the transistors 610₁ and 610₂, to be applied to the input terminal 621 and the control terminals 620₁ and 620₂.

In the example of FIG. 28A, a voltage of 4.50 [V], which is the same as the voltage Vdd, is input to each of the input terminal 621 and the control terminals 620₁ and 620₂. In this case, similarly to the above-described case in FIG. 27A, a voltage of up to 4.00 [V] can be applied to the pixel wire 710 including the Vth drop.

The configuration according to the first variation of the sixth embodiment will be described with reference to FIGS. 28B and 28C. Note that, in FIGS. 28B and 28C, in the configuration on the first semiconductor substrate 41, only portions deeply related to the first variation of the sixth embodiment are extracted and schematically illustrated, and the other portions are omitted.

FIG. 28B is a circuit diagram schematically illustrating a circuit formed on the first semiconductor substrate 41 according to the first variation of the sixth embodiment. In FIG. 28B, an application unit 670b includes a plurality of application circuits 680a, 680b, and 680c, similarly to the application unit 670a in FIG. 27B. In the application circuit 680b, the input terminal 621b is connected to the drain of the transistor 610b₁, and connected to the back gates of the transistors 610b₁ and 610b₂. Similarly in the application circuit 680c, the input terminal 621c is connected to the drain of the transistor 610c₁, and connected to the back gates of the transistors 610c₁ and 610c₂. The other configurations are common to as those in FIG. 27B above, and thus the description thereof will be omitted here.

FIG. 28C is a schematic plan view of one example of the first semiconductor substrate 41 according to the first variation of the sixth embodiment. Note that, in FIG. 28C, similarly to FIG. 27C above, the two transistors 610a₁ and 610a₂ included in the application circuit 680a in FIG. 27C are collectively illustrated as the transistor 610a. Similarly, in the application circuits 680b and 680c, the transistors 610b₁ and 610b₂ are collectively described as the transistor 610b, and the transistors 610c₁ and 610c₂ are collectively described as the transistor 610c.

In FIG. 28C, the application circuit 680a includes the transistor 610a formed on the well 601a. The input terminal 621a is connected to the drain of the transistor 610a, and connected to the well 601a via the connection unit 617a.

Similarly for the application circuits 680b and 680c, the application circuits 680b and 680c respectively include the transistors 610b and 610c formed on wells 601b and 601c. The transistor 610b has a gate to which the control terminal 620b is connected, a drain to which the input terminal 621b is connected, and a source to which the pixel wire 710b is connected. Furthermore, the input terminal 621b is connected to the well 601b via the connection unit 617b. Similarly, the transistor 610c has a gate to which the control terminal 620c is connected, a drain to which the input terminal 621c is connected, and a source to which the pixel wire 710c is connected. Furthermore, the input terminal 621c is connected to the well 601c via the connection unit 617c.

With such a configuration, in each of the application circuits 680a, 680b, and 680c, a well potential is biased in accordance with a voltage input to each of the input terminals 621a, 621b, and 621c without separately biasing the well potential. Therefore, even in the configuration according to the first variation of the sixth embodiment, a high voltage can be applied to each of the pixel wires 710a, 710b, and 710c in a range in consideration of Vth drop from the voltage Vdd while the withstand voltage of each of the transistors 610a, 610b, and 610c is maintained.

Note that, in the above-described sixth embodiment, when bias lines for applying a voltage to each of the wells 601a, 601b, and 601c are independently wired, latch-up may occur. Therefore, attention to layout, such as shortening the wire length from the transistor 610a to the well terminal 630c is needed. In contrast, in the first variation of the sixth embodiment, such attention is unnecessary since the well terminal 630a is not used. For example, connecting the well 601a with the source and the drain in the immediate vicinity of the transistor 610a is conceivable.

Note that, in the above-described sixth embodiment, an input voltage and a well voltage can be set independently, which leads to an advantage of a high degree of freedom of setting. In contrast, in the first variation of the sixth embodiment, the well voltage is automatically determined in accordance with the input voltage, so that fine optimization is difficult. Therefore, which of the configuration of the sixth embodiment and the configuration of the first variation of the sixth embodiment is adopted is preferably selected appropriately in accordance with the purpose, specification, and the like of inspection.

(8-4. Second Variation of Sixth Embodiment)

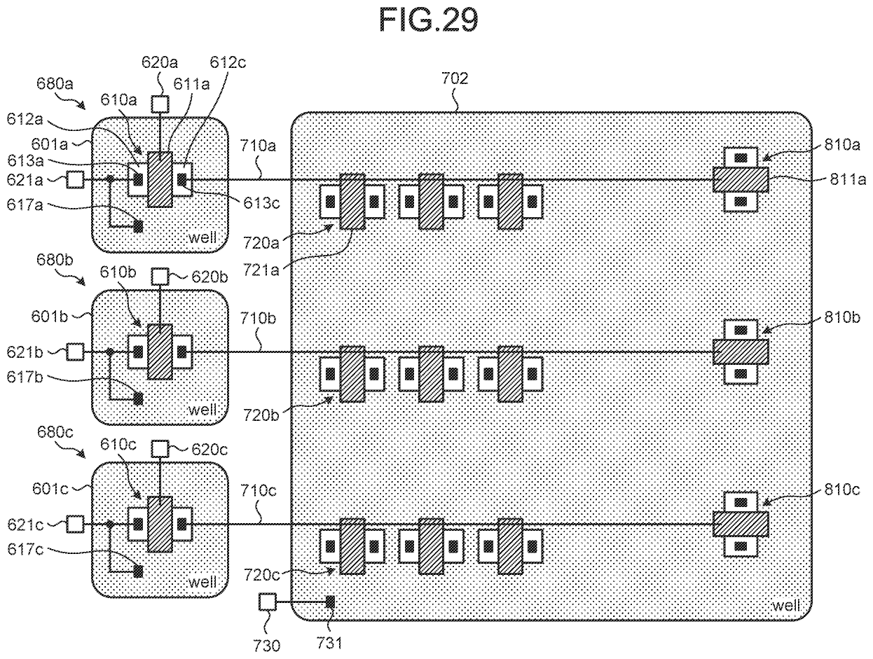

Next, a second variation of the sixth embodiment will be described. FIG. 29 is a schematic plan view of one example of the first semiconductor substrate 41 according to the second variation of the sixth embodiment. Since the circuit described with reference to FIG. 28B can be applied as it is to a circuit formed on the first semiconductor substrate 41 according to the second variation of the sixth embodiment, the description thereof will be omitted here. Furthermore, in FIG. 29, in the description of each of the application circuits 680a, 680b, and 680c, configurations are appropriately omitted in common with FIG. 28C above.

In the above-described sixth embodiment and the first variation thereof, the well 701 and the well 801 are separated. The pixel circuit unit 700 is formed in the well 701. The detection circuit unit 800 is formed in the well 801. Different well voltages can be set to the wells 701 and 801. In contrast, in the second variation of the sixth embodiment, the pixel circuit unit 700 and the detection circuit unit 800 are formed on a common well 702.

That is, it may be unnecessary to independently change the well potential of the detection circuit unit 800 depending on an inspection drive method and the configuration of the detection circuit unit 800. In that case, as illustrated in FIG. 29, the well of the detection circuit unit 800 and the well of the pixel circuit unit 700 can be the same well 702.

Note that, although, in the example of FIG. 29, the application circuit 680 according to the first variation of the sixth embodiment is applied as an application circuit, this example is not a limitation. The application circuit 600 according to the sixth embodiment may be applied as the application circuit.

(8-5. Third Variation of Sixth Embodiment)

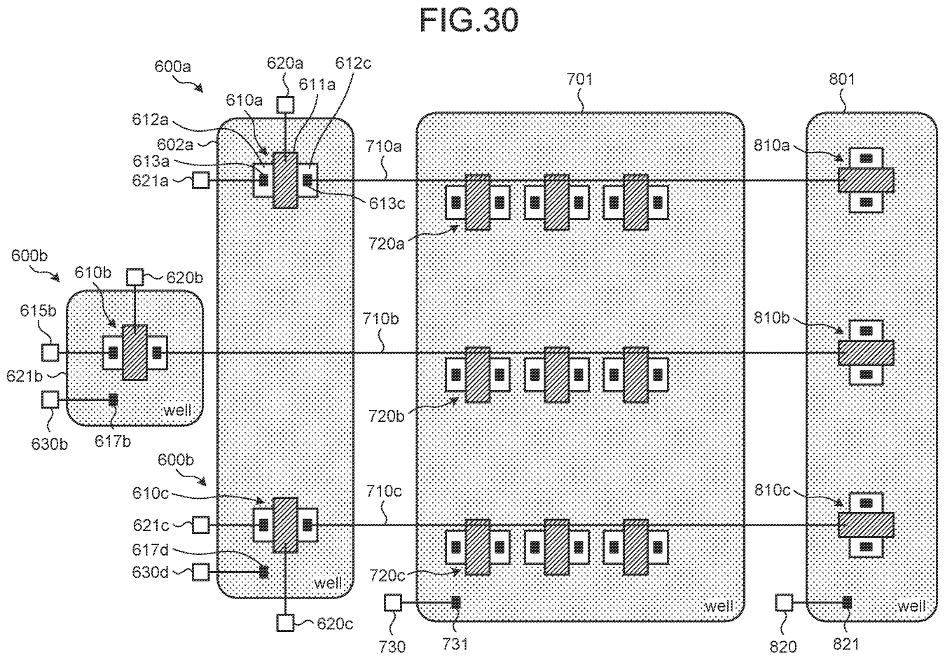

Next, a third variation of the sixth embodiment will be described. FIG. 30 is a schematic plan view of one example of the first semiconductor substrate 41 according to the third variation of the sixth embodiment. Since the circuit described with reference to FIG. 27B can be applied as it is to a circuit formed on the first semiconductor substrate 41 according to the third variation of the sixth embodiment, the description thereof will be omitted here. Furthermore, in FIG. 30, in the description of each of the application circuits 680a, 680b, and 680c, configurations are appropriately omitted in common with FIG. 27C above.

In the above-described sixth embodiment, the application circuits 600a, 600b, and 600c are formed in the wells 601a, 601b, and 601c separated from each other. In contrast, the third variation of the sixth embodiment is an example in which some application circuits among a plurality of application circuits are formed in the same well and other application circuits are formed in a well separated from the same well.

In the example of FIG. 30, the application circuits 600a and 600c are formed in the same well 602a, and the application circuit 600b is formed in a well 602b separated from the well 602a. In the well 602a, a well voltage is applied from a well terminal 630d to the well 602a. Furthermore, since the application circuits 600a and 600b are formed in the same well 602a, the input terminals 621a and 621c can be made common with each other.

That is, in the above-described sixth embodiment and the first and second variations thereof, the well voltages of the application circuits 600a to 600c or the application circuits 680a to 680c can be independently biased. In contrast, depending on an inspection drive method, there may arise a case where a high voltage that requires consideration for the withstand voltage of each transistor included in the application circuit is applied only to some pixel wires, and an application voltage within a normal withstand voltage range is applied to the other pixel wires.

In such a case, as a configuration as illustrated in FIG. 30, the well potential is required to be controlled in accordance with the application voltage only for an application circuit to which a high voltage is desired to be applied. The other application circuits are required to have a common well. A fixed voltage is required to be applied to the common well.

In the example of FIG. 30, the application circuits 600a and 600c among the application circuits 600a to 600c are formed in the common well 602a. In contrast, the application circuit 600b to which a high voltage is desired to be applied is formed in the well 602b separated from the well 602a. The well potentials can be independently controlled to the application circuits 600a and 600c.

In this way, an increase in a layout area due to well separation can be inhibited by inhibiting separation of a well of an application circuit to the minimum necessary and using a common well for the other application circuits.

(8-6. Effects According to Sixth Embodiment and Variations Thereof)

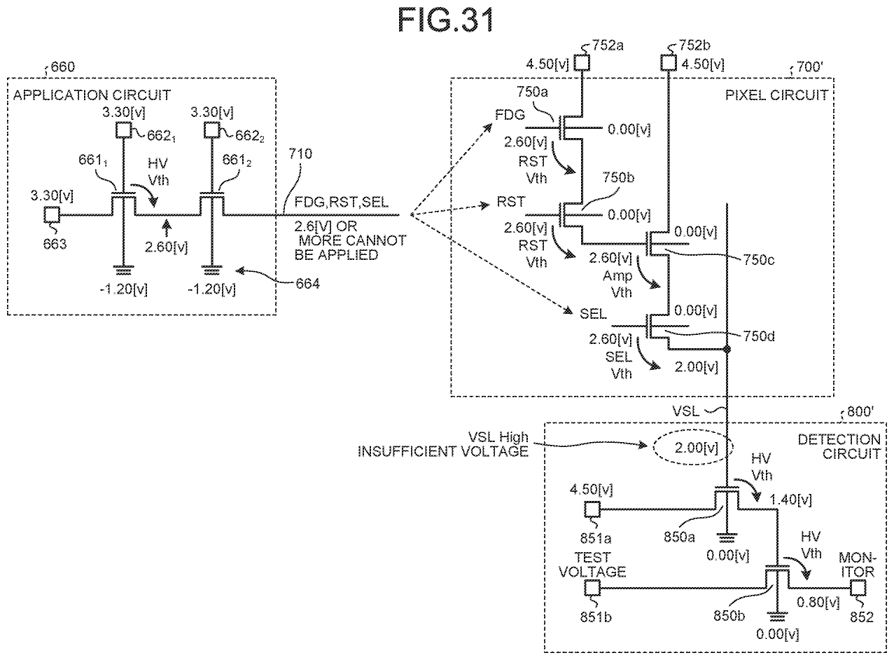

Here, effects of the sixth embodiment and the variation thereof will be described by taking the first variation as an example. FIG. 31 illustrates an example of a pixel circuit and a detection circuit for describing inspection using existing technology.

In FIG. 31, the application circuit 660 is the same as the application circuit 660 described in FIGS. 26A and 26B, and thus the description thereof will be omitted here. Furthermore, a pixel circuit unit 700′ and a detection circuit unit 800′ are referred to for description, and have configurations different from those of the pixel circuit unit 700 and the detection circuit unit 800 described above.

The pixel circuit unit 700′ includes transistors 750a, 750b, 750c, and 750d in this example. Note that, in this figure, configurations of a photodiode, a floating diffusion region FD, and the like, which are not directly related to the inspection here, are omitted.

On/off of the transistor 750a is controlled by a signal FDG applied to a gate. The transistor 750a has a drain connected to a terminal 752a for supplying power and a source connected to the drain of the transistor 750b. On/off of the transistor 750b is controlled by the reset signal RST. The transistor 750b has a source connected to the gate of the transistor 750c.

The transistor 750c has a drain connected to a terminal 752b for supplying power and a source connected to the drain of the transistor 750d. Furthermore, the transistor 750c has a gate to which the source of the transistor 750b is connected and to which the floating diffusion region FD (not illustrated) is connected. A signal obtained by converting a charge accumulated in the floating diffusion region FD into a voltage is amplified, and output from the source. On/off of the transistor 750d is controlled by the selection signal SEL applied to the gate. The transistor 750d has a source connected to a vertical signal line VSL.

Note that, in this example, a voltage of 0.00 [V] is applied to the back gates of the transistors 750a to 750d.

The detection circuit unit 800′ includes transistors 850a and 850b in this example. The transistor 850a has a gate connected to the vertical signal line VSL and a drain to which a terminal 851a for supplying power is connected. The transistor 850a has a source connected to the gate of the transistor 850b. The transistor 850b has a drain connected to a test terminal 851b for supplying a test voltage and a source connected to a monitor terminal 852 for monitoring a detection result.

Note that, in this example, a voltage of 0.00 [V] is applied to the back gates of the transistors 850a and 850b.

In this example, a case in which inspection is performed by writing a high-level voltage (Hi voltage) to the vertical signal line VSL via the pixel circuit unit 700′ will be considered.

As described above, in the application circuit 660, a potential 664 applied to the back gates of the transistors 661₁ and 661₂ is set to −1.2 [V], and the upper limit of the voltage applicable to the control terminals 662₁ and 662₂ and the input terminal 663 is set to 3.30 [V] under the restriction on the withstand voltage of each of the transistors 661₁ and 661₂. Therefore, the maximum potential of a signal output from the application circuit 660 remains at 2.60 [V] due to Vth drop of an NMOS transistor.

An application circuit 660 is provided for each of the signal FDG, the reset signal RST, and the selection signal SEL. The signal FDG, the reset signal RST, and the selection signal SEL having the above-described maximum potential of 2.60 [V] are applied from each application circuit 660 to the gate of each of the transistors 750a, 750b, and 750d. The output of the transistor 750b is input to the gate of the transistor 750c. The output of the transistor 750c is supplied to the vertical signal line VSL via the transistor 750d. At this time, the voltage of a signal supplied to the vertical signal line VSL drops to, for example, 2.00 [V] due to Vth drop of each transistor, In this case, the potential of a high voltage of the vertical signal line VSL may be insufficient.

Moreover, when the vertical signal line VSL has an insufficient potential, output voltage of, for example, only approximately 0.80 [V] can be obtained in the monitor terminal 852 also in the detection circuit unit 800′, and it may be difficult to secure an operation margin. As a result, sufficient inspection results may fail to be obtained. In this way, in a case of a premise that only an NMOS transistor constitutes a circuit, a voltage as high as possible needs to be applicable in the application circuit 660.

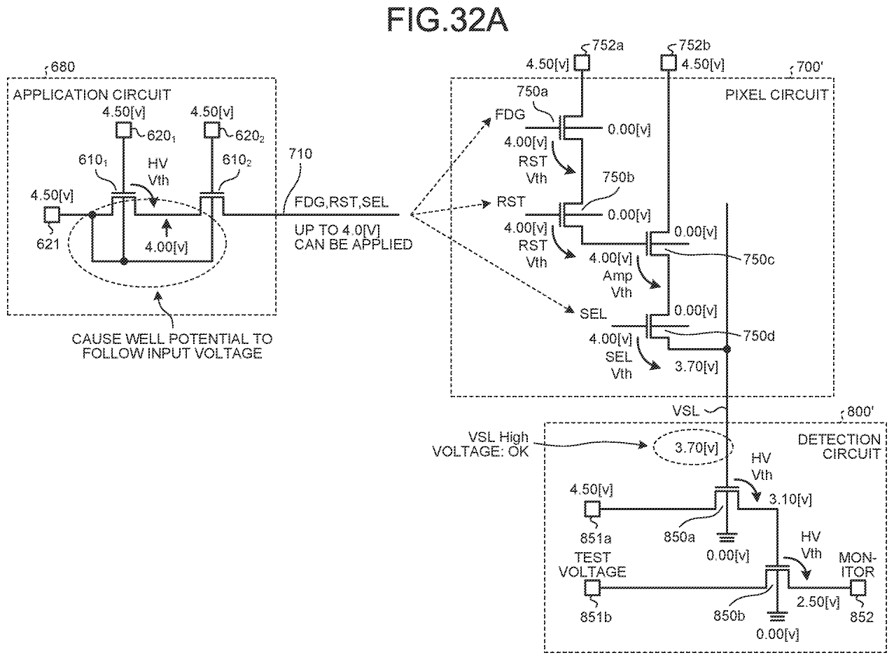

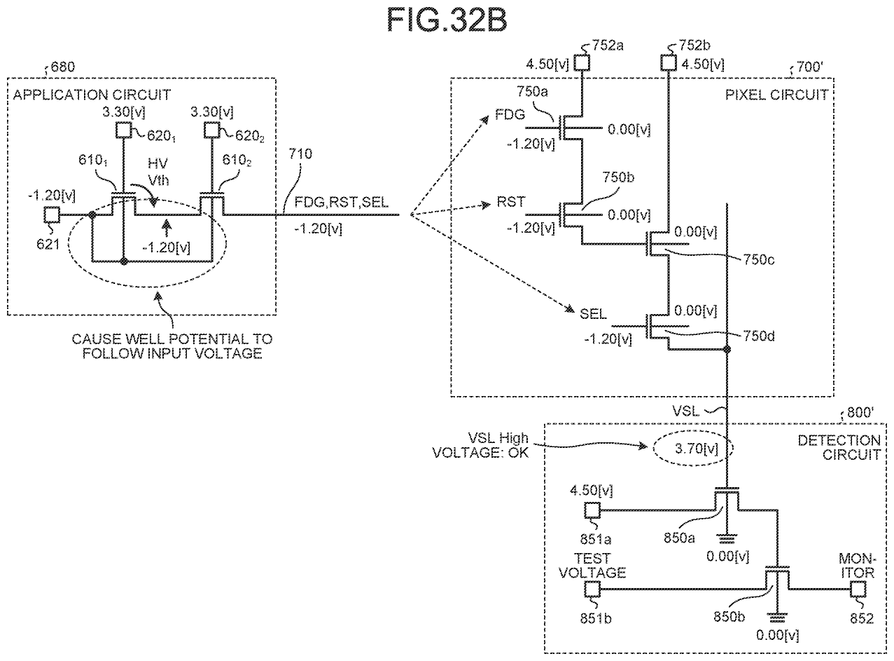

FIGS. 32A and 32B illustrate effects according to the sixth embodiment and the variations thereof. FIGS. 32A and 32B are examples in which the application circuit 680 according to the first variation of the sixth embodiment is applied instead of the application circuit 660 in FIG. 31. Note that, in FIGS. 32A and 32B, the pixel circuit unit 700′ and the detection circuit unit 800′ have the same configurations as the configurations in FIG. 31, and thus the description thereof will be omitted here.

FIG. 32A illustrates an example of a case where the application circuit 600 outputs an application voltage in a case where the pixel circuit unit 700′ is desired to be turned on. As described above, the application circuit 680 applies a voltage input to the input terminal 621 to a well 601 separated for each application circuit 680, and causes the well voltage to follow the input voltage. Therefore, a voltage of up to the voltage Vdd (=4.50 [V]) can be applied to the input terminal 621 and the control terminals 620₁ and 620₂. Moreover, a substrate bias effect of each of the transistors 661₁ and 661₂ also disappears, and the potential of the Vth drop is also decreased. Therefore, an effect of allowing a higher voltage to pass through the transistors 661₁ and 661₂ can also be expected. In this example, the application circuit 680 can output a voltage of up to 4.00 [V].

In the case of this example, the application circuit 680 is provided for each of the signal FDG, the reset signal RST, and the selection signal SEL. The signal FDG, the reset signal RST, and the selection signal SEL having the above-described maximum potential of 4.00 [V] are applied from each application circuit 680 to the gate of each of the transistors 750a, 750b, and 750d. The output of the transistor 750b is input to the gate of the transistor 750c. The output of the transistor 750c is supplied to the vertical signal line VSL via the transistor 750d. At this time, the voltage of a signal supplied to the vertical signal line VSL due to Vth drop of each transistor is set to 3.70 [V], which is approximately 1.70 [V] higher than that in the example of FIG. 31, for example. The vertical signal line VSL has a sufficient potential of the high voltage.

When the vertical signal line VSL has a sufficient potential, output voltage of, for example, approximately 2.50 [V] can be obtained in the monitor terminal 852 also in the detection circuit unit 800′. The operation margin is expanded, and sufficient inspection results can be obtained.

FIG. 32B illustrates an example of a case where the application circuit 600 outputs an application voltage in a case where the pixel circuit unit 700′ is desired to be turned off. In this case, the voltage input to the input terminal 621 is set to, for example, −1.20 [V]. The well voltage follows the input voltage to be −1.20 [V]. For example, 3.30 [V] is applied to the control terminals 620₁ and 620₂. The application circuit 680 outputs the voltage of −1.20 [V] input to the input terminal 621 as an output voltage.

The voltages of the signal FDG, the reset signal RST, and the selection signal SEL are set to −1.20 [V]. The transistors 750a, 750b, and 750d are turned off. The vertical signal line VSL has a potential of 0.00 [V]. Therefore, each of the transistors 850a and 850b of the detection circuit unit 800′ is turned off. The monitor terminal 852 has an output voltage of 0.00 [V].

### 9. Other Embodiments

Note that, although, in the above-described embodiments and the variations thereof, the detection unit 45A (detection units 45Aa to 45Ah) and the bias unit 45B (bias units 45Ba to 45Bh) are arranged on the first semiconductor substrate 41 (first semiconductor substrates 41a to 41i), this example is not a limitation. For example, one or both of the detection unit 45A and the bias unit 45B may be arranged on the second semiconductor substrate 42. In this case, a disconnection or a short circuit of a connection between the first semiconductor substrate 41 and the second semiconductor substrate 42, such as Cu—Cu hybrid bonding, can be inspected.

In one example, the detection unit 45A (detection units 45Aa to 45Ah) and the bias unit 45B (bias units 45Ba to 45Bh) can be separately arranged on the first semiconductor substrate 41b and the second semiconductor substrate 42. Instead of the above-described vertical signal lines 31₁ to 31ₘ, one end and the other end of a connection unit (VIA or Cu—Cu hybrid bonding) that connects the first semiconductor substrate 41b and the second semiconductor substrate 42 are connected to the detection unit 45A and the bias unit 45B. In this case, open inspection and short-circuit inspection for the connection unit can be executed.

Furthermore, although, in the above description, each element (transistor) includes an NMOS transistor, this example is not a limitation. That is, each element may include a PMOS transistor or a CMOS element. Moreover, other elements may be used.

Moreover, although, in the above description, the technology of the present disclosure is described as being applied to the imaging element 1 including the pixel array unit 11, this example is not a limitation. The technology of the present disclosure can also be applied to other elements such as a semiconductor memory as long as the technology has a configuration in which cells including a predetermined circuit are arranged in a matrix and a cell array is provided. In the cell array, each of signal lines is connected to each of the cells in a row direction and a column direction.

The technology of the present disclosure is preferably used for all devices in which wire layers are mounted at high density. For example, the technology of the present disclosure can also be used for inspection of a defect of a wire layer of a memory such as a NAND flash memory and a dynamic RAM (DRAM) and a defect of a wire layer of a micro electro mechanical system (MEMS) device.

### 10. Structure Applicable to Each Embodiment

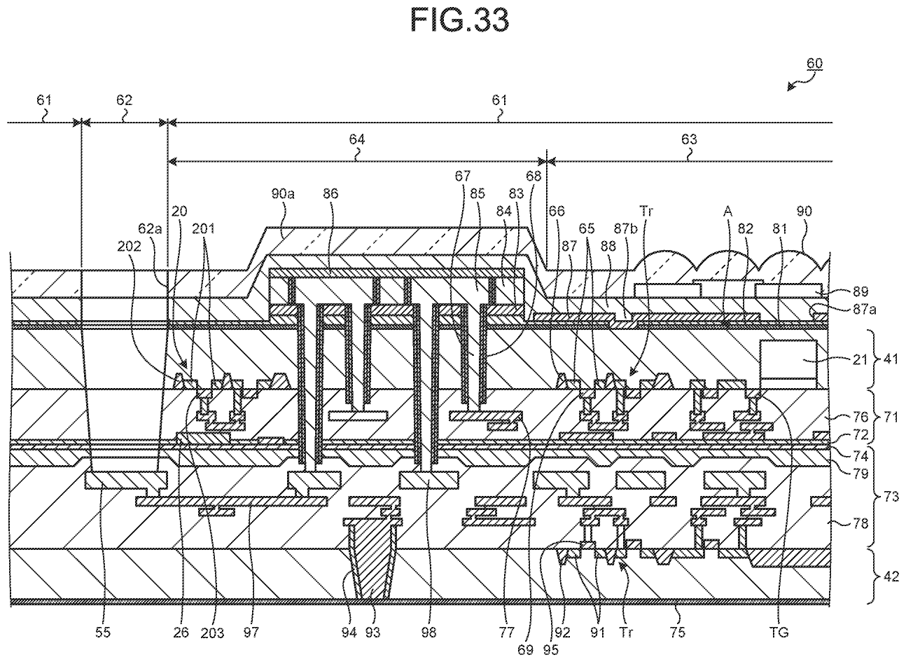

Next, the structures of the first semiconductor substrate 41 (first semiconductor substrates 41a to 41i) and the second semiconductor substrate 42 applicable to each embodiment will be described. FIG. 33 is a cross-sectional view of a main portion of an imaging element wafer applicable to the present disclosure. An imaging element wafer 60 applicable to the present disclosure has a three-dimensional structure in which the first semiconductor substrate 41 and the second semiconductor substrate 42 are laminated and bonded. The first semiconductor substrate 41 is a sensor substrate with the pixel array unit 11. The second semiconductor substrate 42 is a circuit substrate with a peripheral circuit unit of the pixel array unit 11.

The imaging element wafer 60 includes a chip region 61 and a divided region 62 in planar view. Then, the chip region 61 includes a pixel region 63 and a peripheral region 64.

A wire layer 71 and a protective film 72 covering the wire layer 71 are provided on the side of a front surface opposite to a light receiving surface A of the first semiconductor substrate 41, that is, on a surface on the side of the second semiconductor substrate 42. In contrast, a wire layer 73 and a protective film 74 covering the wire layer 73 are provided on the side of a front surface of the second semiconductor substrate 42, that is, on a surface on the side of first semiconductor substrate 41. Furthermore, a protective film 75 is provided on the back surface side of the second semiconductor substrate 42. These first semiconductor substrate 41 and the second semiconductor substrate 42 are bonded between the protective film 72 and the protective film 74.

An antireflection film 81, an interface state inhibiting film 82, an etching stop film 83, a wire groove forming film 84, a wire 85, a cap film 86, and a light shielding film 87 are provided on the back surface side of the first semiconductor substrate 41, that is, on the light receiving surface A. Then, a transparent protective film 88, a color filter 89, and an on-chip lens 90 are laminated in this order on the light shielding film 87.

In the imaging element wafer 60 having the above-described layer configuration, a device terminal 93 is provided on the second semiconductor substrate 42 in the chip region 61, and the device terminal 93 is connected to a drive circuit on the side of the second semiconductor substrate 42. Furthermore, an inspection terminal 55 used for inspecting each imaging element in a wafer state is provided in the wire layer 73 of the divided region 62. The inspection terminal 55 is connected to an embedded wire 97 of a drive circuit extending from the wire layer 73 of the chip region 61. Moreover, an opening 62a that opens on the side of the light receiving surface A is provided in the divided region 62. The opening 62a is formed as a through hole that exposes the inspection terminal 55.

Next, in the imaging element wafer 60 having the above-described configuration, details of the configuration of each layer of the first semiconductor substrate 41, the configuration of each layer of the second semiconductor substrate 42, and the configuration of each layer on the light receiving surface A will be sequentially described.

(First Semiconductor Substrate/Sensor Substrate)

The first semiconductor substrate 41 is formed by thinning a single crystal silicon substrate, for example. A plurality of photodiodes (photoelectric conversion units) 21 is arranged and formed along the light receiving surface A in the pixel region 63 in each chip region 61 in the first semiconductor substrate 41. The photodiode 21 has a laminated structure of, for example, an n-type diffusion layer and a p-type diffusion layer. Note that the photodiode 21 is provided for each pixel, and FIG. 33 illustrates a cross-sectional structure of one pixel.

Furthermore, the floating diffusion region FD including an n+ type impurity layer, a source/drain region 65 of a transistor Tr, other impurity layers (not illustrated here), an element separation region 66, and the like are provided on the side of a front surface opposite to the light receiving surface A in the chip region 61 of the first semiconductor substrate 41.

Moreover, in the chip region 61 of the first semiconductor substrate 41, a through via 67 penetrating the first semiconductor substrate 41 is provided in the peripheral region 64 outside the pixel region 63. The through via 67 includes a conductive material embedded in a connection hole formed through the first semiconductor substrate 41 via a separation insulating film 68.

In the chip region 61 of the wire layer 71 provided on the surface of the first semiconductor substrate 41, a transfer gate TG, a gate electrode 69 of the transistor Tr, and other electrodes (not illustrated here) are provided on the side of an interface with the first semiconductor substrate 41 via a gate insulating film (not illustrated here). Here, the transfer gate TG corresponds to the gate electrode of the transfer transistor 22 in the pixel circuit in FIG. 2. The transistor Tr corresponds to another transistor.

The transfer gate TG and the gate electrode 69 are covered with an interlayer insulating film 76. Embedded wires 77 using, for example, copper (Cu) are provided as multilayer wires in a groove pattern provided in the interlayer insulating film 76. The embedded wires 77 are mutually connected by a via, and partially connected to the source/drain region 65, the transfer gate TG, and the gate electrode 69. Furthermore, the through via 67 provided on the first semiconductor substrate 41 is also connected to the embedded wire 77, and the transistor Tr, the embedded wire 77, and the like constitute a pixel circuit.

The insulating protective film 72 is provided on the interlayer insulating film 76 with the above-described embedded wire 77. Then, the first semiconductor substrate 41 serving as a sensor substrate is bonded and laminated on the second semiconductor substrate 42 serving as a circuit substrate on the surface of the protective film 72.

(Second Semiconductor Substrate/Circuit Substrate)

The second semiconductor substrate 42 is formed by thinning a single crystal silicon substrate, for example. A source/drain region 91 of the transistor Tr, impurity layers (not illustrated here), an element separation region 92, and the like are provided on a surface layer on the side of the first semiconductor substrate 41 in the chip region 61 of the second semiconductor substrate 42.

Moreover, the device terminal 93 penetrating the second semiconductor substrate 42 is provided in the chip region 61 of the second semiconductor substrate 42. The device terminal 93 includes a conductive material embedded in a connection hole formed through the second semiconductor substrate 42 via a separation insulating film 94.

In the chip region 61 of the wire layer 73 provided on the surface of the second semiconductor substrate 42, a gate electrode 95 provided via the gate insulating film (not illustrated here) and other electrodes (not illustrated here) are provided on the side of an interface with the second semiconductor substrate 42. These gate electrode 95 and the other electrodes are covered with an interlayer insulating film 78. The embedded wires 97 using, for example, copper (Cu) are provided as multilayer wires in a groove pattern provided in the interlayer insulating film 78. The embedded wires 97 are mutually connected by a via, and partially connected to the source/drain region 91 and the gate electrode 95. Furthermore, the device terminal 93 provided on the second semiconductor substrate 42 is also connected to the embedded wire 97, and the transistor Tr, the embedded wire 97, and the like constitute a drive circuit.

Moreover, an aluminum wire 98 is provided on the side of the second semiconductor substrate 42 of the multilayer wires. The aluminum wire 98 is connected to the embedded wire 97 by a via, and covered with the interlayer insulating film 78. The surface of the interlayer insulating film 78 has an uneven shape in accordance with the aluminum wire 98. A planarization film 79 is provided so as to cover the uneven surface. The planarization film 79 has a planar surface.

The insulating protective film 74 is provided on the planarization film 79 as described above. The second semiconductor substrate 42 serving as a circuit substrate is bonded and laminated on the first semiconductor substrate 41 serving as a sensor substrate on the surface of the protective film 74. Furthermore, in the second semiconductor substrate 42, the protective film 75 covering the second semiconductor substrate 42 is provided on the back surface side opposite to the front surface side on which the wire layer 73 is provided.

(Each Layer on Light Receiving Surface A and the Like)

Subsequently, each layer on the light receiving surface A, that is, the antireflection film 81, the interface state inhibiting film 82, the etching stop film 83, the wire groove forming film 84, the wire 85, the cap film 86, the light shielding film 87, the transparent protective film 88, the color filter 89, and the on-chip lens 90 will be described.

In the peripheral region 64 of the chip region 61, the antireflection film 81, the interface state inhibiting film 82, the etching stop film 83, and the wire groove forming film 84 are provided on the light receiving surface A of the first semiconductor substrate 41 sequentially from the side of the light receiving surface A. Moreover, the wire 85 is provided in the wire groove forming film 84. The cap film 86 is provided so as to cover the wire 85.

The antireflection film 81, the interface state inhibiting film 82, and the light shielding film 87 are provided on the light receiving surface A of the first semiconductor substrate 41 in the pixel region 63 of the chip region 61. In the divided region 62, the antireflection film 81 and the interface state inhibiting film 82 are provided on the light receiving surface A of the first semiconductor substrate 41.

In each layer having the configuration as described above, the following materials can be used as the materials of each layer. The antireflection film 81 includes an insulating material having a refractive index higher than silicon oxide, such as hafnium oxide (HfO₂), tantalum oxide (Ta₂O₅), and silicon nitride. The interface state inhibiting film 82 includes, for example, silicon oxide (SiO₂). The etching stop film 83 includes a material having an etching selectivity lower than that of the material of the wire groove forming film 84 of the upper layer, and includes, for example, silicon nitride (SiN). The wire groove forming film 84 includes, for example, silicon oxide (SiO₂). The cap film 86 includes, for example, silicon nitride (SiN).

(Wire 85)

The wire 85 is provided as an embedded wire embedded in the wire groove forming film 84 on the light receiving surface A in the peripheral region 64 of the chip region 61. The wire 85 is formed by being integrally embedded with the through vias 67, and connects the through vias 67 with each other. The cap film 86 covers an upper portion of the wire 85.

(Through Via 67)

The through via 67 penetrates the etching stop film 83, the interface state inhibiting film 82, and the antireflection film 81 from the wire 85 on the light receiving surface A, penetrates the first semiconductor substrate 41, and reaches the wire layer 71 in the peripheral region 64 of the chip region 61. A plurality of through vias 67 is provided, and connected to the embedded wire 77 of the first semiconductor substrate 41 and the aluminum wire 98 or the embedded wire 97 of the second semiconductor substrate 42.

The wire 85 and the through via 67 described above are integrally configured by embedding copper (Cu) in a wire groove and a connection hole via the separation insulating film 68. The separation insulating film 68 continuously covers the wire groove formed in the wire groove forming film 84 and an inner wall of the connection hole of the bottom thereof. Here, a portion of the wire groove corresponds to the wire 85. A portion of the connection hole corresponds to the through via 67. Furthermore, the separation insulating film 68 includes a material having an anti-diffusion function of copper (Cu), such as a silicon nitride (SiN).

In this way, the embedded wire 77 of the first semiconductor substrate 41 to which each of the through vias 67 is connected and the aluminum wire 98 or the embedded wire 97 of the second semiconductor substrate 42 are electrically connected by connecting the through vias 67 with each other with the wire 85. That is, the drive circuit of the first semiconductor substrate 41 and the drive circuit of the second semiconductor substrate 42 are connected by connecting the through vias 67 with each other with the wire 85.

(Light Shielding Film 87)

The light shielding film 87 is provided above the interface state inhibiting film 82 on the light receiving surface A in the pixel region 63 of the chip region 61, and includes a plurality of light receiving openings 87a corresponding to the photodiodes (photoelectric conversion units) 21. The light shielding film 87 as described above includes a conductive material having excellent light shielding properties, such as aluminum (Al) and tungsten (W). The light shielding film 87 is provided in an opening 87b so as to be grounded to the first semiconductor substrate 41.

(Transparent Protective Film 88)

The transparent protective film 88 is provided in the chip region 61 and the divided region 62 so as to cover the cap film 86 and the light shielding film 87 on the light receiving surface A. The transparent protective film 88 includes an insulating material, and includes, for example, acrylic resin.

(Color Filter 89 and On-Chip Lens 90)

In the pixel region 63 of the chip region 61, the color filter 89 and the on-chip lens 90 supporting each of the photodiodes 21 are provided on the transparent protective film 88. The color filter 89 includes colors corresponding to the photodiodes 21. The arrangement of the color filters 89 of the respective colors is not particularly limited. The on-chip lens 90 collects incident light on each of the photodiodes 21. In contrast, in the peripheral region 64 and the divided region 62 of the chip region 61, an on-chip lens film 90a integrated with the on-chip lens 90 is provided on the transparent protective film 88.

In the imaging element wafer 60 having the above-described structure, the through vias 67 correspond to, for example, the connection nodes N₁ₐ to Nₘₐ and the connection nodes N_{1b} to N_{mb} of the connection units 43A and 43B in FIG. 6. The through vias 67 are provided so as to penetrate the first semiconductor substrate 41, reach the wire layer 71, and be connected to the embedded wire 77. Then, the transfer elements TR₁ to TRₘ of the detection unit 45A and the switch elements SW₁ to SWₘ of the bias unit 45B are connected to the through vias 67 via the embedded wire 77.

In the imaging element wafer 60, a transistor 20 is used as the transfer elements TR₁ to TRₘ of the detection unit 45A and the switch elements SW₁ to SWₘ of the bias unit 45B in FIG. 6. From the viewpoint of a process, it is more preferable to use a transistor (N-channel transistor in FIG. 2) of the same conductivity type as the transistors (transfer transistor 22, reset transistor 23, amplification transistor 24, and selection transistor 25 in FIG. 2) constituting the pixel 2 as the transistor 20 than to use a transistor of a different conductivity type.

A source/drain region 201 of the transistor 20 serving as a switch element is provided on the side of the surface opposite to the light receiving surface A in the chip region 61 of the first semiconductor substrate 41. The same applies to other impurity layers, an element separation region 202, and the like (not illustrated here). Furthermore, a gate electrode 203 of the transistor 20 is provided via the gate insulating film (not illustrated here) on the side of an interface with the first semiconductor substrate 41 in the chip region 61 of the wire layer 71 provided on the surface of the first semiconductor substrate 41.

Furthermore, in the chip region 61 of the first semiconductor substrate 41, a measurement pad 26 is provided in the same layer as the protective film 72 covering the wire layer 71. The measurement pad 26 is an electrode pad corresponding to the terminals 47A and 47C and the electrode 47B in FIG. 6 and the like, the control terminals 49A₁ and 49A₂ and the control terminals 49B₁ and 49B₂ in FIG. 8 and the like. The measurement pad 26 serves as a needle contact terminal used for inspection of open/short circuit of a wire on the side of the first semiconductor substrate 41 before the first semiconductor substrate 41 and the second semiconductor substrate 42 are bonded together.

### 11. Example of Application of Technology of Present Disclosure

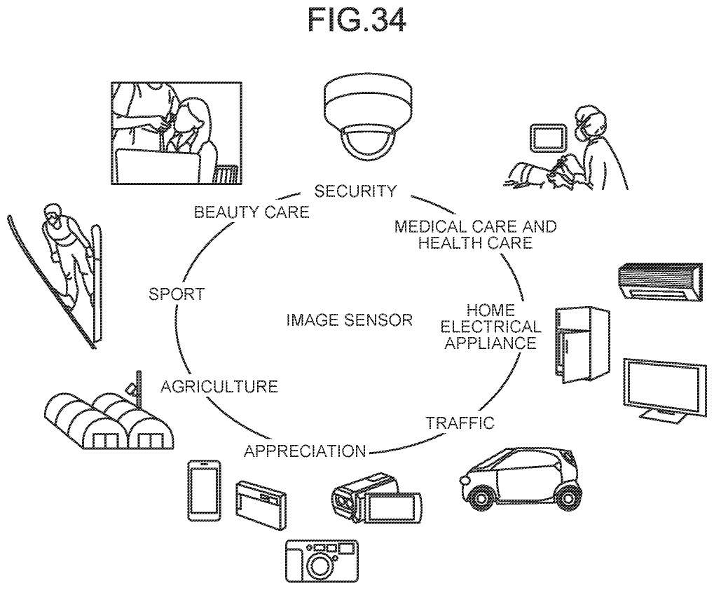

Next, examples of application of the technology of the present disclosure will be described. FIG. 34 illustrates usage examples using the above-described embodiments and the variations thereof according to the technology of the present disclosure.

The above-described imaging element 1 to which the technology of the present disclosure is applied can be used in various cases sensing light such as visible light, infrared light, ultraviolet light, and X-rays as follows, for example.
A device that captures an image provided for appreciation, such as a digital camera and a portable device with a camera function.
A device provided for traffic, such as an in-vehicle sensor, a monitoring camera, and a distance measurement sensor, the in-vehicle sensor capturing an image of, for example, the front, back, surroundings, and inside of an automobile for safe driving such as automatic stop, recognition of the state of a driver, and the like, the monitoring camera monitoring a running vehicle and a road, the distance measurement sensor measuring, for example, a distance between vehicles.
A device provided for a home electrical appliance, such as a TV, a refrigerator, and an air conditioner, for capturing an image of a gesture of a user and operating an instrument in accordance with the gesture.
A device provided for medical care or health care, such as an endoscope and a device that performs angiography by receiving infrared light.
A device provided for security, such as a monitoring camera for security and a camera for person authentication.
A device provided for beauty care, such as a skin measuring instrument that captures an image of skin and a microscope that captures an image of a scalp.
A device provided for sports, such as an action camera and a wearable camera for sports.
A device provided for agriculture, such as a camera for monitoring the states of fields and crops

(Example of Application to Imaging Device)

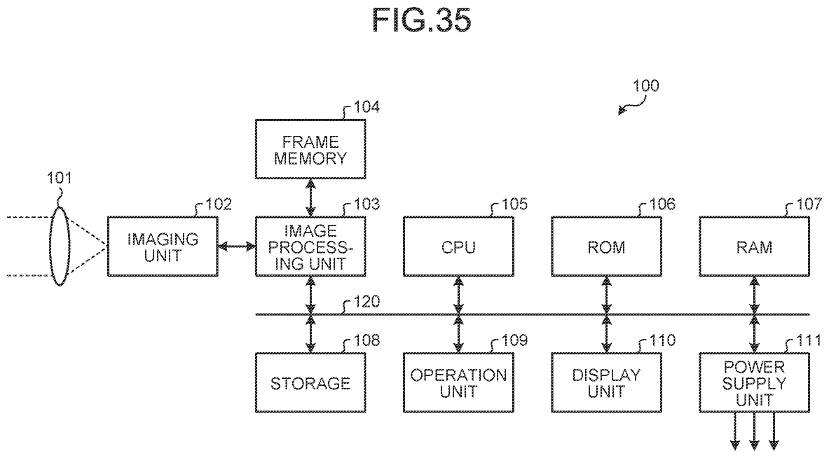

Next, an example of application of the technology according to the present disclosure to an imaging device will be described. FIG. 35 is a block diagram illustrating the configuration of one example of an imaging device to which the technology of the present disclosure can be applied. In FIG. 35, an imaging device 100 includes an optical unit 101, an imaging unit 102, an image processing unit 103, a frame memory 104, a central processing unit (CPU) 105, a read only memory (ROM) 106, a random access memory (RAM) 107, a storage 108, an operation unit 109, a display unit 110, and a power supply unit 111. The image processing unit 103, the frame memory 104, the CPU 105, the ROM 106, the RAM 107, the storage 108, the operation unit 109, the display unit 110, and the power supply unit 111 among these component are connected so as to communicate with each other via a bus 120.

The storage 108 is a storage medium capable of storing data in a nonvolatile manner. For example, a flash memory and a hard disk drive can be applied to the storage 108. The CPU 105 uses the RAM 107 as a work memory to control the overall operation of the imaging device 100 in accordance with a program preliminarily stored in the ROM 106 or the storage 108.

The operation unit 109 includes various operators for the user to operate to operate the imaging device 100, and passes a control signal in response to the user operation to the CPU 105. The display unit 110 includes a display device and a drive circuit that drives the display device. The display device uses a liquid crystal display (LCD) and an organic electro-luminescence (EL). The display unit 110 causes the display device to display a screen in accordance with a display signal passed by the CPU 105 via the bus 120, for example. The power supply unit 111 supplies power to each unit of the imaging device 100.

The optical unit 101 includes one or more lenses and a mechanism such as a diaphragm and a focus, and causes light from a subject to enter the imaging unit 102. The imaging unit 102 includes the imaging element 1 according to the technology of the present disclosure. Light incident from the optical unit 101 is emitted to the pixel array unit 11. In the pixel array unit 11, each pixel 2 outputs a pixel signal in accordance with the emitted light. The imaging unit 102 supplies image data based on a pixel signal output from each pixel 2 to the image processing unit 103.

The image processing unit 103 includes, for example, a digital signal processor (DSP), and performs predetermined image processing such as white balance processing and gamma correction processing on the image data supplied from the imaging unit 102 by using the frame memory 104. The image data subjected to the image processing at the image processing unit 103 is stored in, for example, the storage 108.

Applying the imaging element 1 according to the technology of the present disclosure to the imaging unit 102 allows a wire formed for each pixel row or each pixel column to be inspected by a minimum number of additional circuits, so that an increase in a chip area can be inhibited. Therefore, the imaging unit 102 can contribute to further reduction in the size of the imaging device 100 by using the imaging element 1 according to the technology of the present disclosure. Furthermore, since the first semiconductor substrate 41 can be inspected alone, the yield of the imaging element 1 can be improved, and the cost of the imaging device 100 can be reduced.

Note that the effects set forth in the specification are merely examples and not limitations. Other effects may be obtained.

Note that the present technology can also have the configurations as follows.

(1) A semiconductor element comprising:

a first circuit connected to a first position of each of a plurality of wires of a first wire group including the plurality of wires;

a second circuit connected to a second position corresponding to an end of each of the plurality of wires; and

a plurality of connection units that connects a third circuit with each of the plurality of wires, the plurality of connection units being provided on a one-to-one basis to the plurality of wires between the first position and the second position of each of the plurality of wires.

(2) The semiconductor element according to the above (1), further comprising:

at least one first external connection terminal that is connected to the first circuit and that connects the first circuit and an external device; and

at least one second external connection terminal that is connected to the second circuit and that connects the second circuit and an external device.

(3) The semiconductor element according to the above (2),

wherein the first external connection terminal and the second external connection terminal are arranged on a first surface of a first semiconductor substrate,

the first semiconductor substrate is bonded to a second semiconductor substrate on a second surface corresponding to a back surface of the first surface,

the first external connection terminal and the second external connection terminal are

connected to the first surface and the second surface through a through hole,

the second semiconductor substrate is

provided with an electrode at a position corresponding to each of the first external connection terminal and the second external connection terminal on a surface that is closely attached to the second surface in a case of being bonded to the first semiconductor substrate.

(4) The semiconductor element according to any one of the above (1) to (3),

wherein the first circuit includes

an output circuit that outputs a voltage to each of the plurality of wires,

the second circuit includes

a plurality of input circuits provided on a one-to-one basis and sequentially connected to the plurality of wires, a voltage from each of the plurality of wires being input to the plurality of input circuits, and each of external connection terminals for connection with an external device is connected to sequentially connected one end and another end.

(5) The semiconductor element according to the above (4),

wherein each of the plurality of input circuits includes:

a first control end to which one of the plurality of wires is connected; and

a first switch unit whose states of conduction and non-conduction are controlled in accordance with a voltage input to the first control end, and

in the second circuit,

first switch units of the plurality of input circuits are connected in series connection.

(6) The semiconductor element according to the above (5),

wherein, in the second circuit,

the external connection terminal is connected to each of one end and another end of the series connection of the first switch units of the plurality of input circuits.

(7) The semiconductor element according to the above (5),

wherein the second circuit includes:

a first input circuit group including a plurality of input circuits in which each of a plurality of wires selected every other wire from the plurality of wires is connected to the first control end and the first switch units are connected in the series connection; and

a second input circuit group including a plurality of input circuits in which each of a plurality of wires not connected to the first input circuit group among the plurality of wires is connected to the first control end and the first switch units are connected in series connection, and

each of one end and another end of the first switch units connected in series of the first input circuit group and each of one end and another end of the first switch units connected in series of the second input circuit group are connected.

(8) The semiconductor element according to the above (7),

wherein the output circuit includes

a second switch unit whose states of conduction and non-conduction are controlled in accordance with a voltage input to a second control end, and

the first circuit includes:

a first output circuit group including a plurality of output circuits in which one end of the second switch unit is connected on a one-to-one basis to each of a plurality of wires selected every other wire from the plurality of wires, another end of the second switch unit is connected to an external connection terminal for connection with an external device, and the second control end is connected to an external connection terminal for connection with an external device; and

a second output circuit group including a plurality of output circuits in which one end of the second switch unit is connected on a one-to-one basis to each of a plurality of wires not connected to the first output circuit group among the plurality of wires, another end of the second switch unit is connected to an external connection terminal for connection with an external device, and the second control end is connected to an external connection terminal for connection with an external device.

(9) The semiconductor element according to the above (7),

wherein the output circuit includes

a second switch unit whose states of conduction and non-conduction are controlled in accordance with a voltage input to a second control end,

the first circuit includes:

a first output circuit group including a plurality of output circuits in which one end of the second switch unit is connected on a one-to-one basis to each of a plurality of first wires selected every other wire from the plurality of wires, another end of the second switch unit is connected to an external connection terminal for connection with an external device, and the second control end is connected to an external connection terminal for connection with an external device; and

a second output circuit group including a plurality of output circuits in which one end of the second switch unit is connected on a one-to-one basis to each of a plurality of second wires not connected to the first output circuit group among the plurality of wires, another end of the second switch unit is connected in common to an external connection terminal to which another end of the second switch unit included in the first output circuit group is connected, and the second control end is connected to an external connection terminal for connection with an external device, and

the second circuit further includes

a reset unit including a third switch unit whose states of conduction and non-conduction are controlled in accordance with a voltage input to a third control end, and includes:

a first reset circuit group including a plurality of reset units in which one end of the third switch unit is connected on a one-to-one basis to each of the plurality of first wires, another end of the third switch unit is connected to an external connection terminal for connection with an external device, and the third control end is connected to an external connection terminal for connection with an external device; and

a second reset circuit group including a plurality of reset units in which one end of the third switch unit is connected on a one-to-one basis to each of the plurality of second wires, another end of the third switch unit is connected to an external connection terminal for connection with an external device, and the third control end is connected to an external connection terminal for connection with an external device.

(10) The semiconductor element according to any one of the above (7) to (9),

wherein an external connection terminal for connection with an external device is connected to an intermediate portion of the series connection of each of the first input circuit group and the second input circuit group.

(11) The semiconductor element according to any one of the above (5) to (10), further comprising

a cell array unit in which a plurality of cells each of which executes a predetermined function is arranged in a matrix and the plurality of wires is connected to a plurality of cells aligned in a column in an arrangement among the plurality of cells,

wherein the first circuit

uses a plurality of cells aligned in a row in the arrangement among the plurality of cells of the cell array unit as the output circuit.

(12) The semiconductor element according to the above (5),

wherein the second circuit further includes

a short-circuit unit that short-circuits one or more first switch units in response to an instruction from an external device.

(13) The semiconductor element according to the above (12),

wherein the second circuit includes

a plurality of short-circuit units that short-circuit a different number of first switch units.

(14) The semiconductor element according to the above (4),

wherein each of the plurality of input circuits includes:

a fourth control end to which one of the plurality of wires is connected; and

a fourth switch unit whose states of open and close are controlled in accordance with a voltage input to the fourth control end, and

in the second circuit,

fourth switch units of the plurality of input circuits are connected in parallel connection.

(15) The semiconductor element according to the above (14),

wherein, in the second circuit,

an external connection terminal for connection with an external device is connected in common to one end of the fourth switch unit of each of the plurality of input circuits, and

an external connection terminal for connection with an external device is connected in common to another end of fourth switch unit of each of the plurality of input circuits.

(16) The semiconductor element according to the above (14),

wherein the output circuit includes

a decoding unit that designates one or more wires for outputting the voltage among the plurality of wires in accordance with address information.

(17) The semiconductor element according to the above (14), further comprising

a cell array unit in which a plurality of cells each of which executes a predetermined function is arranged in a matrix and the plurality of wires is connected to a plurality of cells aligned in a column in an arrangement among the plurality of cells,

wherein the first circuit includes

a plurality of cells aligned in a row in the arrangement among the plurality of cells of the cell array unit as the output circuit, and

the second circuit includes

a decoding unit that designates one or more wires to which the voltage is input among the plurality of wires in accordance with address information.

(18) The semiconductor element according to any one of the above (1) to (17), further comprising

a pixel array unit in which a plurality of pixels each including one or more light receiving elements is arranged in a matrix and each of the plurality of wires is connected to a signal line that reads out a pixel signal from a plurality of pixels aligned in a column in an arrangement among the plurality of pixels.

(19) The semiconductor element according to any one of the above (1) to (18),

wherein the third circuit includes

an analog-to-digital converter connected to each of the plurality of wires.

(20) The semiconductor element according to any one of the above (1) to (19), further comprising:

a fourth circuit including an output unit that is connected to one end of a second wire group and that outputs a voltage to each of a plurality of wires included in the second wire group, the second wire group including a plurality of wire bundles each including a plurality of wires and being arranged along a direction different from that of the first wire group; and

a fifth circuit including an input circuit that is connected to another end of the second wire group and to which a voltage is input from a plurality of wires included in the second wire group,

wherein each of the fourth circuit and the fifth circuit includes

a wire designating unit that designates one wire from a plurality of wires included in each of the wire bundles.

(21) The semiconductor element according to the above (20),

wherein the output unit includes

a plurality of switch units connected in series, states of conduction and non-conduction of each of the plurality of switch units being controlled in accordance with a voltage applied to a control end, and

in the switch units,

one end of the plurality of switch units connected in series is connected to one wire included in the second wire group, and a voltage output by the output unit is applied to another end.

(22) The semiconductor element according to the above (20),

wherein the third circuit includes

a selection circuit that selects one wire bundle from the plurality of wire bundles included in the second wire group.

(23) The semiconductor element according to any one of the above (1) to (22), further comprising:

a first semiconductor substrate;

a second semiconductor substrate bonded to the first semiconductor substrate; and

a plurality of connection units that penetrate and connect the first semiconductor substrate and the second semiconductor substrate,

wherein one of the first circuit and the second circuit is arranged on the first semiconductor substrate, and another is arranged on the second semiconductor substrate, and

one end of the plurality of connection units is connected to the first circuit, and another end is connected to the second circuit.

(24) The semiconductor element according to any one of the above (1) to (23), further comprising

a cell array unit in which a plurality of cells each of which executes a predetermined function is arranged in a matrix and the plurality of wires is connected to a plurality of cells aligned in a column in an arrangement among the plurality of cells,

wherein the first circuit includes

an output circuit that outputs a voltage to each of the plurality of wires, and

a well in which the output circuit is arranged and a well in which the cell array unit is arranged are separated.

(25) The semiconductor element according to the above (24),

wherein the output circuit includes a plurality of output units each including a transistor, and

a well in which a first output unit among the plurality of output units is arranged and a well in which a second output unit among the plurality of output units is arranged are separated from each other.

(26) The semiconductor element according to the above (25),

wherein, among the plurality of wires,

a first wire connected to the first output unit, and

a second wire connected to a second output unit

are adjacent.

(27) The semiconductor element according to the above (25) or (26),

wherein each of the plurality of output units includes

an input terminal that inputs an input voltage for determining a voltage to be output to a corresponding wire among the plurality of wires, and

a potential of each well in which each of the plurality of output units is arranged is applied from the input terminal of each of the plurality of output units.

(28) The semiconductor element according to any one of (24) to (27),

wherein the second circuit includes

a plurality of input circuits each of which is provided on a one-to-one basis to each of the plurality of wires and each of which includes a transistor, a voltage being input from the plurality of wires to the plurality of input circuits, and

a well in which the plurality of input circuits is arranged is separated from at least one of a well in which the output circuit is arranged and a well in which the cell array unit is arranged.

### REFERENCE SIGNS LIST

1 IMAGING ELEMENT
2, 2′ PIXEL
11 PIXEL ARRAY UNIT
31, 31₁, 31₂, 31₃, 31₄, 31ₘ₋₁, 31ₘ VERTICAL SIGNAL LINE
32₁, 32₂, 32ₙ CONTROL LINE
41a, 41b, 41c, 41d, 41e, 41f, 41g, 41h FIRST SEMICONDUCTOR SUBSTRATE
42 SECOND SEMICONDUCTOR SUBSTRATE
43A, 43B, 44A, 44B CONNECTION UNIT
45A, 45Aa, 45Ab, 45Ac, 45Ad, 45Ae, 45Af, 45Ag, 45Ah DETECTION UNIT
45B, 45Ba, 45Bb, 45Bc, 45Bd, 45Be, 45Be′, 45Bf, 45Bg, 45Bh, 45Bh′ BIAS UNIT
47A, 47C, 47E, 48A, 48C TERMINAL
47B, 47D, 48B, 48D ELECTRODE
49A, 49A₁, 49A₂, 49B, 50A, 50A_{R}, 50A_{T}, 50A_{S}, 50B, 50B₁, 50B^{R}, 50B_{T}, 50B_{S}, 50C₁, 50C_{R}, 50C_{T}, 50C_{S} CONTROL TERMINAL

1. A semiconductor element comprising:
a first circuit connected to a first position of each of a plurality of wires of a first wire group including the plurality of wires;
a second circuit connected to a second position corresponding to an end of each of the plurality of wires; and
a plurality of connection units that connects a third circuit with each of the plurality of wires, the plurality of connection units being provided on a one-to-one basis to the plurality of wires between the first position and the second position of each of the plurality of wires.

2. The semiconductor element according to claim 1, further comprising:
at least one first external connection terminal that is connected to the first circuit and that connects the first circuit and an external device; and
at least one second external connection terminal that is connected to the second circuit and that connects the second circuit and an external device.

3. The semiconductor element according to claim 2,
wherein the first external connection terminal and the second external connection terminal are arranged on a first surface of a first semiconductor substrate,
the first semiconductor substrate is bonded to a second semiconductor substrate on a second surface corresponding to a back surface of the first surface,
the first external connection terminal and the second external connection terminal are
connected to the first surface and the second surface through a through hole,
the second semiconductor substrate is
provided with an electrode at a position corresponding to each of the first external connection terminal and the second external connection terminal on a surface that is closely attached to the second surface in a case of being bonded to the first semiconductor substrate.

4. The semiconductor element according to claim 1,
wherein the first circuit includes
an output circuit that outputs a voltage to each of the plurality of wires,
the second circuit includes
a plurality of input circuits provided on a one-to-one basis and sequentially connected to the plurality of wires, a voltage from each of the plurality of wires being input to the plurality of input circuits, and each of external connection terminals for connection with an external device is connected to sequentially connected one end and another end.

5. The semiconductor element according to claim 4,
wherein each of the plurality of input circuits includes:
a first control end to which one of the plurality of wires is connected; and
a first switch unit whose states of conduction and non-conduction are controlled in accordance with a voltage input to the first control end, and
in the second circuit,
first switch units of the plurality of input circuits are connected in series connection.

6. The semiconductor element according to claim 5,
wherein, in the second circuit,
the external connection terminal is connected to each of one end and another end of the series connection of the first switch units of the plurality of input circuits.

7. The semiconductor element according to claim 5,
wherein the second circuit includes:
a first input circuit group including a plurality of input circuits in which each of a plurality of wires selected every other wire from the plurality of wires is connected to the first control end and the first switch units are connected in the series connection; and
a second input circuit group including a plurality of input circuits in which each of a plurality of wires not connected to the first input circuit group among the plurality of wires is connected to the first control end and the first switch units are connected in series connection, and
each of one end and another end of the first switch units connected in series of the first input circuit group and each of one end and another end of the first switch units connected in series of the second input circuit group are connected.

8. The semiconductor element according to claim 7,
wherein the output circuit includes
a second switch unit whose states of conduction and non-conduction are controlled in accordance with a voltage input to a second control end, and
the first circuit includes:
a first output circuit group including a plurality of output circuits in which one end of the second switch unit is connected on a one-to-one basis to each of a plurality of wires selected every other wire from the plurality of wires, another end of the second switch unit is connected to an external connection terminal for connection with an external device, and the second control end is connected to an external connection terminal for connection with an external device; and
a second output circuit group including a plurality of output circuits in which one end of the second switch unit is connected on a one-to-one basis to each of a plurality of wires not connected to the first output circuit group among the plurality of wires, another end of the second switch unit is connected to an external connection terminal for connection with an external device, and the second control end is connected to an external connection terminal for connection with an external device.

9. The semiconductor element according to claim 7,
wherein the output circuit includes
a second switch unit whose states of conduction and non-conduction are controlled in accordance with a voltage input to a second control end,
the first circuit includes:
a first output circuit group including a plurality of output circuits in which one end of the second switch unit is connected on a one-to-one basis to each of a plurality of first wires selected every other wire from the plurality of wires, another end of the second switch unit is connected to an external connection terminal for connection with an external device, and the second control end is connected to an external connection terminal for connection with an external device; and
a second output circuit group including a plurality of output circuits in which one end of the second switch unit is connected on a one-to-one basis to each of a plurality of second wires not connected to the first output circuit group among the plurality of wires, another end of the second switch unit is connected in common to an external connection terminal to which another end of the second switch unit included in the first output circuit group is connected, and the second control end is connected to an external connection terminal for connection with an external device, and
the second circuit further includes
a reset unit including a third switch unit whose states of conduction and non-conduction are controlled in accordance with a voltage input to a third control end, and includes:
a first reset circuit group including a plurality of reset units in which one end of the third switch unit is connected on a one-to-one basis to each of the plurality of first wires, another end of the third switch unit is connected to an external connection terminal for connection with an external device, and the third control end is connected to an external connection terminal for connection with an external device; and
a second reset circuit group including a plurality of reset units in which one end of the third switch unit is connected on a one-to-one basis to each of the plurality of second wires, another end of the third switch unit is connected to an external connection terminal for connection with an external device, and the third control end is connected to an external connection terminal for connection with an external device.

10. The semiconductor element according to claim 7,
wherein an external connection terminal for connection with an external device is connected to an intermediate portion of the series connection of each of the first input circuit group and the second input circuit group.

11. The semiconductor element according to claim 5, further comprising
a cell array unit in which a plurality of cells each of which executes a predetermined function is arranged in a matrix and the plurality of wires is connected to a plurality of cells aligned in a column in an arrangement among the plurality of cells,
wherein the first circuit
uses a plurality of cells aligned in a row in the arrangement among the plurality of cells of the cell array unit as the output circuit.

12. The semiconductor element according to claim 5,
wherein the second circuit further includes
a short-circuit unit that short-circuits one or more first switch units in response to an instruction from an external device.

13. The semiconductor element according to claim 12,
wherein the second circuit includes
a plurality of short-circuit units that short-circuit a different number of first switch units.

14. The semiconductor element according to claim 4,
wherein each of the plurality of input circuits includes:
a fourth control end to which one of the plurality of wires is connected; and
a fourth switch unit whose states of open and close are controlled in accordance with a voltage input to the fourth control end, and
in the second circuit,
fourth switch units of the plurality of input circuits are connected in parallel connection.

15. The semiconductor element according to claim 14,
wherein, in the second circuit,
an external connection terminal for connection with an external device is connected in common to one end of the fourth switch unit of each of the plurality of input circuits, and
an external connection terminal for connection with an external device is connected in common to another end of fourth switch unit of each of the plurality of input circuits.

16. The semiconductor element according to claim 14,
wherein the output circuit includes
a decoding unit that designates one or more wires for outputting the voltage among the plurality of wires in accordance with address information.

17. The semiconductor element according to claim 14, further comprising
a cell array unit in which a plurality of cells each of which executes a predetermined function is arranged in a matrix and the plurality of wires is connected to a plurality of cells aligned in a column in an arrangement among the plurality of cells,
wherein the first circuit includes
a plurality of cells aligned in a row in the arrangement among the plurality of cells of the cell array unit as the output circuit, and
the second circuit includes
a decoding unit that designates one or more wires to which the voltage is input among the plurality of wires in accordance with address information.

18. The semiconductor element according to claim 1, further comprising
a pixel array unit in which a plurality of pixels each including one or more light receiving elements is arranged in a matrix and each of the plurality of wires is connected to a signal line that reads out a pixel signal from a plurality of pixels aligned in a column in an arrangement among the plurality of pixels.

19. The semiconductor element according to claim 1,
wherein the third circuit includes
an analog-to-digital converter connected to each of the plurality of wires.

20. The semiconductor element according to claim 1, further comprising:
a fourth circuit including an output unit that is connected to one end of a second wire group and that outputs a voltage to each of a plurality of wires included in the second wire group, the second wire group including a plurality of wire bundles each including a plurality of wires and being arranged along a direction different from that of the first wire group; and
a fifth circuit including an input circuit that is connected to another end of the second wire group and to which a voltage is input from a plurality of wires included in the second wire group,
wherein each of the fourth circuit and the fifth circuit includes
a wire designating unit that designates one wire from a plurality of wires included in each of the wire bundles.

21. The semiconductor element according to claim 20,
wherein the output unit includes
a plurality of switch units connected in series, states of conduction and non-conduction of each of the plurality of switch units being controlled in accordance with a voltage applied to a control end, and
in the switch units,
one end of the plurality of switch units connected in series is connected to one wire included in the second wire group, and a voltage output by the output unit is applied to another end.

22. The semiconductor element according to claim 20,
wherein the third circuit includes
a selection circuit that selects one wire bundle from the plurality of wire bundles included in the second wire group.

23. The semiconductor element according to claim 1, further comprising:
a first semiconductor substrate;
a second semiconductor substrate bonded to the first semiconductor substrate; and
a plurality of connection units that penetrate and connect the first semiconductor substrate and the second semiconductor substrate,
wherein one of the first circuit and the second circuit is arranged on the first semiconductor substrate, and another is arranged on the second semiconductor substrate, and
one end of the plurality of connection units is connected to the first circuit, and another end is connected to the second circuit.

24. The semiconductor element according to claim 1, further comprising
a cell array unit in which a plurality of cells each of which executes a predetermined function is arranged in a matrix and the plurality of wires is connected to a plurality of cells aligned in a column in an arrangement among the plurality of cells,
wherein the first circuit includes
an output circuit that outputs a voltage to each of the plurality of wires, and
a well in which the output circuit is arranged and a well in which the cell array unit is arranged are separated.

25. The semiconductor element according to claim 24,
wherein the output circuit includes a plurality of output units each including a transistor, and
a well in which a first output unit among the plurality of output units is arranged and a well in which a second output unit among the plurality of output units is arranged are separated from each other.

26. The semiconductor element according to claim 25,
wherein, among the plurality of wires,
a first wire connected to the first output unit, and
a second wire connected to a second output unit
are adjacent.

27. The semiconductor element according to claim 25,
wherein each of the plurality of output units includes
an input terminal that inputs an input voltage for determining a voltage to be output to a corresponding wire among the plurality of wires, and
a potential of each well in which each of the plurality of output units is arranged is applied from the input terminal of each of the plurality of output units.

28. The semiconductor element according to claim 24,
wherein the second circuit includes
a plurality of input circuits each of which is provided on a one-to-one basis to each of the plurality of wires and each of which includes a transistor, a voltage being input from the plurality of wires to the plurality of input circuits, and
a well in which the plurality of input circuits is arranged is separated from at least one of a well in which the output circuit is arranged and a well in which the cell array unit is arranged.
